(19) United States
(12) Patent Application Publication
(10) Pub. No.: US 2025/0275174 A1
(43) Pub. Date: Aug. 28, 2025

(54) SEMICONDUCTOR DEVICE AND STORAGE DEVICE

(71) Applicant: SEMICONDUCTOR ENERGY LABORATORY CO., LTD., Atsugi-shi, Kanagawa-ken (JP)

(72) Inventors: Hidekazu MIYAIRI, Hadano, Kanagawa (JP); Motoki NAKASHIMA, Atsugi, Kanagawa (JP)

(21) Appl. No.: 18/856,276

(22) PCT Filed: Apr. 7, 2023
(86) PCT No.: PCT/IB2023/053568

§ 371 Date: Oct. 11, 2024

(30) Foreign Application Priority Data
Apr. 19, 2022 (JP) 2022-069016

(51) Int. Cl. H10D 30/63; H10B 12/00; H10D 62/17; H10D 64/27

(52) U.S. Cl. CPC H10D 30/63; H10B 12/50; H10D 62/292; H10D 64/514; H10D 64/519; H10B 12/05

(57) ABSTRACT

A semiconductor device that can be miniaturized or highly integrated is provided. The semiconductor device includes a first conductor, a first oxide and a second oxide being electrically connected to the first conductor and having an opening, a second conductor electrically connected to the first oxide, a third conductor placed inside the opening that the first oxide has, a fourth conductor electrically connected to the third conductor, a fifth conductor electrically connected to the second oxide, a sixth conductor placed inside the opening that the second oxide has, a seventh conductor electrically connected to the sixth conductor, and an eighth conductor electrically connected to the second conductor and the seventh conductor. The fourth conductor is provided in the same layer as the seventh conductor, and a direction in which the fourth conductor extends is the same as a direction in which the fifth conductor extends.

### TECHNICAL FIELD

One embodiment of the present invention relates to a semiconductor device, a storage device, and an electronic device. One embodiment of the present invention relates to a method for manufacturing a semiconductor device. One embodiment of the present invention relates to a semiconductor wafer and a module.

Note that in this specification and the like, a semiconductor device refers to a general device that can function by utilizing semiconductor characteristics. A semiconductor element such as a transistor, a semiconductor circuit, an arithmetic device, and a storage device are each an embodiment of a semiconductor device. It can be sometimes said that a display device (a liquid crystal display device, a light-emitting display device, and the like), a projection device, a lighting device, an electro-optical device, a power storage device, a storage device, a semiconductor circuit, an image-capture device, an electronic device, and the like include a semiconductor device.

Note that one embodiment of the present invention is not limited to the above technical field. One embodiment of the invention disclosed in this specification and the like relates to an object, a method, or a manufacturing method. One embodiment of the present invention relates to a process, a machine, manufacture, or a composition of matter.

### BACKGROUND ART

Along with the increase in the degree of integration of storage devices, a reduction in the area occupied by a memory has been required. However, miniaturization of storage devices using Si transistors has been becoming difficult in terms of techniques and costs.

In recent years, oxide semiconductors have been attracting attention as a semiconductor material that enables formation of transistors in a BEOL (Back end of line) process for forming wirings in a semiconductor device. A technique for forming an OS transistor (transistor including a metal oxide in a channel formation region) directly above a conventional Si transistor (transistor including silicon in a channel formation region) (this technique is also referred to as a BEOL-Tr technology) enables construction of a 3D functional circuit without deviation from a design rule. Thus, this technique is expected as a technique achieving a high-performance memory device with low power consumption and low cost.

Moreover, if vertical OS transistors can be formed, the minimum design rule can be reduced from 6F² (F is a minimum feature size) to 4F². For example, Patent Document 1 discloses a vertical transistor in which a side surface of an oxide semiconductor is covered with a word line with a gate insulating layer therebetween.

### REFERENCE

### Patent Document

[Patent Document 1] Japanese Published Patent Application No. 2021-108331

### SUMMARY OF THE INVENTION

### Problems to be Solved by the Invention

An object of one embodiment of the present invention is to provide a transistor that can be miniaturized or highly integrated. An object of one embodiment of the present invention is to provide a transistor with favorable electrical characteristics. An object of one embodiment of the present invention is to provide a transistor with a small variation in electrical characteristics. An object of one embodiment of the present invention is to provide a transistor with a high on-state current. An object of one embodiment of the present invention is to provide a transistor with high reliability. An object of one embodiment of the present invention is to provide a novel transistor. An object of one embodiment of the present invention is to provide a semiconductor device or a storage device that includes the above transistor. An object of one embodiment of the present invention is to provide a semiconductor device or a storage device with low power consumption. An object of one embodiment of the present invention is to provide a semiconductor device or a storage device with high operation speed.

Note that the description of these objects does not preclude the existence of other objects. One embodiment of the present invention does not need to achieve all of these objects. Note that other objects will be apparent from the description of the specification, the drawings, the claims, and the like, and other objects can be derived from the description of the specification, the drawings, the claims, and the like.

### Means for Solving the Problems

One embodiment of the present invention is a semiconductor device which includes a first conductor, a first oxide and a second oxide being electrically connected to the first conductor and having an opening, a second conductor electrically connected to the first oxide, a first insulator placed inside the opening that the first oxide has, a third conductor over the first insulator, a fourth conductor electrically connected to the third conductor, a fifth conductor electrically connected to the second oxide, a second insulator placed inside the opening that the second oxide has, a sixth conductor over the second insulator, a seventh conductor electrically connected to the sixth conductor, and an eighth conductor electrically connected to the second conductor and the seventh conductor. The fourth conductor is provided in the same layer as the seventh conductor, and a direction in which the fourth conductor extends is the same as a direction in which the fifth conductor extends.

In the above-described semiconductor device, the first conductor preferably extends in a direction orthogonal to the direction in which the fourth conductor extends.

The above-described semiconductor device preferably further includes a ninth conductor and a tenth conductor, the ninth conductor is preferably provided between the first oxide and the second conductor, a side surface of the ninth conductor is preferably aligned with a side surface of the first oxide, the tenth conductor is preferably provided between the second oxide and the fifth conductor, and a side surface of the tenth conductor is preferably aligned with a side surface of the second oxide. Furthermore, it is further preferable that the second conductor have a protruding portion and that the protruding portion be in contact with the ninth conductor.

In the above-described semiconductor device, the side surface of the first oxide preferably has a tapered shape in a cross-sectional view.

One embodiment of the present invention is a semiconductor device which includes a first conductor and a second conductor, a first oxide electrically connected to the first conductor and having an opening, a third conductor electrically connected to the first oxide, a first insulator placed inside the opening that the first oxide has, a fourth conductor over the first insulator, a fifth conductor electrically connected to the fourth conductor, a second oxide electrically connected to the second conductor and having an opening, a sixth conductor electrically connected to the second oxide, a second insulator placed inside the opening that the second oxide has, a seventh conductor over the second insulator, an eighth conductor electrically connected to the seventh conductor, and a ninth conductor electrically connected to the third conductor and the eighth conductor. The fifth conductor is provided in the same layer as the eighth conductor, and a direction in which the fifth conductor extends is the same as a direction in which the sixth conductor extends.

In the above-described semiconductor device, the first conductor preferably extends in a direction orthogonal to the direction in which the fifth conductor extends, and the second conductor preferably extends in a direction orthogonal to the direction in which the sixth conductor extends.

The above-described semiconductor device preferably further includes a tenth conductor and an eleventh conductor, the tenth conductor is preferably provided between the first oxide and the third conductor, a side surface of the tenth conductor is preferably aligned with a side surface of the first oxide, the eleventh conductor is preferably provided between the second oxide and the sixth conductor, and a side surface of the eleventh conductor is preferably aligned with a side surface of the second oxide.

In the above-described semiconductor, the side surface of the first oxide preferably has a tapered shape in a cross-sectional view.

One embodiment of the present invention is a storage device which includes the above-described semiconductor device and a layer including a peripheral circuit, where the layer is positioned below the semiconductor device and the peripheral circuit has a function of writing data to the semiconductor device and reading data from the semiconductor device.

### Effect of the Invention

With one embodiment of the present invention, a transistor that can be miniaturized or highly integrated can be provided. With one embodiment of the present invention, a transistor with favorable electrical characteristics can be provided. With one embodiment of the present invention, a transistor with a small variation in electrical characteristics can be provided. With one embodiment of the present invention, a transistor with a high on-state current can be provided. With one embodiment of the present invention, a transistor with high reliability can be provided. With one embodiment of the present invention, a novel transistor can be provided. With one embodiment of the present invention, a semiconductor device or a storage device that includes the above transistor can be provided. With one embodiment of the present invention, a semiconductor device or a storage device with low power consumption can be provided. A semiconductor device or a storage device with high operation speed can be provided.

Note that the description of these effects does not preclude the existence of other effects. Note that one embodiment of the present invention does not need to have all of these effects. Note that effects other than these will be apparent from the description of the specification, the drawings, the claims, and the like and effects other than these can be derived from the description of the specification, the drawings, the claims, and the like.

### BRIEF DESCRIPTION OF THE DRAWINGS

FIG. 1A is a perspective view illustrating a structure example of a semiconductor device. FIG. 1B is a top view illustrating the structure example of the semiconductor device.

FIG. 2A is a top view illustrating a structure example of a semiconductor device. FIG. 2B and FIG. 2C are cross-sectional views illustrating the structure example of the semiconductor device.

FIG. 2D is a perspective view illustrating the structure example of the semiconductor device.

FIG. 2E is a cross-sectional view illustrating the structure example of the semiconductor device.

FIG. 3A to FIG. 3F are top views illustrating structure examples of a semiconductor device.

FIG. 4A to FIG. 4E are top views illustrating structure examples of a semiconductor device.

FIG. 5A and FIG. 5B are cross-sectional views illustrating a structure example of a semiconductor device. FIG. 5C is a perspective view illustrating a structure example of a semiconductor device.

FIG. 6A is a top view illustrating a structure example of a semiconductor device. FIG. 6B is a cross-sectional view illustrating the structure example of the semiconductor device. FIG. 6C is a perspective view illustrating the structure example of the semiconductor device.

FIG. 7A and FIG. 7B are top views illustrating structure examples of a semiconductor device.

FIG. 8A is a top view illustrating a structure example of a semiconductor device. FIG. 8B is a cross-sectional view illustrating the structure example of the semiconductor device. FIG. 8C is a perspective view illustrating the structure example of the semiconductor device.

FIG. 9A and FIG. 9B are top views illustrating structure examples of a semiconductor device.

FIG. 10A and FIG. 10B are cross-sectional views illustrating a structure example of a semiconductor device. FIG. 10C is a perspective view illustrating the structure example of the semiconductor device.

FIG. 11A and FIG. 11B are cross-sectional views illustrating structure examples of a semiconductor device.

FIG. 12A to FIG. 12C are cross-sectional views illustrating structure examples of a semiconductor device.

FIG. 13A and FIG. 13D are top views illustrating a structure example of a semiconductor device.

FIG. 13B and FIG. 13C are cross-sectional views illustrating the structure example of the semiconductor device.

FIG. 14A and FIG. 14B are cross-sectional views illustrating structure examples of a semiconductor device.

FIG. 15A1 and FIG. 15B1 are top views illustrating an example of a method for manufacturing a semiconductor device. FIG. 15A2 and FIG. 15B2 are cross-sectional views illustrating the example of the method for manufacturing a semiconductor device.

FIG. 16A1 and FIG. 16B1 are top views illustrating the example of the method for manufacturing a semiconductor device. FIG. 16A2 and FIG. 16B2 are cross-sectional views illustrating the example of the method for manufacturing a semiconductor device.

FIG. 17A1 and FIG. 17B1 are top views illustrating the example of the method for manufacturing a semiconductor device. FIG. 17A2 and FIG. 17B2 are cross-sectional views illustrating the example of the method for manufacturing a semiconductor device.

FIG. 18A1 and FIG. 18B1 are top views illustrating the example of the method for manufacturing a semiconductor device. FIG. 18A2 and FIG. 18B2 are cross-sectional views illustrating the example of the method for manufacturing a semiconductor device.

FIG. 19A1 and FIG. 19B1 are top views illustrating the example of the method for manufacturing a semiconductor device. FIG. 19A2 and FIG. 19B2 are cross-sectional views illustrating the example of the method for manufacturing a semiconductor device.

FIG. 20A1 and FIG. 20B1 are top views illustrating the example of the method for manufacturing a semiconductor device. FIG. 20A2 and FIG. 20B2 are cross-sectional views illustrating the example of the method for manufacturing a semiconductor device.

FIG. 21A1 and FIG. 21B1 are top views illustrating the example of the method for manufacturing a semiconductor device. FIG. 21A2 and FIG. 21B2 are cross-sectional views illustrating the example of the method for manufacturing a semiconductor device.

FIG. 22A1 and FIG. 22B1 are top views illustrating the example of the method for manufacturing a semiconductor device. FIG. 22A2 and FIG. 22B2 are cross-sectional views illustrating the example of the method for manufacturing a semiconductor device.

FIG. 23A is a block diagram illustrating a structure example of a storage device. FIG. 23B is a perspective view illustrating the structure example of the storage device.

FIG. 24A and FIG. 24B are circuit diagrams illustrating structure examples of a memory cell.

FIG. 24C and FIG. 24D are perspective views illustrating a structure example of a storage device.

FIG. 25 is a cross-sectional view illustrating a structure example of a storage device.

FIG. 26 is a cross-sectional view illustrating a structure example of a storage device.

FIG. 27A to FIG. 27E are diagrams for describing examples of a storage device.

FIG. 28A to FIG. 28G are diagrams for describing examples of an electronic device.

### MODE FOR CARRYING OUT THE INVENTION

Embodiments will be described below with reference to the drawings. Note that the embodiments can be implemented with many different modes, and it is readily understood by those skilled in the art that modes and details thereof can be changed in various ways without departing from the spirit and scope thereof. Thus, the present invention should not be construed as being limited to the description of the embodiments below.

In the drawings, the size, the layer thickness, or the region is exaggerated for clarity in some cases. Therefore, the size, the layer thickness, or the region is not limited to the illustrated scale. The drawings are schematic views illustrating ideal examples, and embodiments of the present invention are not limited to shapes, values, or the like shown in the drawings. For example, in the actual manufacturing process, a layer, a resist mask, or the like might be unintentionally reduced in size by treatment such as etching, which might not be reflected in the drawings for easy understanding. Furthermore, in the drawings, the same reference numerals are used in common for the same portions or portions having similar functions in different drawings, and repeated description thereof is omitted in some cases. The same hatching pattern is used for portions having similar functions, and the portions are not especially denoted by reference numerals in some cases.

In particular, in a perspective view, a top view (also referred to as a “plan view”), or the like for example, some components might not be illustrated for easy understanding of the invention. In addition, some hidden lines and the like might not be illustrated. In the drawings, for example, a hatching pattern or the like is omitted in some cases. Furthermore, a hatching pattern for one component is different between a top view and a cross-sectional view in some cases.

The ordinal numbers such as “first” and “second” in this specification and the like are used for convenience and do not denote the order of steps or the stacking order of layers. Therefore, for example, the term “first” can be replaced with the term “second”, “third”, or the like as appropriate. In addition, the ordinal numbers in this specification and the like do not sometimes correspond to the ordinal numbers that are used to specify one embodiment of the present invention.

Moreover, in this specification and the like, terms for describing arrangement, such as “over” and “under”, are used for convenience for describing the positional relationship between components with reference to drawings. The positional relationship between components changes as appropriate in accordance with the direction in which the components are described. Thus, without limitation to terms described in the specification, the description can be changed appropriately depending on the situation.

When this specification and the like explicitly state that X and Y are connected, for example, the case where X and Y are electrically connected, the case where X and Y are functionally connected, and the case where X and Y are directly connected are regarded as being disclosed in this specification and the like. Accordingly, without being limited to a predetermined connection relation, for example, a connection relation illustrated in drawings or described with texts, a connection relation other than one illustrated in drawings or described with texts is regarded as being disclosed in the drawings or description with the texts. Here, X and Y each denote an object (e.g., a device, an element, a circuit, a wiring, an electrode, a terminal, a conductive film, or a layer).

In this specification and the like, a transistor is an element having at least three terminals including a gate, a drain, and a source. The transistor includes a region where a channel is formed (hereinafter also referred to as a channel formation region) between the drain (a drain terminal, a drain region, or a drain electrode) and the source (a source terminal, a source region, or a source electrode), and a current can flow between the source and the drain through the channel formation region. Note that in this specification and the like, a channel formation region refers to a region through which a current mainly flows.

Furthermore, functions of a source and a drain are sometimes interchanged with each other when transistors having different polarities are used or when the direction of current is changed in circuit operation, for example. Therefore, the terms “source” and “drain” can sometimes be interchanged with each other in this specification and the like.

An impurity in a semiconductor refers to, for example, an element other than the main components of a semiconductor. For example, an element with a concentration lower than 0.1 atomic % can be regarded as an impurity. When an impurity is contained, for example, the density of defect states in a semiconductor increases and the crystallinity decreases in some cases. In the case where the semiconductor is an oxide semiconductor, examples of an impurity which changes the characteristics of the semiconductor include Group 1 elements, Group 2 elements, Group 13 elements, Group 14 elements, Group 15 elements, and transition metals other than the main components of the oxide semiconductor; hydrogen, lithium, sodium, silicon, boron, phosphorus, carbon, and nitrogen are given as examples. Note that water also serves as an impurity in some cases. In addition, oxygen vacancies (also referred to as V_{O}) are formed in an oxide semiconductor in some cases by entry of impurities, for example.

Note that in this specification and the like, an oxynitride refers to a material that contains more oxygen than nitrogen in its composition, and a nitride oxide refers to a material that contains more nitrogen than oxygen in its composition. For example, silicon oxynitride refers to a material that contains more oxygen than nitrogen in its composition, and silicon nitride oxide refers to a material that contains more nitrogen than oxygen in its composition.

In this specification and the like, the term “insulator” can be replaced with an insulating film or an insulating layer. The term “conductor” can be replaced with a conductive film or a conductive layer. The term “semiconductor” can be replaced with a semiconductor film or a semiconductor layer.

In this specification and the like, “parallel” indicates a state where two straight lines are placed at an angle greater than or equal to −10 degrees and less than or equal to 10 degrees. Accordingly, the case where the angle is greater than or equal to −5 degrees and less than or equal to 5 degrees is also included. Furthermore, “substantially parallel” indicates a state where two straight lines are placed at an angle greater than or equal to −30 degrees and less than or equal to 30 degrees. Moreover, “perpendicular” indicates a state where two straight lines are placed at an angle greater than or equal to 80 degrees and less than or equal to 100 degrees. Accordingly, the case where the angle is greater than or equal to 85 degrees and less than or equal to 95 degrees is also included. Furthermore, “substantially perpendicular” indicates a state where two straight lines are placed at an angle greater than or equal to 60 degrees and less than or equal to 120 degrees.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is used in a semiconductor layer of a transistor, the metal oxide is referred to as an oxide semiconductor in some cases. That is, an OS transistor can also be referred to as a transistor including a metal oxide or an oxide semiconductor.

In this specification and the like, “normally off” means that a drain current per micrometer of channel width flowing through a transistor when no potential is applied to a gate or the gate is supplied with a ground potential is lower than or equal to 1×10⁻²⁰ A at room temperature, lower than or equal to 1×10⁻¹⁸ A at 85° C., or lower than or equal to 1×10⁻¹⁶ A at 125° C.

In this specification and the like, when a plurality of components are denoted with the same reference numeral and in particular need to be distinguished from each other, an identification sign such as “[n]”, or “[m, n]” is sometimes added to the reference numeral.

Note that in this specification and the like, the expression “level with” indicates a structure having the same level from a reference surface (e.g., a flat surface such as a substrate surface) in a cross-sectional view. For example, in a manufacturing process of the semiconductor device, planarization treatment (typically, CMP (chemical mechanical polishing) treatment) is performed, whereby the surface(s) of a single layer or a plurality of layers are exposed in some cases. In that case, the surfaces on which the CMP treatment is performed are at the same level from a reference surface. Note that the plurality of layers are not level with each other in some cases, depending on a treatment apparatus, a treatment method, or a material of the treated surfaces at the time when the CMP treatment is performed. This case is also regarded as “level with” in this specification and the like. For example, the expression “level with” includes the case where two layers (here, given as a first layer and a second layer) having different two levels with respect to the reference surface are included, and the difference between the top-surface level of the first layer and the top-surface level of the second layer is less than or equal to 20 nm.

In this specification and the like, “end portions are aligned” means that at least outlines of stacked layers partly overlap with each other in a top view. For example, the case of processing an upper layer and a lower layer with the use of the same mask pattern or mask patterns that are partly the same is included. Note that in some cases, the outlines do not exactly overlap with each other and the outline of the upper layer is located inward from the outline of the lower layer or the outline of the upper layer is located outward from the outline of the lower layer; such a case is also represented by the expression “end portions are aligned”.

In general, it is difficult to clearly differentiate “perfectly aligned” from “substantially aligned”. Therefore, in this specification and the like, the expression “aligned” includes both “perfectly aligned” and “substantially aligned”.

### Embodiment 1

In this embodiment, a semiconductor device of one embodiment of the present invention and a method for manufacturing the semiconductor device are described with reference to drawings.

One embodiment of the present invention relates to a semiconductor device in which a storage layer is provided over a substrate. The storage layer includes a first and a second transistor, which can form a memory cell. The semiconductor device of one embodiment of the present invention includes the memory cell and thus has a function of storing data. Therefore, the semiconductor device of one embodiment of the present invention can be referred to as a storage device.

In the case where a memory cell is formed using the first and second transistors, one of the first and second transistors functions as a write transistor and the other functions as a read transistor.

The semiconductor device of one embodiment of the present invention preferably includes a transistor (OS transistor) including a metal oxide in a channel formation region. The OS transistor has a low off-state current. Thus, when the OS transistor is used in a semiconductor device that can be a storage device, stored contents can be retained for a long time. That is, a refresh operation is not required or the frequency of the refresh operation is extremely low; thus, the power consumption of the semiconductor device can be adequately reduced. Therefore, a semiconductor device with low power consumption can be provided. In addition, since the OS transistor has high frequency characteristics, the semiconductor device can perform high-speed data reading and writing. Therefore, a semiconductor device that operates at high speed can be provided.

In each of the first and second transistors, one of a source and a drain is positioned below and the other is positioned above; thus, a current flows in the vertical direction. In other words, the channel length direction of the first and second transistors is the vertical direction. That is, the first and second transistors have a vertical structure. A transistor having a vertical structure can be miniaturized as compared with a transistor having what is called a horizontal structure, in which a current flows in the horizontal direction. Accordingly, the first and second transistors each having a vertical structure can be arranged at high density and thus the semiconductor device can be highly integrated. In addition, a transistor having a vertical structure can have a larger channel width per unit area than a transistor having a horizontal structure. Thus, the density of a current flowing through the transistor is increased, the on-state current of the transistor is increased, and the frequency characteristics can be improved.

An OS transistor has high resistance to a short-channel effect. Accordingly, as compared with a transistor including silicon in a channel formation region (also referred to as a Si transistor), an OS transistor is hardly affected by a substrate floating effect even with a vertical structure, and can easily have a short channel length even with a thick gate insulating film. That is, a gate leakage current can be reduced, so that the storage device can have improved retention characteristics.

The short-channel effect refers to degradation of electrical characteristics that becomes obvious along with miniaturization of a transistor (a decrease in channel length). Examples of the short-channel effect include drain-induced barrier lowering, electron velocity saturation, and hot-carrier degradation. Specific examples of the short-channel effect include a decrease in threshold voltage, an increase in subthreshold swing value, and an increase in leakage current. The subthreshold swing value refers to the amount of change in gate voltage which makes the drain current change by one digit in a subthreshold region at a constant drain voltage.

The channel length of the transistor having the vertical structure included in the semiconductor device of one embodiment of the present invention can be controlled by the thickness of an oxide semiconductor, so that a processing variation in the channel length can be smaller than that of a transistor having a horizontal structure. That is, a variation in the density of a current flowing through the transistor can be suppressed. Consequently, the frequency characteristics can be improved.

### <Structure Example of Semiconductor Device>

Structure examples of a semiconductor device of one embodiment of the present invention are described below. Note that components of the semiconductor device of this embodiment may each have either a single-layer structure or a stacked-layer structure.

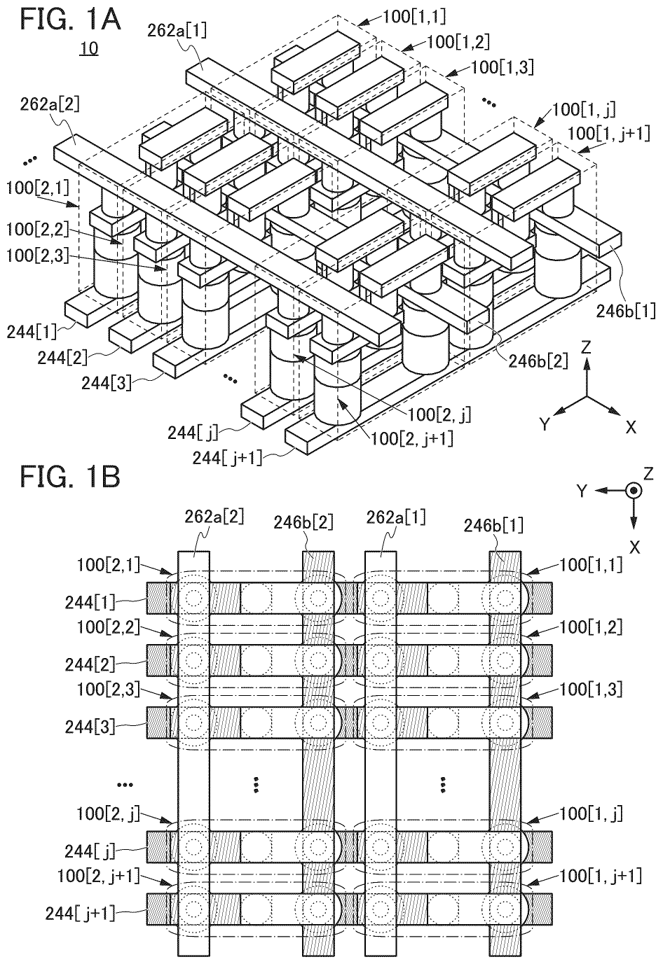

FIG. 1A and FIG. 1B are a perspective view and a top view illustrating a structure example of the semiconductor device of one embodiment of the present invention. FIG. 1A is a perspective view of a semiconductor device 10. FIG. 1B is a top view of the semiconductor device 10.

Note that in the drawings and the like in this specification, arrows indicating the X direction, the Y direction, and the Z direction are illustrated in some cases. In this specification and the like, the “X direction” is a direction along the X-axis, and the forward direction and the reverse direction are not distinguished in some cases, unless otherwise specified. The same applies to the “Y direction” and the “Z direction”. The X direction, the Y direction, and the Z direction are directions intersecting with each other. More specifically, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

The semiconductor device 10 includes a plurality of memory cells 100. FIG. 1A illustrates an example of the semiconductor device 10 where the plurality of memory cells 100 are arranged in a matrix of m rows and n columns (m and n are each independently an integer greater than or equal to 2). A memory cell array can be formed when the memory cells 100 are arranged in a matrix.

Note that the rows and the columns extend in directions orthogonal to each other. In this embodiment, the X direction represents “row” and the Y direction represents “column”. Note that the X direction may represent “column” and the Y direction may represent “row”.

In FIG. 1A, the memory cell 100 in the first row and the first column is denoted by a memory cell 100[1, 1], the memory cell 100 in the second row and the first column is denoted by a memory cell 100[2, 1], and the memory cell 100 in the first row and the second column is denoted by a memory cell 100[1, 2]. Although not illustrated in FIG. 1A, the memory cell 100 in the m-th row and the n-th column is denoted by a memory cell 100[m, n].

In this embodiment and the like, a given row is denoted as an i-th row in some cases. A given column is denoted as a j-th column in some cases. Thus, i is an integer greater than or equal to 1 and less than or equal to m, and j is an integer greater than or equal to 1 and less than or equal to n. In this embodiment and the like, the memory cell 100 in the i-th row and the j-th column is referred to as a memory cell 100[i, j]. Note that in this embodiment and the like, “i+α” (α is a positive or negative integer) is not below 1 and does not exceed m. Similarly, “j+α” is not below 1 and does not exceed n.

The semiconductor device 10 includes m conductors 262a extending in the row direction, m conductors 246b extending in the row direction, and n conductors 244 extending in the column direction. In this embodiment and the like, the i-th conductor 262a provided in the i-th row is referred to as a conductor 262a[i] and the i-th conductor 246b provided in the i-th row is referred to as a conductor 246b[i]. Similarly, the j-th conductor 244 provided in the j-th column is referred to as a conductor 244[j].

The memory cell 100[i, j] is electrically connected to each of the conductor 262a[i], the conductor 246b[i], and the conductor 244[j]. In other words, the conductor 262a[i] is electrically connected to n memory cells (the memory cell 100[i, 1] to the memory cell 100[i, n]), the conductor 246b[i] is electrically connected to n memory cells (the memory cell 100[i, 1] to the memory cell 100[i, n]), and the conductor 244[j] is electrically connected to m memory cells (the memory cell 100[1, j]) to the memory cell 100[m, j].

The conductor 262a hereinafter refers to any one or more of the conductor 262a[1] to the conductor 262a[m], and the conductor 246b hereinafter refers to any one or more of the conductor 246b[1] to the conductor 246b[m]. Similarly, the conductor 244 hereinafter refers to any one or more of the conductor 244[1] to the conductor 244[n]. Similarly, the memory cell 100 hereinafter refers to any one or more of the memory cell 100[1, 1] to the memory cell 100[m, n].

The conductor 262a, the conductor 246b, and the conductor 244 function as wirings.

### [Memory Cell 100]

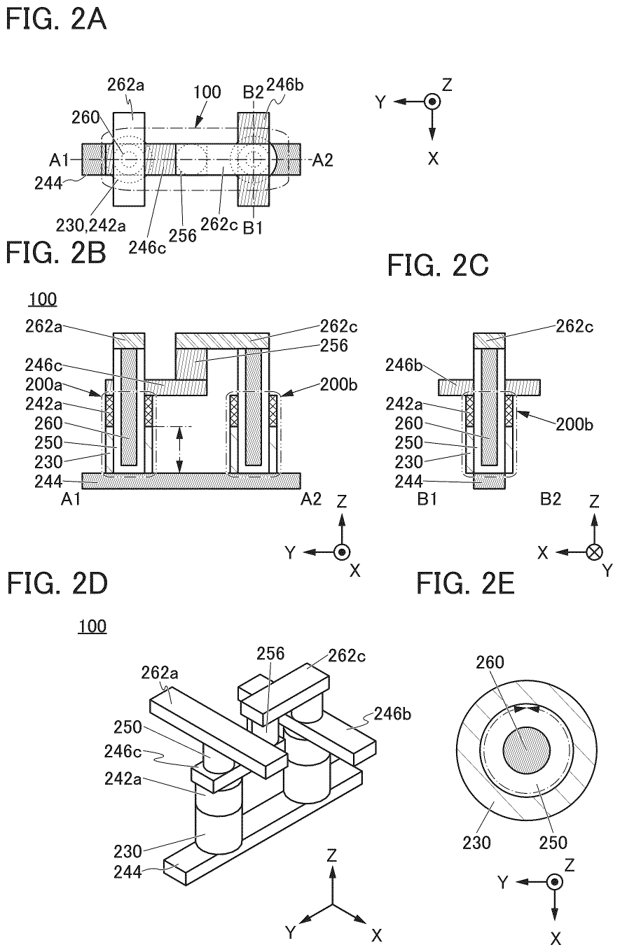

FIG. 2A to FIG. 2E are top views, cross-sectional views, and a perspective view illustrating a structure example of a memory cell included in the semiconductor device of one embodiment of the present invention. FIG. 2A is a top view of the memory cell 100. FIG. 2B is a cross-sectional view of the memory cell 100 and is also a cross-sectional view of a portion indicated by the dashed-dotted line A1-A2 in FIG. 2A. FIG. 2C is a cross-sectional view of the memory cell 100 and is also a cross-sectional view of a portion indicated by the dashed-dotted line B1-B2 in FIG. 2A. FIG. 2D is a perspective view of the memory cell 100.

Since the memory cell 100[1, 1] to the memory cell 100[m, n] have the same structure, they are denoted as the memory cell 100 in FIG. 2 and the like, and identification signs are not added thereto.

The memory cell 100 illustrated in FIG. 2 includes a transistor 200a and a transistor 200b. Note that the transistor 200a is provided in the same layer as the transistor 200b. When the transistor 200a and the transistor 200b are provided in the same layer, the transistor 200a and the transistor 200b can be manufactured at the same time and the manufacturing process of the semiconductor device can be shortened as compared with the structure where the transistor 200a and the transistor 200b are provided in different layers.

In the following description of matters common to components distinguished from each other using letters of the alphabet, reference numerals without the letters of the alphabet are sometimes used. For example, in the description of matters common to the transistor 200a and the transistor 200b, the term “transistor 200” is used in some cases.

The transistor 200 includes an oxide 230, a conductor 242a over the oxide 230, an insulator 250, and a conductor 260 over the insulator 250. As illustrated in FIG. 2A to FIG. 2C, a side surface of the conductor 242a is aligned with a side surface of the oxide 230. In addition, the oxide 230 and the conductor 242a each have a cylindrical shape (also referred to as a circular column shape). Note that the cylindrical shapes that the oxide 230 and the conductor 242a have extend in the Z direction. The oxide 230 and the conductor 242a each have an opening. Note that the openings that the oxide 230 and the conductor 242a have are sometimes referred to as opening portions, hollows, hollow portions, or the like. The opening that the oxide 230 has and the opening that the conductor 242a has overlap with each other. The top surface shapes of the oxide 230 and the conductor 242a each have a hollow circular shape. In other words, the oxide 230 and the conductor 242a each have a cylindrical shape provided with a hollow portion. Note that a cylindrical shape provided with a hollow portion is referred to as a hollow cylindrical shape in some cases.

Note that in this specification and the like, the top surface shape of a component means the shape of the outline of the component in a plan view. A plan view means a view to observe the component from a normal direction of a surface where the component is formed or from a normal direction of a surface of a support (e.g., a substrate) where the component is formed.

Although FIG. 2A illustrates the structure in which the top surface shapes of the oxide 230 and the conductor 242a each have a hollow circular shape, the present invention is not limited thereto. For example, the top surface shapes of the oxide 230 and the conductor 242a may have a hollow elliptical shape, a hollow polygonal shape, or a hollow polygonal shape with rounded corners. The polygonal shape here means a triangle, a quadrangle, a pentagon, a hexagon, and the like.

The insulator 250 and the conductor 260 are placed inside the openings that the oxide 230 and the conductor 242a have. The insulator 250 includes a region in contact with a side surface of the conductor 260 and a region in contact with the bottom surface of the conductor 260.

The memory cell 100 includes the conductor 244. The oxide 230 is electrically connected to the conductor 244. In the structure illustrated in FIG. 2B, the oxide 230 includes a region in contact with at least part of the top surface of the conductor 244.

The conductor 260 functions as a gate electrode of the transistor 200. The insulator 250 functions as a gate insulator of the transistor 200. Note that the gate insulator is also referred to as a gate insulating layer or a gate insulating film in some cases. The conductor 244 includes a region functioning as one of a source electrode and a drain electrode of the transistor 200. The conductor 242a functions as the other of the source electrode and the drain electrode of the transistor 200. At least part of a region that is of the oxide 230 and overlaps with the conductor 260 functions as a channel formation region of the transistor 200. Note that the region that is of the oxide 230 and overlaps with the conductor 260 can be rephrased as a region that is of the oxide 230 and faces the conductor 260. Alternatively, the region that is of the oxide 230 and overlaps with the conductor 260 can be rephrased as a region that is of the oxide 230 and faces the conductor 260 with the insulator 250 therebetween. That is, at least part of the region that is of the oxide 230 and faces the conductor 260 functions as the channel formation region of the transistor 200.

The transistor 200 is what is called a vertical transistor in which one of the source electrode and the drain electrode is positioned below the channel formation region and the other thereof is positioned above the channel formation region, whereby a current flows in the vertical direction. The transistor 200 has a structure in which the channel formation region surrounds the gate electrode. Thus, the transistor 200 can be referred to as a transistor having a CAA (Channel-All-Around) structure.

Note that the channel length of the transistor 200 refers to the length of a region where the semiconductor (or a portion where a current flows in the semiconductor when the transistor is in the on state) and the gate electrode overlap with each other, the length of a region where the semiconductor and the gate electrode face each other, or the distance between the source (the source region or the source electrode) and the drain (the drain region or the drain electrode) in the channel formation region in the cross-sectional view. That is, the channel length of the transistor 200 corresponds to the thickness of the oxide 230. Thus, the channel length of the transistor 200 can be adjusted by the thickness of the oxide 230, which makes it possible to form the transistor 200 with a short channel length when the thickness of the oxide 230 is made thin. When the oxide 230 is deposited using a film formation method enabling thin film formation, the channel length of the transistor 200 can be, for example, less than or equal to 30 nm, less than or equal to 20 nm, less than or equal to 15 nm, less than or equal to 10 nm, less than or equal to 8 nm, or less than or equal to 5 nm. In other words, the oxide 230 is preferably formed to have a thickness greater than or equal to 3 nm and less than or equal to 30 nm, for example. Since the OS transistor has an extremely low off-state current, the transistor 200 even with the above channel length can have the reduced off-state current. In FIG. 2B, the channel length of the transistor 200 is indicated by a dashed-dotted double-headed arrow.

Meanwhile, in the case where a transistor operates in a saturation region, the channel length of the transistor is sometimes lengthened so that its electrical characteristics in the saturation region can be improved. Since the transistor 200 is a vertical transistor, the area occupied by the transistor 200 in the top view does not depend on the thickness of the oxide 230. Thus, the thickness of the oxide 230 corresponding to the channel length may be made large. For example, the thickness of the oxide 230 may be greater than 30 nm and less than or equal to 100 nm.

From the above, the thickness of the oxide 230 is greater than or equal to 3 nm and less than or equal to 100 nm, preferably greater than or equal to 3 nm and less than or equal to 30 nm, further preferably greater than or equal to 5 nm and less than or equal to 30 nm, still further preferably greater than or equal to 5 nm and less than or equal to 15 nm.

The channel width of the transistor 200 refers to, in the top view, the length of a region where the semiconductor (or a portion where a current flows in the semiconductor when the transistor is in the on state) and the gate electrode overlap with each other, the length of a region where the semiconductor and the gate electrode face each other, or the length of the channel formation region in a direction perpendicular to the channel length direction in the channel formation region. That is, the channel width of the transistor 200 corresponds to a circumference of the hollow that the oxide 230 has. Note that in one transistor, channel widths in all regions do not necessarily have the same value. In other words, the channel width of one transistor is not fixed to one value in some cases. Examples of such a case include a case where the side surface of the hollow portion of the oxide 230 has a tapered shape in a cross-sectional view of the transistor as described later. Therefore, in this specification and the like, the channel width is any one of values, the maximum value, the minimum value, or the average value in a channel formation region. In FIG. 2E, the channel width of the transistor 200 is indicated by a dashed-dotted double-headed arrow. Note that FIG. 2E is a cross-sectional view of the XY plane including the oxide 230.

Note that the values of the channel length and the channel width can be determined by analyzing a cross-sectional TEM image, for example.

The memory cell 100 includes the conductor 262a and a conductor 262c, the conductor 246b and a conductor 246c, and a conductor 256. The conductor 262a is provided in the same layer as the conductor 262c. The conductor 246b is provided in the same layer as the conductor 246c.

The conductor 262a is electrically connected to the conductor 260 included in the transistor 200a. In the structure illustrated in FIG. 2B, the conductor 262a includes a region in contact with the top surface of the conductor 260 included in the transistor 200a.

The conductor 262c is electrically connected to the conductor 260 included in the transistor 200b. In the structure illustrated in FIG. 2B, the conductor 262c includes a region in contact with the top surface of the conductor 260 included in the transistor 200b.

The conductor 246b is electrically connected to the conductor 242a included in the transistor 200b. Furthermore, the conductor 246b is electrically connected to the oxide 230 included in the transistor 200b through the conductor 242a included in the transistor 200b. In other words, the conductor 242a included in the transistor 200b is provided between the oxide 230 included in the transistor 200b and the conductor 246b. In the structure illustrated in FIG. 2C, the conductor 246b includes a region in contact with at least part of the top surface of the conductor 242a included in the transistor 200b.

The conductor 246c is electrically connected to the conductor 242a included in the transistor 200a. Furthermore, the conductor 246c is electrically connected to the oxide 230 included in the transistor 200a through the conductor 242a included in the transistor 200a. In other words, the conductor 242a included in the transistor 200a is provided between the oxide 230 included in the transistor 200a and the conductor 246c. In the structure illustrated in FIG. 2B, the conductor 246c includes a region in contact with at least part of the top surface of the conductor 242a included in the transistor 200a.

The conductor 256 is electrically connected to the conductor 262c and the conductor 246c. In other words, the conductor 246c is electrically connected to the conductor 262c through the conductor 256.

As illustrated in FIG. 2A, the conductor 262a and the conductor 246b are provided to extend in the X direction. That is, the direction in which the conductor 262a extends is the same as the direction in which the conductor 246b extends. The conductor 244 is provided to extend in the Y direction. That is, the conductor 244 extends in the direction orthogonal to the direction in which the conductor 262a extends. Furthermore, the conductor 244 extends in the direction orthogonal to the direction in which the conductor 246b extends.

As described above, the transistor 200 is a vertical transistor. The vertical transistor can be formed at a cross point where wirings with the minimum pitch intersect with each other. Specifically, the transistor 200a is formed in a region where the conductor 244 and the conductor 262a intersect with each other, and the transistor 200b is formed in a region where the conductor 244 and the conductor 246b intersect with each other. Thus, miniaturization or high integration of the semiconductor device can be achieved.

In the transistor 200, a metal oxide functioning as a semiconductor (hereinafter also referred to as an oxide semiconductor) is preferably used for the oxide 230 including the channel formation region.

The metal oxide functioning as a semiconductor preferably has a band gap wider than or equal to 2.0 eV, further preferably wider than or equal to 2.5 eV. With the use of a metal oxide having a wide band gap, the off-state current of the transistor can be reduced.

As the metal oxide 230, a metal oxide such as indium oxide, gallium oxide, or zinc oxide is preferably used, for example. Alternatively, as the metal oxide 230, a metal oxide containing two or three selected from indium, an element M, and zinc is preferably used, for example. Note that the element M is one or more kinds selected from gallium, aluminum, silicon, boron, yttrium, tin, antimony, copper, vanadium, beryllium, titanium, iron, nickel, germanium, zirconium, molybdenum, lanthanum, cerium, neodymium, hafnium, tantalum, tungsten, and magnesium. In particular, the element M is preferably one or more kinds selected from aluminum, gallium, yttrium, and tin. Note that a metal oxide containing indium, the element M, and zinc is referred to as In-M-Zn oxide in some cases.

Specifically, as the oxide 230, a metal oxide having a composition where In:M:Zn=4:2:3 [atomic ratio] or a neighborhood thereof, a metal oxide having a composition where In:M:Zn=1:1:1 [atomic ratio] or a neighborhood thereof, a metal oxide having a composition where In:M:Zn=1:1:1.2 [atomic ratio] or a neighborhood thereof, or a metal oxide having a composition where In:M:Zn=1:1:2 [atomic ratio] or a neighborhood thereof can be used. Note that a composition in the neighborhood includes the range of ±30% of an intended atomic ratio.

It is particularly preferable to use an oxide containing indium (In), gallium (Ga), and zinc (Zn) (also referred to as IGZO) for the oxide 230. Alternatively, an oxide containing indium (In), aluminum (Al), and zinc (Zn) (also referred to as IAZO) may be used for the oxide 230. Alternatively, an oxide containing indium (In), aluminum (Al), gallium (Ga), and zinc (Zn) (also referred to as IAGZO, IGAZO, or AGIZO) may be used for the oxide 230.

Note that in this specification and the like, a metal oxide containing nitrogen is also collectively referred to as a metal oxide in some cases. A metal oxide containing nitrogen may be referred to as a metal oxynitride.

A vertical transistor including silicon in a channel formation region has unstable electrical characteristics due to the substrate floating effect. Meanwhile, a metal oxide such as IGZO, IAZO, or IAGZO has a large effective mass of a hole. Thus, by using such a metal oxide for a channel formation region, hole accumulation in the channel formation region is reduced, so that a vertical transistor that is less affected or substantially not affected by the substrate floating effect can be fabricated. That is, the use of the above metal oxide as the oxide 230 imparts stable electrical characteristics to the transistor 200. Thus, a transistor having favorable electrical characteristics and a semiconductor device including the transistor can be provided. A transistor with a small variation in electrical characteristics and a semiconductor device including the transistor can be provided.

An oxide semiconductor having crystallinity is preferably used for the oxide 230. Examples of an oxide semiconductor having crystallinity include a CAAC-OS (c-axis aligned crystalline oxide semiconductor), an nc-OS (nanocrystalline oxide semiconductor), a polycrystalline oxide semiconductor, and a single-crystal oxide semiconductor. For the oxide 230, the CAAC-OS or the nc-OS is preferably used, and the CAAC-OS is particularly preferably used.

The CAAC-OS is a metal oxide having a dense structure with high crystallinity and small amounts of impurities and defects (e.g., oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. As the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including the CAAC-OS is physically stable. Therefore, the metal oxide including the CAAC-OS is resistant to heat and has high reliability.

When an oxide having crystallinity, such as CAAC-OS, is used as the oxide 230, oxygen extraction from the oxide 230 by the conductor 244 and the conductor 242a can be inhibited. This can suppress oxygen extraction from the oxide 230 even when heat treatment is performed; thus, the transistor is stable with respect to high temperatures in a manufacturing process (what is called thermal budget). Furthermore, it is possible to inhibit a reduction in the conductivity of the conductor 244 and the conductor 242a.

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal (also referred to as a nanocrystal). Furthermore, there is no regularity of crystal orientation between different nanocrystals in the nc-OS, and thus the orientation in the whole film is not observed. That is, in the case where the nc-OS is used as the oxide 230, the oxide 230 has uniform film characteristics regardless of the direction of carriers flowing in the oxide 230; thus, the transistor has stable electrical characteristics.

Oxide semiconductors have various structures with different properties. The oxide 230 may include two or more kinds of the CAAC-OS, the nc-OS, an amorphous-like oxide semiconductor (a-like OS), an amorphous oxide semiconductor, a polycrystalline oxide semiconductor, and a CAC-OS (cloud-aligned composite oxide semiconductor).

When the CAAC-OS film is subjected to structural analysis by out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS. For example, a plurality of bright spots are observed in the electron diffraction pattern of the CAAC-OS film. Note that one spot and another spot are observed point-symmetrically with a spot of an incident electron beam passing through a sample (also referred to as a direct spot) as a symmetric center.

In some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or less than the diameter of a nanocrystal (e.g., greater than or equal to 1 nm and less than or equal to 30 nm).

The oxide 230 can be rephrased as a semiconductor layer including the channel formation region of the transistor 200. Note that a material that can be used for the semiconductor layer is not limited to a metal oxide functioning as a semiconductor (an oxide semiconductor). For example, a semiconductor such as single crystal silicon, polycrystalline silicon, or amorphous silicon may be used for the semiconductor layer, and low-temperature polysilicon (LTPS) may be used, for example.

As the semiconductor layer, the transition metal chalcogenide functioning as a semiconductor may be used; for example, molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), or zirconium selenide (typically ZrSe₂) may be used.

The oxide 230 can be deposited by a sputtering method, a chemical vapor deposition (CVD) method, a molecular beam epitaxy (MBE) method, a pulsed laser deposition (PLD) method, an atomic layer deposition (ALD) method, or the like. It is particularly preferable to employ a sputtering method for deposition of the oxide 230. With use of a sputtering method, a metal oxide having crystallinity can be formed. The sputtering method is a deposition method enabling thin film formation and accordingly can be suitably used for the deposition of the oxide 230.

In the case of a transistor in which the side surface of a metal oxide functioning as a semiconductor is covered with a word line with a gate insulating layer therebetween, i.e., what is called a gate all around transistor, the metal oxide is provided inside an opening portion formed in the word line or the gate insulating layer. To miniaturize the transistor, an inner wall of the opening portion needs to be as perpendicular to the substrate surface as possible. At this time, the metal oxide to be deposited requires high step coverage, so that there is a limitation on the flexibility of a method for depositing the metal oxide.

Meanwhile, the transistor 200 is fabricated in the following manner: an opening is formed in a stack of the oxide 230 and the conductor 242a, and the insulator 250 and the conductor 260 are formed inside the opening. At this time, the oxide 230 may be formed over the conductor 244, and the oxide 230 does not need to have high step coverage at the time of being deposited. Thus, a deposition method of the oxide 230 can be freely selected. For example, a sputtering method can be used for the deposition of the oxide 230, which enables a metal oxide having crystallinity to be formed.

Note that for formation of the opening or the depression, it is preferable to use a multi-patterning technique including double patterning such as LELE (Litho-Etch-Litho-Etch) and SADP (Self-Aligned Double Patterning), quadruple patterning such as SAQP (Self-Aligned Quadruple Patterning), and octuple patterning. With use of a multi-patterning technique, a fine opening or a fine depression can be formed.

In addition, a shrink agent may be used for a resist pattern so that an opening portion in the resist pattern is downsized. For example, the shrink agent is applied on a resist surface, and then heat treatment is performed. Thus, the resist reacts with the shrink agent, so that a reaction layer is formed on the resist surface. At this time, the reaction layer is formed on a side surface of the opening portion in the resist pattern; thus, the opening portion can be downsized. With use of a resist pattern with a downsized opening portion, a fine opening or a fine depression can be formed. Note that the shrink agent is referred to as a pattern shrinking agent or a hole shrinking agent in some cases.

A fine pattern may be directly formed by light exposure using EUV (Extreme Ultraviolet) light or the like.

Furthermore, patterning may be performed by a combination of the above methods.

As described above, after an oxide semiconductor that is less affected or substantially not affected by the substrate floating effect is deposited by a sputtering method, a multi-patterning technique such as SAQP is used to form a cylindrical channel having a hollow portion. With a vertical transistor structure in which a gate electrode is provided in the hollow portion, a transistor that can be miniaturized or highly integrated can be provided. With use of the transistor, a memory cell with a minimum feature size (F) less than or equal to 15 nm, for example, can be achieved. Here, the minimum feature size (F) is, for example, the width of the conductor 244 in the X direction, the width of the conductor 262a in the Y direction, or the width of the conductor 246b in the Y direction.

As the conductor 242a, for example, a nitride containing tantalum, a nitride containing titanium, a nitride containing molybdenum, a nitride containing tungsten, a nitride containing tantalum and aluminum, or a nitride containing titanium and aluminum is preferably used. In one embodiment of the present invention, a nitride containing tantalum is particularly preferable. As another example, ruthenium oxide, ruthenium nitride, an oxide containing strontium and ruthenium, or an oxide containing lanthanum and nickel may be used. These materials are preferable because they are each a conductive material that is not easily oxidized or a material that maintains the conductivity even after absorbing oxygen.

Note that hydrogen contained in the oxide 230 or the like diffuses into the conductor 242a in some cases. In particular, when a nitride containing tantalum is used for the conductor 242a, hydrogen contained in the oxide 230 or the like is likely to diffuse into the conductor 242a, and the diffusing hydrogen is bonded to nitrogen contained in the conductor 242a in some cases. That is, hydrogen contained in the oxide 230 or the like is sometimes absorbed by the conductor 242a.

The conductor 242a includes a region in contact with the oxide 230 and thus is preferably formed using a conductive material containing oxygen. When a conductive material containing oxygen is used for the conductor 242a, the conductor 242a can maintain its conductivity even when absorbing oxygen. In addition, also in the case of using an insulator containing oxygen as the insulator 250, the conductor 242a can maintain its conductivity, which is preferable. Examples of the conductive material containing oxygen include indium oxide containing tungsten oxide, indium oxide containing titanium oxide, indium tin oxide (also referred to as ITO), indium tin oxide containing titanium oxide, indium tin oxide to which silicon is added (also referred to as ITSO), indium zinc oxide (also referred to as IZO (a registered trademark)), and indium zinc oxide containing tungsten oxide. Examples of the conductive material containing oxygen also include ruthenium oxide, an oxide containing strontium and ruthenium, and an oxide containing lanthanum and nickel. In this specification and the like, a conductive film formed using the conductive material containing oxygen may be referred to as an oxide conductive film.

The insulator 250 is preferably formed using an insulator having a function of inhibiting diffusion of oxygen. With this structure, oxygen contained in the oxide 230 can be inhibited from diffusing into the conductor 260. Thus, formation of oxygen vacancies in the oxide 230 can be inhibited. In addition, oxidation of the conductor 260 due to oxygen contained in the oxide 230 can be inhibited. Thus, the transistor 200 can have favorable electrical characteristics and higher reliability.

As the insulator 250, an insulator containing an oxide of one or both of aluminum and hafnium is preferably used, for example. As the insulator, aluminum oxide, hafnium oxide, an oxide containing aluminum and hafnium (hafnium aluminate), an oxide containing hafnium and silicon (hafnium silicate), or the like can be used.

A high dielectric constant (high-k) material may be used for the insulator 250. When a high dielectric constant material is used for the insulator 250, the equivalent oxide thickness (EOT) of the insulator functioning as the gate insulator can be reduced. Therefore, the withstand voltage of the insulator 250 can be increased.

Examples of the high dielectric constant material include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

As the insulator 250, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, or the like may be used.

The insulator 250 extends in the Z direction. The top surface of the insulator 250 included in the transistor 200a is preferably positioned above the top surface of the conductor 246c. Thus, the conductor 246c and the conductor 262a can be prevented from being in contact with each other, and a leakage current and a short circuit between the conductor 246c and the conductor 262a can be prevented. Note that in the case where an insulator is provided between the conductor 246c and the conductor 260 included in the transistor 200a and the top surface of the insulator is positioned above the top surface of the conductor 246c, the top surface of the insulator 250 included in the transistor 200a may be positioned below the top surface of the conductor 246c.

Similarly, the top surface of the insulator 250 included in the transistor 200b is preferably positioned above the top surface of the conductor 246b. Thus, the conductor 246b and the conductor 262c can be prevented from being in contact with each other, and a leakage current and a short circuit between the conductor 246b and the conductor 262c can be prevented. Note that in the case where an insulator is provided between the conductor 246b and the conductor 260 included in the transistor 200b and the top surface of the insulator is positioned above the top surface of the conductor 246b, the top surface of the insulator 250 included in the transistor 200b may be positioned below the top surface of the conductor 246b.

Although FIG. 2B illustrates a single-layer structure of the insulator 250, the present invention is not limited to this structure, and a stacked-layer structure of two or more layers may be employed. For example, in the case where the insulator 250 has a stacked-layer structure of two layers, an insulator provided on the oxide 230 side may be formed using an insulator having a function of inhibiting diffusion of oxygen and an insulator provided on the conductor 260 side may be formed using a high dielectric constant material.

For the conductor 260, for example, a nitride containing tantalum, a nitride containing titanium, a nitride containing molybdenum, a nitride containing tungsten, a nitride containing tantalum and aluminum, a nitride containing titanium and aluminum, ruthenium nitride, or the like is preferably used. As another example, ruthenium oxide, an oxide containing strontium and ruthenium, or an oxide containing lanthanum and nickel may be used. These materials are suitable in the case where an insulating material containing oxygen is used for the insulator 250 in contact with the conductor 260 because they are conductive materials that are not easily oxidized or materials that maintain their conductivity even after absorbing oxygen.

For the conductor 260, a conductive material having a function of inhibiting diffusion of impurities such as a hydrogen atom, a hydrogen molecule, a water molecule, a nitrogen atom, a nitrogen molecule, a nitrogen oxide molecule, and a copper atom is preferably used.

Alternatively, a conductive material having a function of inhibiting diffusion of oxygen (e.g., at least one of an oxygen atom, an oxygen molecule, and the like) may be used. Examples of the conductive material having a function of inhibiting diffusion of oxygen include titanium, titanium nitride, tantalum, tantalum nitride, ruthenium, and ruthenium oxide.

In addition, when the conductor 260 has a function of inhibiting diffusion of oxygen, the conductivity of the conductor 260 can be inhibited from being lowered because of oxidation due to oxygen included in the insulator 250. As the conductive material having a function of inhibiting diffusion of oxygen, for example, titanium, titanium nitride, tantalum, tantalum nitride, ruthenium, or ruthenium oxide is preferably used.

A conductive material containing tungsten, copper, or aluminum as its main component is preferably used for the conductor 246b and the conductor 246c. The conductor 246b and the conductor 246c may each have a stacked-layer structure and, for example, may be stacked layers of titanium or titanium nitride and the above conductive material.

For the conductor 262a and the conductor 262c, a conductive material containing tungsten, copper, or aluminum as its main component is preferably used. The conductor 262a and the conductor 262c may each have a stacked-layer structure and, for example, may be stacked layers of titanium or titanium nitride and the above conductive material.

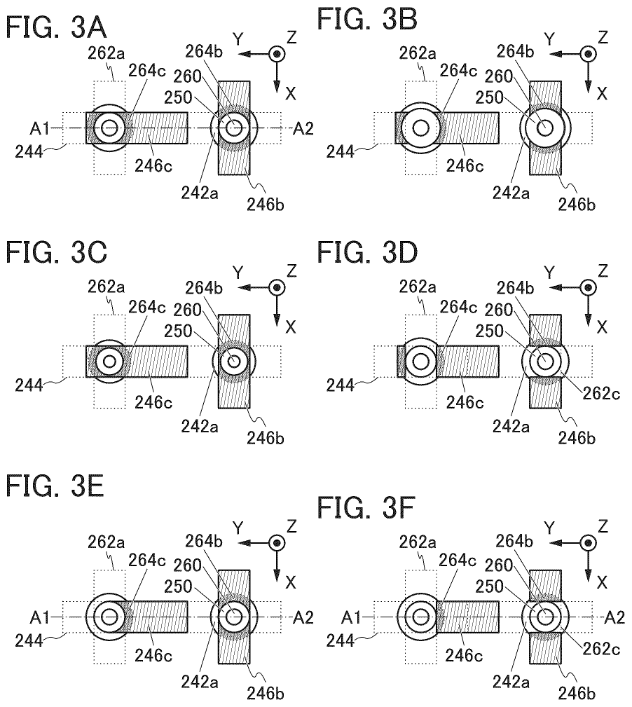

Here, a top view of the components including the conductor 242a, the insulator 250, the conductor 260, the conductor 246b, and the conductor 246c, which is extracted from the top view of FIG. 2A, is illustrated in FIG. 3A. In FIG. 3A, the outlines of the conductor 244 and the conductor 262a are indicated by dotted lines for easy understanding. FIG. 3B to FIG. 3F illustrate modification examples of the structure illustrated in FIG. 3A. FIG. 3A to FIG. 3F are also top views illustrating structure examples of the semiconductor device. In FIG. 3D and FIG. 3F, the outline of the conductor 262c is indicated by dotted lines.

A region 264b illustrated in FIG. 3A to FIG. 3F is a region where the conductor 246b and the conductor 242a provided below the conductor 246b overlap with each other. Furthermore, a region 264c illustrated in FIG. 3A to FIG. 3F is a region where the conductor 246c and the conductor 242a provided below the conductor 246c overlap with each other.

As illustrated in FIG. 3A, the conductor 246b has an opening. The insulator 250 and the conductor 260 are provided in the opening. In the case where the width of the conductor 246b in the Y direction is equal to the diameter of the outer periphery of the insulator 250 in the top view as illustrated in FIG. 3A or the case where the width of the conductor 246b in the Y direction is smaller than the diameter of the outer periphery of the insulator 250 in the top view as illustrated in FIG. 3B, the conductor 246b is divided by the insulator 250. Note that the separated parts of the conductor 246b are electrically connected to each other through the conductor 242a provided below the conductor 246b. Thus, the parts of the conductor 246b extend in the X direction with the conductor 242a below the conductor 246b provided therebetween, the conductor 246b can be regarded as extending in the X direction.

While in the case where the width of the conductor 246b in the Y direction is larger than the diameter of the outer periphery of the insulator 250 in the top view as illustrated in FIG. 3C, the conductor 246b extends in the X direction as a continuous conductor.

Although FIG. 3A to FIG. 3C illustrate the structures in which the insulator 250 and the conductor 260 are provided in the opening portion that the conductor 246b has, the present invention is not limited thereto. The conductor 260 and an insulator covering the side surface of the conductor 260 may be provided in the opening portion that the conductor 246b has. The insulator may be formed using only the insulator 250, or may be formed using the insulator 250 and an insulator provided over the insulator 250.

As long as the parts of the conductor 246b extend in the X direction with the conductor 242a below the conductor 246b provided therebetween, the conductor 246b does not necessarily have the same outline as the outer periphery of the insulator 250 in the top view. For example, as illustrated in FIG. 3D, an end portion of the conductor 246b in a region overlapping with the conductor 242a provided below the conductor 246b may be linear in the top view. FIG. 3D illustrates a structure in which the conductor 246b does not overlap with the conductor 262c.

Note that the shape of the region that is of the conductor 246c and overlaps with the conductor 242a of the transistor 200a may be similar to the shape of the conductor 246b.

Although the conductor 246c is provided on both the A1 side and the A2 side with respect to the center of the conductor 260 of the transistor 200a in FIG. 3A, the present invention is not limited to this structure. The conductor 246c is electrically connected to the conductor 242a of the transistor 200a. For example, as illustrated in FIG. 3E, the conductor 246c may be provided only on the A2 side with respect to the center of the conductor 260 of the transistor 200a. The same applies to the structure illustrated in FIG. 3D, and the conductor 246c may be provided only on the A2 side with respect to the center of the conductor 260 of the transistor 200a (see FIG. 3F).

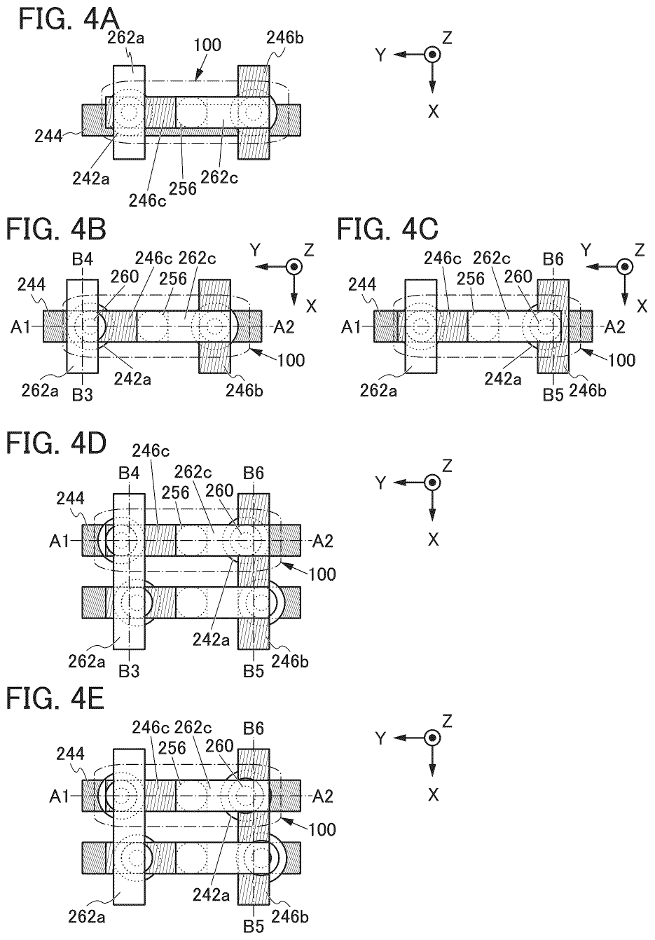

As illustrated in FIG. 2A, the conductor 244 overlaps with the center of the hollow cylindrical shape of the oxide 230 in the top view. Note that the conductor 244 does not necessarily overlap with the center of the hollow cylindrical shape that the oxide 230 has as long as the conductor 244 is in contact with at least part of the oxide 230. For example, in the top view, the conductor 244 may be placed at a position shifted in the X direction from the center of the hollow cylindrical shape that the oxide 230 has as illustrated in FIG. 4A. FIG. 4A is a top view of the memory cell 100.

FIG. 2A illustrates a structure in which a straight line that divides the width in the Y direction of the conductor 262a into two equal parts overlaps with the center of the conductor 260 included in the transistor 200a in the top view. Note that the conductor 262a is in contact with at least part of the conductor 260 included in the transistor 200a. For example, as illustrated in the top view of FIG. 4B, the conductor 262a may be placed such that the straight line that divides the width in the Y direction of the conductor 262a into two equal parts (the dashed-dotted line B3-B4) is shifted from the center of the conductor 260 in the Y direction. FIG. 4B is a top view of the memory cell 100.

FIG. 2A illustrates a structure in which a straight line that divides the width in the Y direction of the conductor 246b into two equal parts overlaps with the center of the conductor 260 included in the transistor 200b in the top view. Note that the conductor 246b is in contact with at least part of the conductor 260 included in the transistor 200b. For example, as illustrated in the top view of FIG. 4C, the conductor 246b may be placed such that the straight line that divides the width in the Y direction of the conductor 246b into two equal parts (the dashed-dotted line B5-B6) is shifted from the center of the conductor 260 in the Y direction. FIG. 4C is a top view of the memory cell 100.

In view of the structure illustrated in FIG. 4B, the center of the conductor 260 included in the transistor 200a may be positioned at a position shifted in the Y direction from the straight line that divides the width in the Y direction of the conductor 262a into two equal parts. Furthermore, in view of the structure illustrated in FIG. 4C, the center of the conductor 260 included in the transistor 200b may be positioned at a position shifted in the Y direction from the straight line that divides the width in the Y direction of the conductor 246b into two equal parts. For example, as illustrated in FIG. 4D, the center of the conductor 260 included in the transistor 200b may be positioned on the A1 side of the straight line that divides the width in the Y direction of the conductor 246b into two equal parts (the dashed-dotted line B5-B6), and the center of the conductor 260 that is adjacent in the X direction to the above-mentioned conductor 260 may be positioned on the A2 side of the dashed-dotted line B5-B6. With this structure, the distance between the transistor 200b and the transistor 200b that is adjacent in the X direction thereto can be increased without changing the distance between the conductors 244.

Note that in the case of placing the transistor 200b as illustrated in FIG. 4D, the distance between the transistor 200b and the transistor 200a included in the memory cell 100 that is adjacent in the Y direction to the memory cell 100 including the transistor 200b becomes small in some cases. Therefore, the transistor 200a is preferably placed in a manner similar to that of the transistor 200b. For example, as illustrated in FIG. 4D, the center of the conductor 260 included in the transistor 200a may be positioned on the A1 side of the straight line that divides the width in the Y direction of the conductor 262a into two equal parts (the dashed-dotted line B3-B4), and the center of the conductor 260 that is adjacent in the X direction to the above-mentioned conductor 260 may be positioned on the A2 side of the dashed-dotted line B3-B4. With this structure, a reduction in the distance between the transistor 200a and the transistor 200b can be inhibited.

With the structure illustrated in FIG. 4D, the distance between the transistors 200a, the distance between the transistors 200b, and the distance between wirings can be reduced, so that a semiconductor device with a high degree of integration of memory cells can be provided.

With the structure illustrated in FIG. 4D, the circumference of the hollow that the oxide 230 has can be increased while keeping the space between the conductors 246b and the space between the conductors 262a. Accordingly, the channel width of the transistor can be increased, and the on-state current can be increased. For example, as illustrated in FIG. 4E, the circumference of the hollow that the oxide 230 of the transistor 200b has is made larger than the circumference of the hollow that the oxide 230 of the transistor 200a has. With this structure, the channel width of the transistor 200b is increased. Thus, the on-state current of the transistor 200b functioning as a read transistor can be increased, so that a semiconductor device with a high reading speed can be provided.

Although FIG. 2B and FIG. 2C illustrate a structure in which the bottom surfaces of the conductor 246b and the conductor 246c are flat, the present invention is not limited thereto. The conductor 246b and the conductor 246c may have one or both of a protrusion and a depression, as long as the conductor 246b and the conductor 246c are in contact with at least part of the top surfaces of the conductors 242a of the transistor 200b and the transistor 200a, respectively.

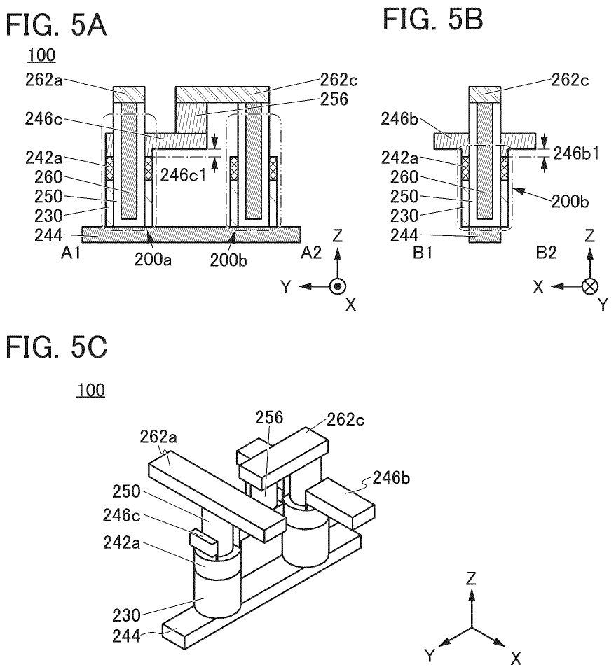

For example, as illustrated in FIG. 5A, the conductor 246c may include a protruding portion 246cl. The protruding portion 246cl is provided in a region where the conductor 246c and the conductor 242a of the transistor 200a overlap with each other. In this case, the top surface shape of the protruding portion 246cl is the same as the shape of the region 264c illustrated in any of FIG. 3A to FIG. 3F. The protruding portion 246cl is in contact with the conductor 242a of the transistor 200a.

Furthermore, for example, as illustrated in FIG. 5B, the conductor 246b may include a protruding portion 246b1. The protruding portion 246b1 is provided in a region where the conductor 246b and the conductor 242a of the transistor 200b overlap with each other. In this case, the top surface shape of the protruding portion 246b1 is the same as the shape of the region 264b illustrated in any of FIG. 3A to FIG. 3F. The protruding portion 246b1 is in contact with the conductor 242a of the transistor 200a.

Note that a method for forming the conductor 246b and the conductor 246c having the protruding portions will be described later.

FIG. 5C is a perspective view of the memory cell 100 in which the conductor 246b and the conductor 246c each have a protruding portion and the conductor 246b and the conductor 246c have the top surface shape illustrated in FIG. 3D.

### [Memory Cell 100A]

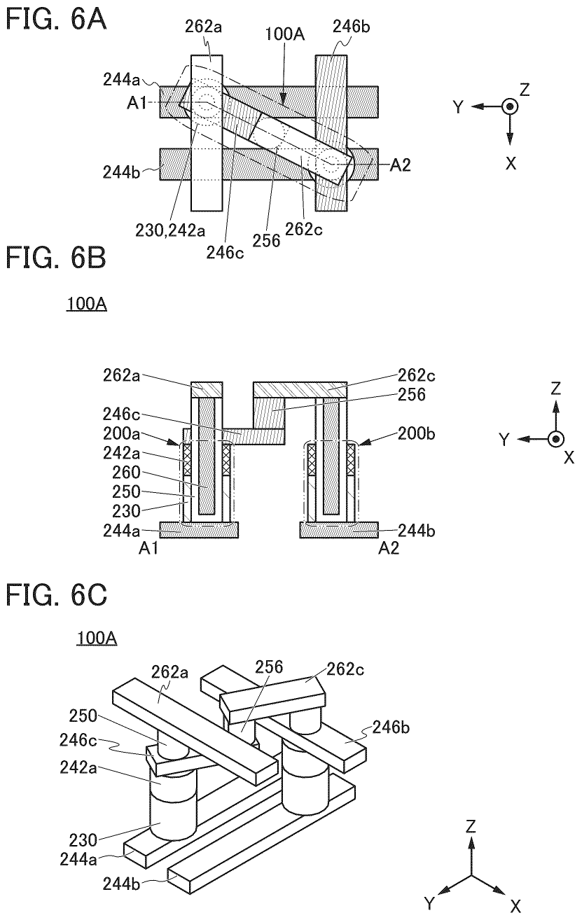

FIG. 6A to FIG. 6C illustrate a structure example different from that of the above-described memory cell 100. Note that in the memory cell described below, components having the same functions as the components included in the above-described memory cell 100 are denoted by the same reference numerals. Furthermore, differences from the above-described memory cell 100 are mainly described below, and common portions are not described.

FIG. 6A is a top view of a memory cell 100A, FIG. 6B is a cross-sectional view of the memory cell 100A, and FIG. 6C is a perspective view of the memory cell 100A. The memory cell 100A is different from the memory cell 100 illustrated in FIG. 2 in including a conductor 244a and a conductor 244b instead of the conductor 244.

The conductor 244a is electrically connected to the oxide 230 included in the transistor 200a, and the conductor 244b is electrically connected to the oxide 230 included in the transistor 200b. In FIG. 6, the conductor 244a and the conductor 244b are provided to extend in the Y direction. That is, the conductor 244a extends in the direction orthogonal to the direction in which the conductor 262a extends. In addition, the conductor 244b extends in the direction orthogonal to the direction in which the conductor 246b extends.

The conductor 244a has a function of one of a source electrode and a drain electrode of the transistor 200a and a function of a wiring. The conductor 244b has a function of one of a source electrode and a drain electrode of the transistor 200b and a function of a wiring.

With the above-described structure, a write bit line and a read bit line of the memory cell can be independent of each other. Note that the structure of the memory cell will be described in Embodiment 2.

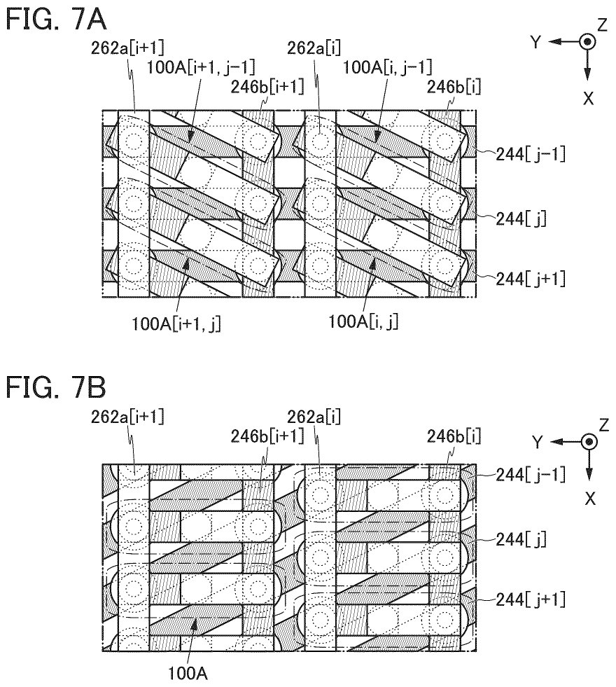

FIG. 7A is a top view of a memory cell array in which the memory cells 100A illustrated in FIG. 6 are arranged in a matrix. In FIG. 7A, the conductor 262a and the conductor 246b extend in the X direction, the conductor 244 extends in the Y direction, and a line segment connecting the transistor 200a and the transistor 200b included in the memory cell 100A is inclined in the X direction.

As illustrated in FIG. 7A, one conductor 244 is electrically connected to a first memory cell and a second memory cell that is adjacent in the X direction to the first memory cell. For example, in the memory cell positioned in the i-th row, the conductor 244[j] is electrically connected to a memory cell 100A[i, j−1] and a memory cell 100A[i, j]. That is, the conductor 244[j] corresponds to the conductor 244b of the memory cell 100A[i, j−1] and the conductor 244a of the memory cell 100A[i, j].

Note that the present invention is not limited to the above structure. For example, as illustrated in FIG. 7B, the conductor 262a and the conductor 246b may extend in the X direction, the conductor 244 may be inclined in the X direction and extend, and the line segment connecting the transistor 200a and the transistor 200b included in the memory cell 100A may be parallel to the Y direction. With this structure, the memory density of the semiconductor device can be further increased in some cases.

### [Memory Cell 100B]

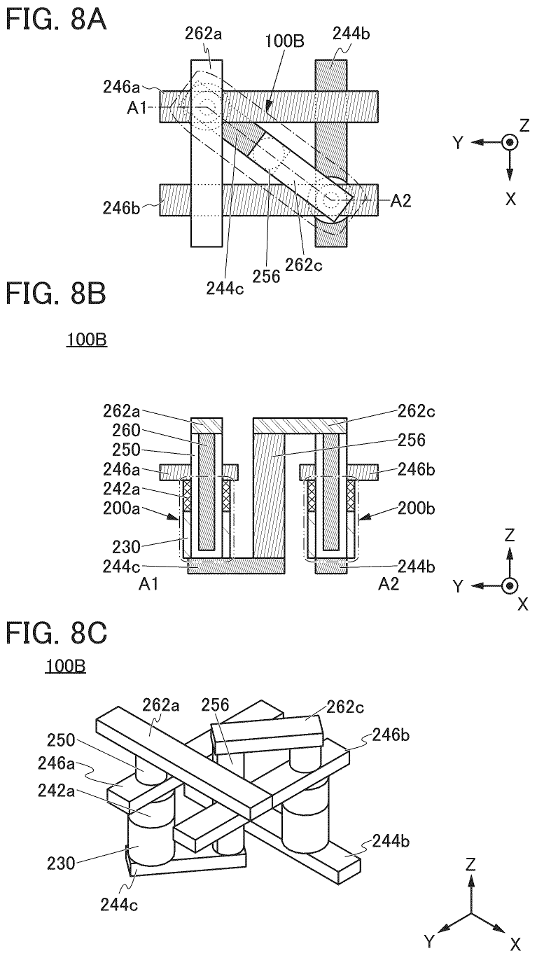

FIG. 8A to FIG. 8C illustrate a structure example different from those of the above-described memory cell 100 and memory cell 100A. Note that in the memory cell described below, components having the same functions as the components included in the above-described memory cell 100 and memory cell 100A are denoted by the same reference numerals.

Furthermore, differences from the above-described memory cell 100 and memory cell 100A are mainly described below, and common portions are not described.

FIG. 8A is a top view of a memory cell 100B, FIG. 8B is a cross-sectional view of the memory cell 100B, and FIG. 8C is a perspective view of the memory cell 100B.

The memory cell 100B includes the transistor 200a and the transistor 200b, the conductor 244b and a conductor 244c, a conductor 246a and the conductor 246b, the conductor 256, and the conductor 262a and the conductor 262c.

The conductor 244b is electrically connected to the oxide 230 included in the transistor 200b, and the conductor 244c is electrically connected to the oxide 230 included in the transistor 200a.

The conductor 246a is electrically connected to the conductor 242a included in the transistor 200a, and the conductor 246b is electrically connected to the conductor 242a included in the transistor 200b.

The conductor 256 is electrically connected to the conductor 244c and the conductor 262c.

In FIG. 8, the conductor 262a and the conductor 244b are provided to extend in the X direction, the conductor 246a and the conductor 246b are provided to extend in the Y direction, and the line segment connecting the transistor 200a and the transistor 200b is inclined in the X direction.

With the above-described structure, a write bit line and a read bit line of the memory cell can be independent of each other.

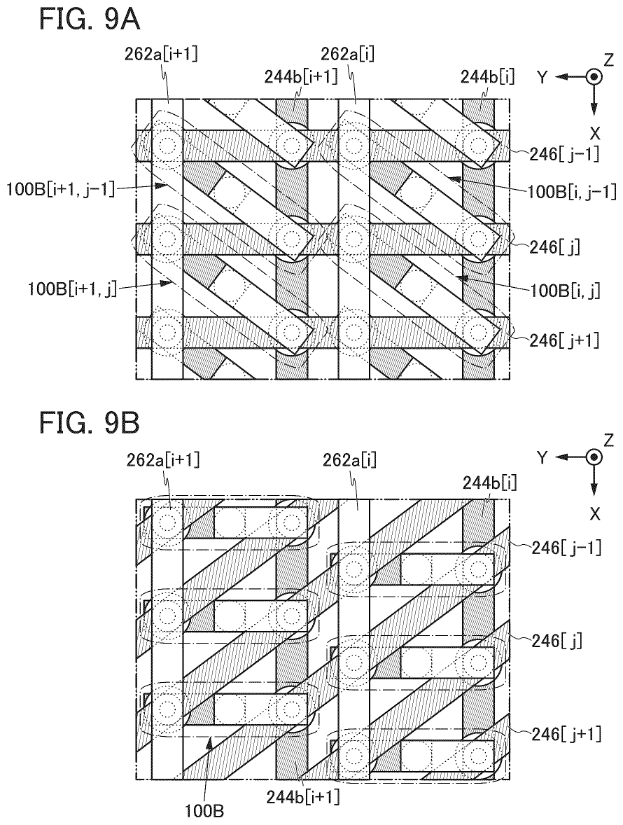

FIG. 9A is a top view of a memory cell array in which the memory cells 100B illustrated in FIG. 8 are arranged in a matrix. In FIG. 9A, the conductor 262a and the conductor 244b extend in the X direction, the conductor 246 extends in the Y direction, and a line segment connecting the transistor 200a and the transistor 200b included in the memory cell 100B is inclined in the X direction.

As illustrated in FIG. 9A, one conductor 246 is electrically connected to a first memory cell and a second memory cell that is adjacent in the X direction to the first memory cell. For example, in the memory cell positioned in the i-th row, a conductor 246[j] is electrically connected to a memory cell 100B[i, j−1] and a memory cell 100B[i, j]. That is, the conductor 246[j] corresponds to the conductor 246b of the memory cell 100B[i, j−1] and the conductor 246a of the memory cell 100B[i, j].

Note that the present invention is not limited to the above structure. For example, as illustrated in FIG. 9B, the conductor 262a and the conductor 244b may extend in the X direction, the conductor 246 may be inclined in the X direction and extend, and the line segment connecting the transistor 200a and the transistor 200b included in the memory cell 100B may be parallel to the Y direction. With this structure, the memory density of the semiconductor device can be further increased in some cases.

### [Memory Cell 100C]

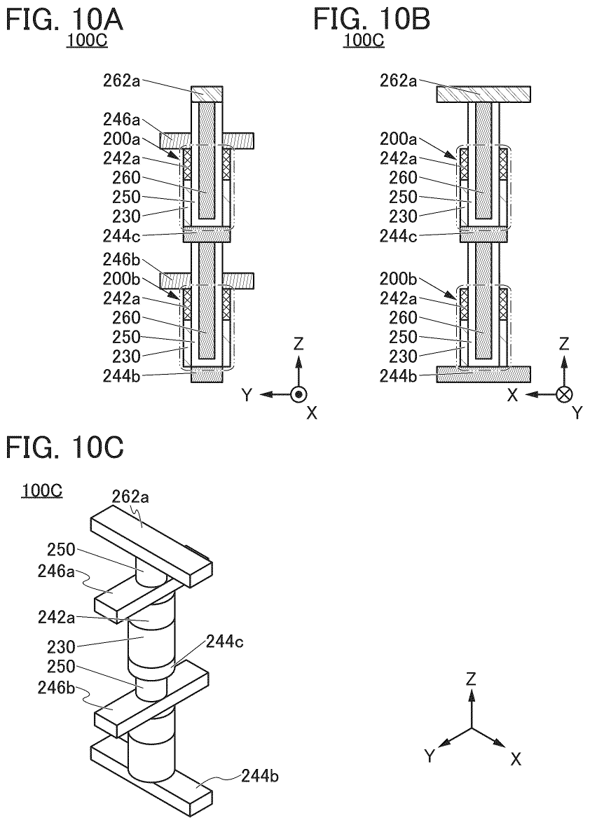

FIG. 10C to FIG. 10B illustrate a structure example different from those of the above-described memory cell 100, memory cell 100A, and memory cell 100B. Note that in the memory cell described below, components having the same functions as the components included in the above-described memory cell 100, memory cell 100A, and memory cell 100B are denoted by the same reference numerals. Furthermore, differences from the above-described memory cell 100, memory cell 100A, and memory cell 100B are mainly described below, and common portions are not described.

FIG. 10A and FIG. 10B are cross-sectional views of the memory cell 100A, and FIG. 10C is a perspective view of a memory cell 100C. The memory cell 100C is mainly different from the above-described memory cell 100, memory cell 100A, and memory cell 100B in that the transistor 200a and the transistor 200b are stacked.

The memory cell 100C includes the transistor 200a and the transistor 200b, the conductor 244b and the conductor 244c, the conductor 246a and the conductor 246b, and the conductor 262a.

The conductor 244c is electrically connected to the oxide 230 included in the transistor 200a and the conductor 260 included in the transistor 200b. That is, the oxide 230 included in the transistor 200a is electrically connected to the conductor 260 included in the transistor 200b through the conductor 244c.

In the memory cell 100B, the oxide 230 included in the transistor 200a and the conductor 260 included in the transistor 200b are electrically connected to each other through the conductor 244c, the conductor 256, and the conductor 262c; while in the memory cell 100C, the oxide 230 included in the transistor 200a and the conductor 260 included in the transistor 200b are electrically connected to each other only through the conductor 244c. With the structure of the memory cell 100C, the number of steps in the manufacturing process of the semiconductor device can be reduced and the productivity can be improved. In addition, a region for placing the conductor 256 does not need to be provided, whereby the memory density of the semiconductor device can be further increased.

In the case where the transistor 200a and the transistor 200b are stacked as illustrated in FIG. 10, the thickness of the oxide 230 included in the transistor 200a and the thickness of the oxide 230 included in the transistor 200b can be different from each other. In other words, the transistor 200a and the transistor 200b can have different channel lengths.

An increase in the channel length of the transistor can reduce a variation in Vth of the transistor. Thus, for example, the thickness of the oxide 230 included in the transistor 200b is made larger than the thickness of the oxide 230 included in the transistor 200a. In this case, the transistor 200b functioning as a read transistor has a large channel length, so that a memory cell that allows highly accurate reading can be provided.

When the channel length is shorter, the on-state resistance becomes lower and thus a transistor capable of high-speed operation can be provided. Thus, for example, the thickness of the oxide 230 included in the transistor 200a is made smaller than the thickness of the oxide 230 included in the transistor 200b. In this case, the transistor 200a functioning as a write transistor has a short channel length, so that a memory cell that allows high-speed writing can be provided. Moreover, when the thickness of the oxide 230 included in the transistor 200b is made large, the transistor 200b functioning as a read transistor has a long channel length, so that a memory cell that allows high-speed writing and highly accurate reading can be provided.

In the structure illustrated in FIG. 10, the transistor 200a and the transistor 200b are not provided in the same layer and thus may have different structures. For example, one of the transistor 200a and the transistor 200b may be a planar transistor, a staggered transistor, or an inverted staggered transistor, for example. The transistor structure may be either a top-gate structure or a bottom-gate structure. Furthermore, gates may be provided above and below a semiconductor layer where a channel is formed.

In the structure illustrated in FIG. 10, the semiconductor layer of the transistor 200a and the semiconductor layer of the transistor 200b may be formed using the same material or different materials.

Other examples of the semiconductor material that can be used for the semiconductor layer of one of the transistor 200a and the transistor 200b include a single-element semiconductor and a compound semiconductor. Examples of the single-element semiconductor include silicon and germanium. Examples of the compound semiconductor include gallium arsenide and silicon germanium. Other examples of the compound semiconductor include an organic semiconductor and a nitride semiconductor. Note that the above-described oxide semiconductor is also one kind of the compound semiconductor. These semiconductor materials may contain an impurity as a dopant.

As silicon that can be used for the semiconductor layer, single crystal silicon, polycrystalline silicon, microcrystalline silicon, and amorphous silicon can be given. Examples of polycrystalline silicon include low-temperature polysilicon (LTPS).

A transistor including amorphous silicon in its semiconductor layer can be formed over a large glass substrate, and can be manufactured at low cost. A transistor including polycrystalline silicon in its semiconductor layer has high field-effect mobility and enables high-speed operation. A transistor including microcrystalline silicon in its semiconductor layer has higher field-effect mobility and enables higher speed operation than the transistor including amorphous silicon.

### [Modification Example of Transistor 200]

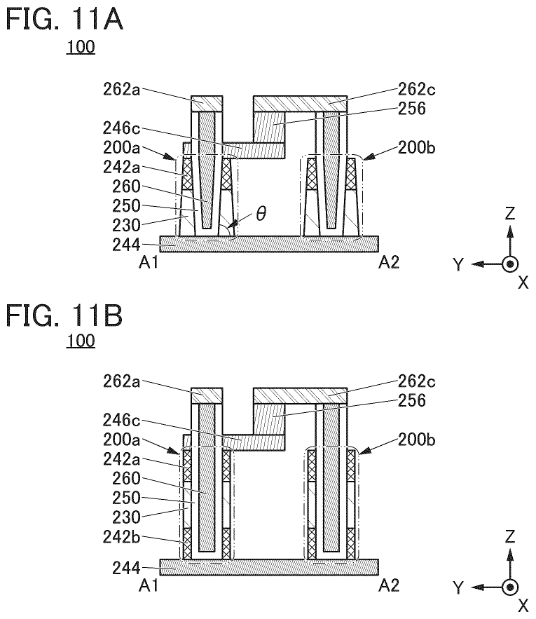

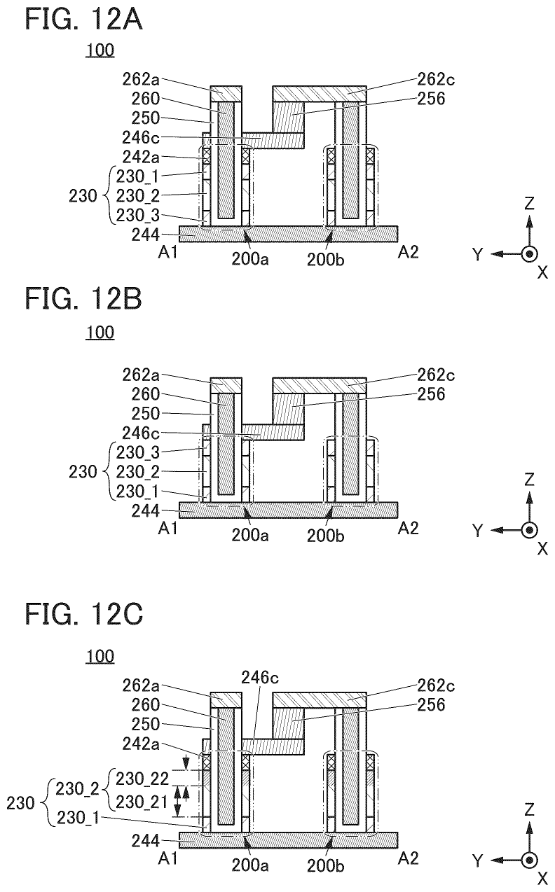

A structure example different from that of the above-described transistor 200 is described below with reference to FIG. 11A to FIG. 12C. Although a modification example of the transistor 200 included in the memory cell 100 illustrated in FIG. 2 is described in this section, the structure of the modification example of the transistor 200 described below may be applied to the memory cells illustrated in FIG. 6 to FIG. 10 (the memory cell 100A to the memory cell 100C).

FIG. 11A illustrates a modification example of the transistor 200 illustrated in FIG. 2B. FIG. 11A is a cross-sectional view of the memory cell 100. The transistor 200 illustrated in FIG. 11A is different from the transistor 200 illustrated in FIG. 2B in the shapes of the oxide 230 and the conductor 242a. Specifically, the transistor 200 illustrated in FIG. 11A is different from the transistor 200 illustrated in FIG. 2B in that each of the side surfaces of the oxide 230 and the conductor 242a has a tapered shape.

In this specification and the like, a tapered shape refers to such a shape that at least part of a side surface of a component is inclined with respect to a substrate surface or a formation surface. For example, the tapered shape refers to a shape including a region where the angle formed by the inclined side surface and the substrate surface or the formation surface (such an angle is also referred to as a taper angle) is less than 90 degrees. Note that the side surface of the component and the substrate surface are not necessarily completely flat and may be substantially flat with a slight curvature or substantially flat with slight unevenness.

As illustrated in FIG. 11A, in a cross-sectional view of the transistor 200, the side surface of the oxide 230 on the opening side (on the insulator 250 side) may have a tapered shape with a taper angle θ. Here, the taper angle θ is an angle formed by the side surface of the oxide 230 on the opening side and the substrate surface. Note that one of two sides extending from the vertex of the taper angle θ is not limited to the substrate surface and may be the top surface of the conductor 244, the bottom surface of the oxide 230, or the like. That is, the taper angle θ may be an angle formed by the side surface of the oxide 230 and the top surface of the conductor 244 or the bottom surface of the oxide 230. At this time, the outer side surface of the oxide 230 also has a tapered shape with the taper angle θ.

When the side surface of the oxide 230 on the opening side has a tapered shape, the coverage with the insulator 250 provided in the opening portion of the oxide 230 is improved, so that a defect such as a void can be reduced. Moreover, the area of the lower base surface of the oxide 230 is increased, and the area of a region where the conductor 244 and the oxide 230 are in contact with each other can be increased.

Note that as the taper angle θ is closer to 90 degrees, the conductor 260 can be provided in a lower part of the opening that the oxide 230 has. Thus, a region that is of the oxide 230 and overlaps with the conductor 260 can be increased, so that the electrical characteristics of the transistor can be stable. Furthermore, the area occupied by the transistor 200 can be reduced. For example, the taper angle θ is greater than or equal to 80 degrees, greater than or equal to 85 degrees, or greater than or equal to 87 degrees and less than 90 degrees.

Also in the above-described structure, the top surface of the oxide 230 has a hollow circular shape. That is, in the above-described structure, the oxide 230 has a hollow truncated cone shape. Specifically, in the oxide 230 with the truncated cone shape, the area of the upper base surface (the surface on the conductor 242a side) is smaller than the area of the lower base surface (the surface on the conductor 244 side).

Like the oxide 230, the conductor 242a has a tapered side surface on the opening side (on the insulator 250 side) and a tapered side surface on the outer side. Note that the angle formed between the substrate surface and the side surface of the opening of the conductor 242a and the angle formed between the substrate surface and the side surface on the outer side of the conductor 242a are equal or substantially equal to the taper angle θ. Depending on the combination of a material used for the oxide 230 and a material used for the conductor 242a, processing conditions of the oxide 230 and the conductor 242a, or the like, the angle formed between the substrate surface and the side surface of the opening of the conductor 242a and the angle formed between the substrate surface and the side surface on the outer side of the conductor 242a are not equal to the taper angle θ, in some cases.

In addition, the conductor 242a has a hollow truncated cone shape. That is, in the conductor 242a with the truncated cone shape, the area of the upper base surface (the surface on the conductor 246b side or the conductor 246c side) is smaller than the area of the lower base surface (the surface on the oxide 230 side).

FIG. 11B illustrates a modification example of the transistor 200 illustrated in FIG. 2B. FIG. 11B is a cross-sectional view of the memory cell 100. The transistor 200 illustrated in FIG. 11B is different from the transistor 200 illustrated in FIG. 2B in including a conductor 242b.

The conductor 242b is provided between the oxide 230 and the conductor 244. In FIG. 11B, the conductor 242b is provided in contact with the bottom surface of the oxide 230. In addition, the conductor 242b is provided in contact with at least part of the top surface of the conductor 244.

The conductor 242b has a cylindrical shape (also referred to as a circular column shape). Note that the cylindrical shape that the conductor 242b has extends in the Z direction. The conductor 242b has an opening. In addition, the top surface of the conductor 242b has a hollow circular shape. In other words, the conductor 242b has a cylindrical shape provided with a hollow portion. The conductor 242b functions as one of the source electrode and the drain electrode of the transistor 200.

The insulator 250 and the conductor 260 are placed inside the opening that the conductor 242b has. With this structure, an end portion of a region where the oxide 230 and the conductor 260 overlap with each other with the insulator 250 therebetween can be made closer to the conductor 244. In other words, such a structure allows a region where the oxide 230 and the conductor 260 do not overlap with each other with the insulator 250 therebetween, what is called an Loff region, to be narrow or omitted. Thus, the frequency characteristics of the transistor 200 can be improved. Accordingly, an increase in the writing speed and reading speed of the memory cell 100, an increase in the operation speed of the semiconductor device 10, and the like can be achieved. Thus, a semiconductor device that operates at high speed can be provided.

Note that a conductive film to be the conductor 242a and a conductive film to be the conductor 242b are deposited in different steps. Thus, the conductor 242a and the conductor 242b may be formed using different materials or may be formed using the same material.

Although the structure illustrated in FIG. 2B includes a single layer of the oxide 230, the present invention is not limited to this. For example, the oxide 230 may have a stacked-layer structure of two or more layers.

FIG. 12A illustrates a modification example of the transistor 200 illustrated in FIG. 2B. FIG. 12A is a cross-sectional view of the memory cell 100. The transistor 200 illustrated in FIG. 12A is different from the transistor 200 illustrated in FIG. 2B in that the oxide 230 has a stacked-layer structure of three layers of an oxide 230_1, an oxide 230_2, and an oxide 230_3.

The oxide 230_2 functions as a channel formation region of the transistor 200, the oxide 230_1 functions as one of a source region and a drain region of the transistor 200, and the oxide 230_3 functions as the other of the source region and the drain region of the transistor 200.

A metal oxide that can be used as the above-described oxide 230 may be used as the oxide 230_2.

A material whose conductivity is higher than that of the oxide 230_2 is preferably used for the oxide 230_1 and the oxide 230_3. A degenerated oxide semiconductor is preferably used for the oxide 230_1 and the oxide 230_3.

For example, for the oxide 230_1 and the oxide 230_3, a material obtained by adding nitrogen to a metal oxide that can be used for the oxide 230_2 can be used. Specifically, a metal oxide containing indium, the above-described element M, zinc, and nitrogen (also referred to as a metal oxynitride) is preferably used. More specifically, an oxide containing indium (In), gallium (Ga), zinc (Zn), and nitrogen (also referred to as an oxynitride containing In, Ga, and Zn or IGZO to which nitrogen is added), an oxide containing indium (In), aluminum (Al), zinc (Zn), and nitrogen (also referred to as an oxynitride containing In, Al, and Zn or IAZO to which nitrogen is added), an oxide containing indium (In), aluminum (Al), gallium (Ga), zinc (Zn), and nitrogen (also referred to as an oxynitride containing In, Al, Ga, and Zn, IAGZO to which nitrogen is added, IGAZO to which nitrogen is added, or AGIZO to which nitrogen is added), or the like can be used.

For example, IGZO to which nitrogen is added tends to have a wurtzite crystal structure. A wurtzite crystal structure and a crystal structure of a crystal of an In-M-Zn oxide have lattices matching well each other. Thus, use of a metal oxynitride having a wurtzite crystal structure as the oxide 230_1 can increase the crystallinity of the oxide 230_2. Accordingly, a metal oxide having a CAAC structure is likely to be formed as the oxide 230_2.

In the case where the CAAC-OS is used as the oxide 230_2 as described above, the crystal in the oxide 230_2 has c-axis alignment with respect to the substrate surface. Note that impurities in the CAAC-OS are less likely to diffuse in the c-axis direction. Thus, use of the CAAC-OS as the oxide 230_2 can inhibit entry of impurities into the oxide 230_2. For example, entry of nitrogen into the oxide 230_2 can be inhibited. Hence, an increase in the conductivity of the oxide 230_2 can be inhibited.

Note that although a material obtained by adding nitrogen to a metal oxide that can be used as the oxide 230_2 is described above, the element added to a metal oxide that can be used as the oxide 230_2 can be any of the elements increasing the conductivity of the metal oxide. As such an element, for example, one or more kinds selected from hydrogen, a Group 15 element (typically, nitrogen (N), phosphorus (P), arsenic (As), and antimony (Sb)), boron (B), aluminum (Al), argon (Ar), helium (He), neon (Ne), indium (In), fluorine (F), chlorine (Cl), titanium (Ti), and zinc (Zn) can be used.

Note that it is preferable that the conductivity of the metal oxide used as the oxide 230_1 and the oxide 230_3 be higher than that of the oxide 230_2. For example, as the oxide 230_1 and the oxide 230_3, a metal oxide containing the same element, besides oxygen, as the oxide 230_2 as a main component and having a different chemical composition from the oxide 230_2 may be used.

In the case where the oxide 230_1 and the oxide 230_3 contain the same element, besides oxygen, as the oxide 230_2 as a main component, the oxide 230 preferably has a stacked-layer structure of a plurality of oxide layers with different chemical compositions. For example, in the case where an In-M-Zn oxide is used as the oxide 230_2, the proportion of indium atoms to the sum of atoms of the metal elements that are main components of the metal oxide used as the oxide 230_1 or the oxide 230_3 is preferably greater than the proportion of indium atoms to the sum of atoms of the metal elements that are main components of the metal oxide used as the oxide 230_2. Moreover, the proportion of indium atoms to atoms of the element M in the metal oxide used as the oxide 230_1 or the oxide 230_3 is preferably greater than the proportion of indium atoms to atoms of the element M in the metal oxide used as the oxide 230_2.

When the oxide 230_1 and the oxide 230_3 contain the same element, besides oxygen, as the oxide 230_2 as a main component, the density of defect states at an interface between the oxide 230_1 or the oxide 230_3 and the oxide 230_2 can be made low. Since the density of defect states at the interface between the oxide 230_1 or the oxide 230_3 and the oxide 230_2 can be made low, the influence of interface scattering on carrier conduction is small, and a high on-state current can be obtained.

Alternatively, as the oxide 230_1 and the oxide 230_3, titanium oxide, molybdenum oxide, zinc oxide, indium oxide, tungsten oxide, magnesium oxide, calcium oxide, tin oxide, indium zinc oxide, indium tin oxide, indium tin oxide containing silicon, or the like may be used.

Note that in the case where the oxide 230 has the above-described three-layer structure, the conductor 242a is sometimes not necessarily provided as illustrated in FIG. 12B. In such a case, the conductor 246b or the conductor 246c also functions as the conductor 242a. In other words, the conductor 246b or the conductor 246c has a function of a wiring and a function of the other of the source electrode and the drain electrode. With a structure not including the conductor 242a, the number of steps in the manufacturing process of the semiconductor device can be reduced and the productivity can be improved.

FIG. 12C illustrates a modification example of the transistor 200 in FIG. 2B. FIG. 12C is a cross-sectional view of the memory cell 100. The transistor 200 illustrated in FIG. 12C is different from the transistor 200 illustrated in FIG. 2B in that the oxide 230 has a stacked-layer structure of two layers of the oxide 230_1 and the oxide 230_2.

When heat treatment is performed in the state where the conductor 242a and the oxide 230_2 are in contact with each other, the sheet resistance of the oxide 230_2 in the vicinity of the conductor 242a is decreased in some cases. Furthermore, the carrier concentration is sometimes increased. Thus, the resistance of the oxide 230_2 in the vicinity of the conductor 242a can be decreased in a self-aligned manner.

In the above case, for example, a region 230_22 is formed in the oxide 230_2 as illustrated in FIG. 12C. The region 230_22 is a region in the oxide 230_2 which is in the vicinity of the conductor 242a and has reduced resistance. The region 230_22 functions as the other of the source region and the drain region. A region that is in the oxide 230_2 and functions as a channel formation region is referred to as a region 230_21. In the oxide 230_2, the boundaries between the regions are difficult to detect clearly in some cases.

The region 230_22 is not formed depending on a material used for the conductor 242a, in some cases. At this time, the oxide 230_2 includes the region 230_21. Depending on a material used for the conductor 244, a low-resistance region is formed in the oxide 230_1 in the vicinity of the conductor 244, in some cases.

### <Detailed Structure Example of Semiconductor Device>

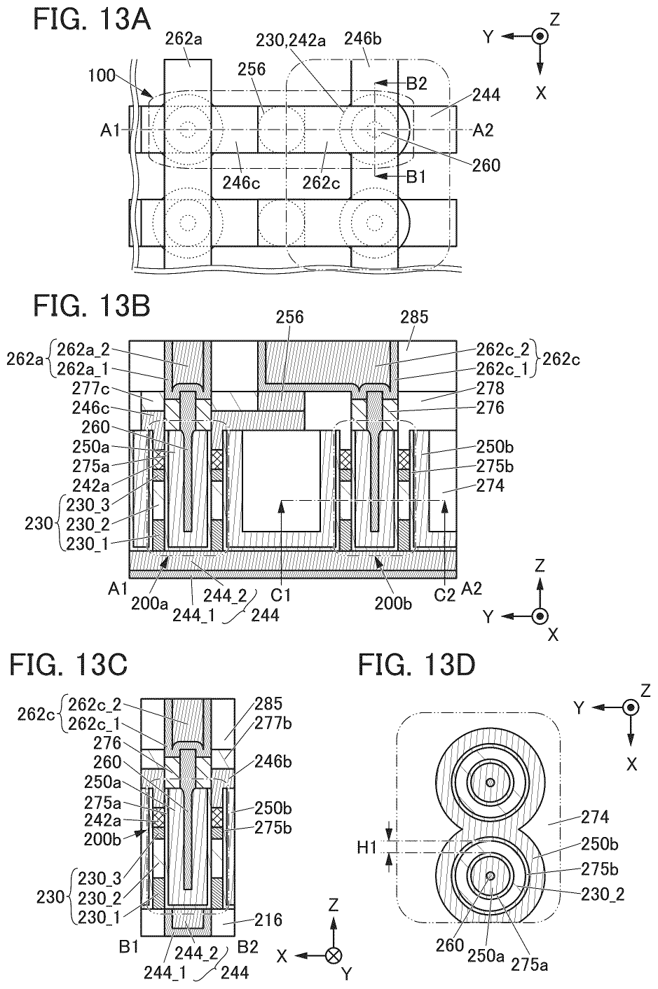

A detailed structure example of the semiconductor device of one embodiment of the present invention is described below with reference to FIG. 13A to FIG. 13D. Note that in the semiconductor device described below, structures having the same functions as the structures included in the semiconductor device described above in <Structure example of semiconductor device> are denoted by the same reference numerals. Furthermore, differences from the semiconductor device described above in <Structure example of semiconductor device> are mainly described below, and common portions are not described.

FIG. 13A to FIG. 13D are top views and cross-sectional views of a semiconductor device including the memory cell 100. FIG. 13A and FIG. 13D are top views of the semiconductor device. FIG. 13B and FIG. 13C are cross-sectional views of the semiconductor device. Here, FIG. 13B is a cross-sectional view of a portion indicated by the dashed-dotted line A1-A2 in FIG. 13A. FIG. 13C is a cross-sectional view of a portion indicated by the dashed-dotted line B1-B2 in FIG. 13A. FIG. 13D is a top view of a region which includes a cross section of a portion indicated by the dashed-dotted line C1-C2 in FIG. 13B and which is surrounded by the dashed double-dotted line in FIG. 13A. For clarity of the drawing, some components are not illustrated in the top view of FIG. 13A.

The semiconductor device illustrated in FIG. 13A to FIG. 13D includes a plurality of the memory cells 100 arranged in a matrix. Note that FIG. 13A illustrates two of the plurality of memory cells 100 included in the semiconductor device.

The semiconductor device illustrated in FIG. 13A to FIG. 13D includes an insulator 216 and the conductor 244 over a substrate (not illustrated); the transistor 200a, the transistor 200b, an insulator 275b, an insulator 250b, and an insulator 274 over the insulator 216 and the conductor 244; the conductor 246b, the conductor 246c, an insulator 276, and an insulator 278 over the transistor 200a, the transistor 200b, the insulator 275b, the insulator 250b, and the insulator 274; an insulator 277b over the conductor 246b; an insulator 277c and the conductor 256 over the conductor 246c; and the conductor 262a, the conductor 262c, and an insulator 285 over the insulator 276, the insulator 277b, the insulator 277c, the insulator 278, and the conductor 256. The insulator 216, the insulator 274, the insulator 276, the insulator 277b, the insulator 277c, the insulator 278, and the insulator 285 function as interlayer films.

In the top view of the semiconductor device illustrated in FIG. 13A to FIG. 13D, the conductor 262a does not overlap with the conductor 246c. In addition, the conductor 262c does not overlap with the conductor 246b.

The memory cell 100 included in the semiconductor device illustrated in FIG. 13A to FIG. 13D is composed of the transistor 200a and the transistor 200b. Note that the transistor 200a and the transistor 200b are electrically connected to each other through the conductor 262c, the conductor 256, and the conductor 246c. The memory cell 100 illustrated in FIG. 13A to FIG. 13D is also a detailed structure example of the memory cell 100 illustrated in FIG. 3D, FIG. 5A, FIG. 5B, and FIG. 5C.

### [Details of Memory Cell 100]

As illustrated in FIG. 13B and FIG. 13C, the transistor 200 includes the conductor 244 (a conductor 244_1 and a conductor 244_2) placed so as to be embedded in the insulator 216; the oxide 230_1 and an insulator 275a over the insulator 216 and the conductor 244; the oxide 230_2 over the oxide 230_1; the oxide 230_3 over the oxide 230_2; the conductor 242a over the oxide 230_3; an insulator 250a over the insulator 275a; and the conductor 260 over the insulator 250a.

Hereinafter, the oxide 230_1, the oxide 230_2, and the oxide 230_3 are sometimes collectively referred to as the oxide 230.

The insulator 275a, the insulator 250a, and the conductor 260 are provided inside the openings that the oxide 230 and the conductor 242a have. The insulator 250a includes a region in contact with the side surface of the conductor 260 and a region in contact with the bottom surface of the conductor 260. The insulator 275a includes a region in contact with the side surface of the insulator 250a, a region in contact with the bottom surface of the insulator 250a, a region in contact with the side surface of the oxide 230 on the opening side, a region in contact with the side surface of the conductor 242a on the opening side, and a region in contact with the top surface of the conductor 244. In such a structure, each of the insulator 275a and the insulator 250a can be regarded as having a depression. For example, in the top view, in the case where the conductor 244 is placed at a position shifted in the X direction from the center of the hollow cylindrical shape of the oxide 230 as illustrated in FIG. 4A, the insulator 275a includes a region in contact with the insulator 216 in some cases.

FIG. 13D corresponds to the X-Y plane taken at the center of the oxide 230_2 or the vicinity of the center. In the case where the top surface of the oxide 230_2 has a hollow circular shape in FIG. 13D, the insulator 275a is provided concentrically inside the oxide 230_2, the insulator 250a is provided concentrically inside the insulator 275a, and the conductor 260 is provided concentrically inside the insulator 250a.

Here, the width of the oxide 230_2 in the direction from the center of the hollow portion of the oxide 230_2 toward the outer periphery of the cylindrical shape is denoted by a width H1. In other words, the width H1 is half a difference between the outer diameter and the inner diameter of the hollow cylindrical shape.

In order to prevent the adjacent oxides 230_2 from being in contact with each other, the width H1 needs to be made smaller than half the minimum feature size (F). Meanwhile, in order to form the oxide 230_2 with a hollow cylindrical shape, it is necessary to secure the width H1 having a certain value. When the minimum feature size (F) is 15 nm, for example, the width H1 is preferably greater than or equal to 1 nm and less than or equal to 7 nm, further preferably greater than or equal to 1.5 nm and less than or equal to 6 nm, still further preferably greater than or equal to 2 nm and less than or equal to 5 nm. With such a structure, the adjacent oxides 230_2 are not in contact with each other and at least the insulator 275b can be provided between the adjacent oxides 230_2. Note that the preferable range of the width H1 is not limited to the above. The width H1 is set as appropriate in consideration of the minimum feature size, the thickness of the insulator 275b, and the like.

The oxide 230 includes a region overlapping with the conductor 244. Specifically, the oxide 230_1 includes a region in contact with at least part of the top surface of the conductor 244. The oxide 230 includes a region overlapping with the conductor 242a. Specifically, the oxide 230_3 includes a region in contact with at least part of the bottom surface of the conductor 242a.

The uppermost portion of the insulator 250a is level with each of the uppermost portion of the insulator 275a, the uppermost portion of the insulator 275b, the uppermost portion of the insulator 250b, and the uppermost portion of the insulator 274.

The insulator 276 is provided over the insulator 275a and the insulator 250a. The conductor 262a or the conductor 262c is positioned over the insulator 276. That is, the insulator 276 is provided between the conductor 262a and the insulators 275a and 250a and between the conductor 262c and the insulators 275a and 250a. The insulator 276 includes a region overlapping with the insulator 275a and the insulator 250a. The insulator 276 includes a region in contact with the bottom surface of the conductor 262a or the conductor 262c. In other words, at least part of the bottom surface of the conductor 262a or the conductor 262c is in contact with the top surface of the insulator 276.

The insulator 276 functions as an interlayer film. The insulator 276 has a cylindrical shape and has an opening. That is, the insulator 276 has a cylindrical shape provided with a hollow portion. In other words, the top surface shape of the insulator 276 has a hollow circular shape. The conductor 260 is provided in the hollow portion that the insulator 276 has. When the cross-sectional shape of the conductor 260 is a circular shape, the insulator 276 is provided concentrically outside the conductor 260.

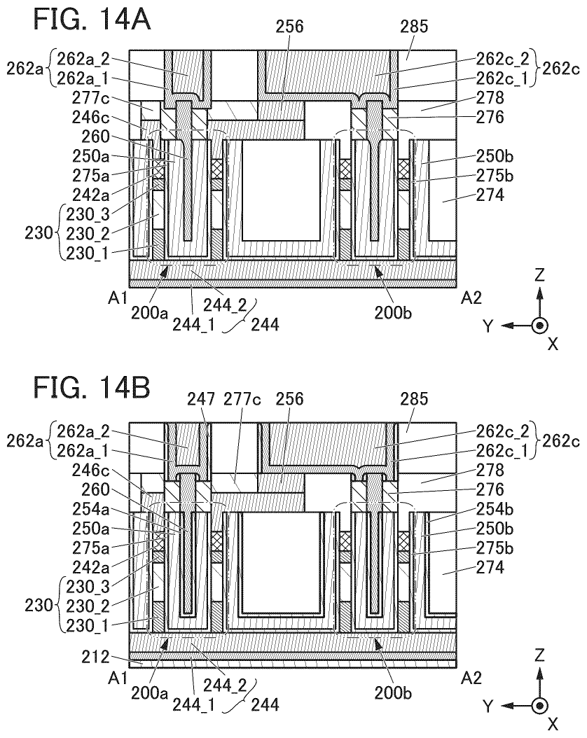

In the top view, the diameter of the hollow portion of the insulator 276 is preferably equal to or larger than the diameter of the inside of the depression of the insulator 250a where the conductor 260 is provided. With such a structure, the conductor 260 can be surely embedded in the depression of the insulator 250a. For example, as illustrated in FIG. 14A, part of the conductor 246c is provided over the insulator 275a or over the insulator 275a and the insulator 250a in some cases. Even in such a case, the above-described structure allows the conductor 260 to be surely embedded in the depression of the insulator 250a. Note that the same applies to the case where part of the conductor 246b is provided over the insulator 275a or over the insulator 275a and the insulator 250a.

The outline of the cylindrical shape of the insulator 276 is preferably aligned with the outline of the insulator 275a. With such a structure, the area where the conductor 242a and the conductor 246b or the conductor 246c are in contact with each other can be made large compared with a structure where the outline of the cylindrical shape of the insulator 276 is larger than the outline of the insulator 275a. Furthermore, with such a structure, the distance between the conductor 262a and the conductor 246c and the distance between the conductor 262c and the conductor 246b can be made large compared with a structure where the outline of the cylindrical shape of the insulator 276 is smaller than the outline of the insulator 275a. Thus, a leakage current and a short circuit between the conductor 262a and the conductor 246c and between the conductor 262c and the conductor 246b can be prevented.

The insulator 276 preferably extends in the Z direction so that the top surface of the conductor 246b or the conductor 246c is positioned between the bottom surface and the top surface of the insulator 276. In other words, the insulator 276 preferably extends in the Z direction so that the top surface of the conductor 246b or the conductor 246c is positioned above the bottom surface of the insulator 276 and positioned below the top surface of the insulator 276. This structure can prevent the conductor 262a and the conductor 246c from being in contact with each other and the conductor 262c and the conductor 246b from being in contact with each other, and can prevent a leakage current and a short circuit between the conductor 262a and the conductor 246c and between the conductor 262c and the conductor 246b.

An insulator 277b is provided over the conductor 246b, and the insulator 277c is provided over the conductor 246c. As illustrated in FIG. 13B, there is a region where end portions of the insulator 277c and the conductor 246c are aligned with each other. Although not illustrated, there is a region where end portions of the insulator 277b and the conductor 246b are aligned with each other.

The conductor 260 functions as the gate electrode of the transistor 200. The insulator 275a and the insulator 250a function as a gate insulator of the transistor 200. The conductor 244 functions as one of the source electrode and the drain electrode of the transistor 200, and the conductor 242a functions as the other of the source electrode and the drain electrode of the transistor 200. At least part of a region that is of the oxide 230 and overlaps with the conductor 260 functions as the channel formation region of the transistor 200. For example, the oxide 230_2 functions as the channel formation region of the transistor 200, the oxide 230_1 functions as one of the source region and the drain region of the transistor 200, and the oxide 230_3 functions as the other of the source region and the drain region of the transistor 200.

In the transistor 200, a metal oxide functioning as a semiconductor (hereinafter also referred to as an oxide semiconductor) is preferably used as the oxide 230_2 including the channel formation region. Note that part of a region that is of the oxide 230_1 and the oxide 230_3 and overlaps with the conductor 260 functions as the channel formation region in some cases.

Although the oxide 230 has a three-layer stacked structure of the oxide 230_1, the oxide 230_2, and the oxide 230_3 in the transistor 200 illustrated in FIG. 13B, the present invention is not limited to the structure. For example, the oxide 230 may have a single-layer structure or a stacked-layer structure of two layers or four or more layers.

The above description in <Structure example of semiconductor device> can be referred to for a material, a structure, and the like of the oxide 230 (the oxide 230_1, the oxide 230_2, and the oxide 230_3).

The insulator 216, the insulator 274, the insulator 276, the insulator 277b, the insulator 277c, the insulator 278, and the insulator 285 preferably have low relative dielectric constants. When a material with a low relative dielectric constant is used for an interlayer film, parasitic capacitance generated between wirings can be reduced. For example, as the insulator 216, the insulator 274, the insulator 276, the insulator 277b, the insulator 277c, the insulator 278, and the insulator 285, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like is used as appropriate. Examples of the resin include polyester, polyolefin, polyamide (e.g., nylon and aramid), polyimide, polycarbonate, and acrylic.

The conductor 244 includes a region overlapping with the oxide 230. More specifically, the conductor 244 is placed to be in contact with at least part of the bottom surface of the oxide 230_1. Here, the conductor 244 is preferably provided to be embedded in an opening that the insulator 216 has.

The conductor 244 has a two-layer structure of the conductor 244_1 and the conductor 244_2. The conductor 244_1 is provided in contact with the bottom surface and the sidewall of the opening portion that the insulator 216 has. The conductor 244_2 is provided to be embedded in a depression formed in the conductor 244_1. Here, the top surface of the conductor 244_2 is level with the top surfaces of the conductor 244_1 and the insulator 216.

Here, it is preferable for the conductor 244_1 to use a conductive material having a function of inhibiting diffusion of oxygen (e.g., at least one of an oxygen atom, an oxygen molecule, and the like). Alternatively, as the conductor 244_1, it is preferable to use a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, NO₂), and a copper atom.

When the conductor 244_1 is formed using a conductive material having a function of inhibiting diffusion of oxygen, the conductivity of the conductor 244_2 can be inhibited from being lowered by oxidation. As the conductive material having a function of inhibiting diffusion of oxygen, for example, titanium, titanium nitride, tantalum, tantalum nitride, ruthenium, ruthenium oxide, or the like is preferably used. Thus, the conductor 244_1 is a single layer or stacked layers of the above-described conductive materials. For example, titanium nitride is used as the conductor 244_1.

A conductive material containing tungsten, copper, or aluminum as its main component is preferably used as the conductor 244_2. For example, tungsten is used as the conductor 244_2.

The electric resistivity of the conductor 244 is designed in consideration of the potential applied to the conductor 244, and the thickness of the conductor 244 is determined in accordance with the electric resistivity. The thickness of the insulator 216 is substantially equal to that of the conductor 244. Here, the conductor 244 and the insulator 216 are preferably as thin as possible in the allowable range of the design of the conductor 244. When the thickness of the insulator 216 is reduced, the absolute amount of impurities such as hydrogen contained in the insulator 216 can be reduced, thereby inhibiting diffusion of impurities into the oxide 230.

Note that although the conductor 244 in FIG. 13B has a two-layer structure of the conductor 244_1 and the conductor 244_2, the present invention is not limited thereto. For example, the conductor 244 may be provided to have a single-layer structure or a stacked-layer structure of three or more layers.

Note that the above description in <Structure example of semiconductor device> can be referred to for a material, a structure, and the like of the conductor 244. The conductor 244 may be formed using a conductive material that can be used for the conductor 242a.

The conductor 242a overlaps with the oxide 230. More specifically, the conductor 242a is provided in contact with the top surface of the oxide 230_3.

Although the conductor 242a in FIG. 13B has a single layer, the present invention is not limited to this structure. The conductor 242a may have a stacked-layer structure of two or more layers. For example, the conductor 242a may have a two-layer structure of a first conductor over the oxide 230_3 and a second conductor over the first conductor.

The first conductor of the conductor 242a is preferably formed using a conductive material that is unlikely to be oxidized. This can inhibit the oxidation of the first conductor of the conductor 242a and a reduction in the conductivity of the conductor 242a. Note that the first conductor of the conductor 242a may have a property of being likely to absorb (extract) hydrogen. Accordingly, hydrogen in the oxide 230 is diffused into the first conductor of the conductor 242a, so that the hydrogen concentration of the oxide 230 can be reduced. Thus, the transistor 200 can have stable electrical characteristics.

The second conductor of the conductor 242a is preferably formed using a conductive material having higher conductivity than the first conductor of the conductor 242a. In this case, at least part of the second conductor of the conductor 242a includes a region having higher conductivity than the first conductor of the conductor 242a. Furthermore, the second conductor of the conductor 242a is preferably formed using a conductive material having lower resistivity than the first conductor of the conductor 242a. Accordingly, a semiconductor device with reduced wiring delay can be manufactured.

Note that the second conductor of the conductor 242a may have a property of being likely to absorb hydrogen. Accordingly, hydrogen absorbed by the first conductor of the conductor 242a is also diffused into the second conductor of the conductor 242a, so that the hydrogen concentration in the oxide 230 can be further reduced. Thus, the transistor 200 can have stable electrical characteristics.

Here, as the first conductor and the second conductor of the conductor 242a, conductive materials containing the same constituent elements and different chemical compositions are preferably used. In this case, the first conductor and the second conductor of the conductor 242a can be formed successively without being exposed to an air environment. By the film deposition without exposure to the atmosphere, impurities or moisture from the air environment can be prevented from being attached onto the surface of the first conductor of the conductor 242a, so that the vicinity of the interface between the first conductor and the second conductor of the conductor 242a can be kept clean.

In addition, a nitride containing tantalum with a high atomic ratio of nitrogen to tantalum is preferably used as the first conductor of the conductor 242a, and a nitride containing tantalum with a low atomic ratio of nitrogen to tantalum is preferably used as the second conductor of the conductor 242a. For example, a nitride containing tantalum with an atomic ratio of nitrogen to tantalum being greater than or equal to 1.0 and less than or equal to 2.0, preferably greater than or equal to 1.1 and less than or equal to 1.8, further preferably greater than or equal to 1.2 and less than or equal to 1.5 is used as the first conductor of the conductor 242a. In addition, for example, a nitride containing tantalum with an atomic ratio of nitrogen to tantalum being greater than or equal to 0.3 and less than or equal to 1.5, preferably greater than or equal to 0.5 and less than or equal to 1.3, further preferably greater than or equal to 0.6 and less than or equal to 1.0 is used as the second conductor of the conductor 242a.

The high atomic ratio of nitrogen to tantalum in the nitride containing tantalum can inhibit oxidation of the nitride containing tantalum. In addition, the oxidation resistance of the nitride containing tantalum can be improved. Moreover, the diffusion of oxygen into the nitride containing tantalum can be inhibited. Hence, the nitride containing tantalum with a high atomic ratio of nitrogen to tantalum is preferably used as the first conductor of the conductor 242a. It is thus possible to prevent an oxide layer from being formed between the first conductor of the conductor 242a and the oxide 230 or reduce the thickness of the oxide layer.

The low atomic ratio of nitrogen to tantalum in the nitride containing tantalum can reduce the resistivity of the nitride. Hence, the nitride containing tantalum with a low atomic ratio of nitrogen to tantalum is preferably used as the second conductor of the conductor 242a. Accordingly, a semiconductor device with reduced wiring delay can be manufactured.

Note that the boundary between the first conductor and the second conductor of the conductor 242a is difficult to detect clearly in some cases. In the case where a nitride containing tantalum is used as the conductor 242a, the tantalum concentration and the nitrogen concentration detected in each layer may change gradually within each layer and may also change continuously (or in a gradation manner) in a region between the first conductor and the second conductor. That is, the atomic ratio of nitrogen to tantalum is higher in the region of the conductor 242a that is closer to the oxide 230. Thus, the atomic ratio of nitrogen to tantalum in a lower region of the conductor 242a is preferably higher than the atomic ratio of nitrogen to tantalum in an upper region of the conductor 242a.

The thickness of the first conductor of the conductor 242a is greater than or equal to 0.1 nm and less than or equal to 5.0 nm, preferably greater than or equal to 0.5 nm and less than or equal to 3.0 nm, further preferably greater than or equal to 1.0 nm and less than or equal to 3.0 nm. In this case, at least part of the first conductor of the conductor 242a includes a region having the above-described thickness. Furthermore, the thickness of the first conductor of the conductor 242a is preferably smaller than the thickness of the second conductor of the conductor 242a. In this case, at least part of the first conductor of the conductor 242a includes a region having a thickness smaller than that of the second conductor of the conductor 242a.

The example in which conductive materials having the same constituent elements and having different chemical compositions are used for the first conductor and the second conductor of the conductor 242a has been described; however, one embodiment of the present invention is not limited thereto, and the first conductor and the second conductor of the conductor 242a may be formed using different conductive materials. For example, a nitride containing tantalum may be used as the first conductor of the conductor 242a, and tungsten or a nitride containing titanium may be used as the second conductor of the conductor 242a.

Note that the above description in <Structure example of semiconductor device> can be referred to for a material, a structure, and the like of the conductor 242a.

The insulator 275a is placed inside the openings that the oxide 230 and the conductor 242a have (in the hollow portions of the oxide 230 and the conductor 242a) in the top view. The insulator 275a functions as part of the gate insulator. The insulator 275b is placed outside the cylindrical shapes of the oxide 230 and the conductor 242a in the top view.

The insulator 275a and the insulator 275b are formed through the same step, which will be described in detail. Thus, the insulator 275a and the insulator 275b contain the same insulating material. The thickness of the insulator 275b is equal to that of the insulator 275a.

The insulator 275a is provided in the same layer as the insulator 275b. In FIG. 13B, the insulator 275a and the insulator 275b are provided over the insulator 216 and the conductor 244.

As the insulator 275a and the insulator 275b, a barrier insulating film against oxygen is preferably used. An insulator containing an oxide of one or both of aluminum and hafnium is preferably used as the insulator 275a and the insulator 275b, for example. As the insulator, aluminum oxide, hafnium oxide, an oxide containing aluminum and hafnium (hafnium aluminate), an oxide containing hafnium and silicon (hafnium silicate), or the like can be used. In this embodiment, aluminum oxide is used as the insulator 275a and the insulator 275b. In this case, the insulator 275a and the insulator 275b each contain at least oxygen and aluminum.

As illustrated in FIG. 13B, the insulator 275a is provided in contact with the side surface of the opening of the oxide 230. The insulator 275b is provided in contact with the outer side surface of the oxide 230. That is, the oxide 230 is covered with the insulator 275a and the insulator 275b. With this structure, the insulator 275a and the insulator 275b each having a barrier property against oxygen can prevent release of oxygen from the oxide 230 at the time of heat treatment or the like. This can inhibit formation of oxygen vacancies in the oxide 230. Thus, the amount of oxygen vacancies and V_{O}H formed in the oxide 230 can be reduced. Thus, the transistor 200 can have favorable electrical characteristics and higher reliability.

Even when an excess amount of oxygen is contained in the insulator 274, the insulator 250a, and the like, oxygen can be inhibited from being excessively supplied to the oxide 230. Thus, the oxide 230_1 and the oxide 230_3 are inhibited from being excessively oxidized; a reduction in the on-state current or field-effect mobility of the transistor 200 can be inhibited.

As illustrated in FIG. 13B, the insulator 275a is provided in contact with the side surface of the conductor 242a on the opening side, and the insulator 275b is provided in contact with the outer side surface of the conductor 242a. That is, the conductor 242a is covered with the insulator 275a and the insulator 275b. This can inhibit formation of an oxide film on the side surface of the conductor 242a by oxidization of the side surface. Accordingly, a decrease in the on-state current or field-effect mobility of the transistor 200 can be inhibited.

In the case where aluminum oxide is used as the insulator 275a and the insulator 275b, aluminum is added to the region that is of the oxide 230_2 and is in contact with the insulator 275a and the vicinity thereof, and the region that is of the oxide 230_2 and is in contact with the insulator 275b and the vicinity thereof, in some cases. For example, in the case where IGZO is used as the oxide 230_2, the region that is of the oxide 230_2 and is in contact with the insulator 275a and the vicinity thereof, and the region that is of the oxide 230_2 and is in contact with the insulator 275b and the vicinity thereof include indium, gallium, aluminum, and zinc.

As illustrated in FIG. 13B or the like, the insulator 275a formed using aluminum oxide or the like is provided in contact with the side surface of the opening of the oxide 230_2, whereby indium contained in the oxide 230_2 is unevenly distributed in some cases, at the interface between the oxide 230_2 and the insulator 275a and in the vicinity of the interface. Accordingly, the vicinity of the surface of the oxide 230_2 on the opening side comes to have an atomic ratio close to that of an indium oxide or that of an In—Zn oxide. Such an increase in the atomic ratio of indium in the oxide 230_2, specifically, in the vicinity of the surface of the oxide 230_2 on the opening side, can increase the field-effect mobility of the transistor 200.

The insulator 275a needs to be provided in the openings that the conductor 242a and the oxide 230 have, together with the insulator 250a and the conductor 260. The thickness of the insulator 275a is preferably small for miniaturization of the transistor 200. The thickness of the insulator 275a is greater than or equal to 0.1 nm and less than or equal to 5.0 nm, preferably greater than or equal to 0.5 nm and less than or equal to 3.0 nm, further preferably greater than or equal to 1.0 nm and less than 3.0 nm. In this case, at least part of the insulator 275a preferably includes a region having the above-described thickness. The thickness of the insulator 275a is preferably smaller than that of the insulator 250a. In this case, at least part of the insulator 275a preferably includes a region having a thickness smaller than that of the insulator 250a.

To form the insulator 275a having a small thickness like the above-described thickness, an ALD method is preferably used for deposition of the insulator 275a. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because it enables deposition at a lower temperature.

An ALD method, which enables atomic layers to be deposited one by one, has advantages such as deposition of an extremely thin film, deposition on a component with a high aspect ratio, deposition of a film with a small number of defects such as pinholes, deposition with excellent coverage, and low-temperature deposition. Therefore, the insulator 275a can be deposited on the side surfaces of the opening portions that the conductor 242a and the oxide 230 have or the like, with a small thickness like the above-described thickness and favorable coverage.

Note that some of precursors used in an ALD method contain carbon or the like. For that reason, in some cases, a film provided by the ALD method contains impurities such as carbon in a larger amount than a film provided by another deposition method. Note that impurities can be quantified by secondary ion mass spectrometry (SIMS), X-ray photoelectron spectroscopy (XPS), or auger electron spectroscopy (AES).

The insulator 250a is placed in a depression of the insulator 275a. The insulator 250a functions as part of the gate insulator. The insulator 250b is placed in contact with the top surface of the insulator 275b.

The insulator 250a and the insulator 250b are formed through the same step, which will be described later in detail. Thus, the insulator 250a and the insulator 250b contain the same insulating material. The thickness of the insulator 250b is equal to that of the insulator 250a.

In FIG. 13B, the insulator 250a is provided over the insulator 275a, and the insulator 250b is provided over the insulator 275b. Since the insulator 275a is provided in the same layer as the insulator 275b as described above, the insulator 250a can be regarded as being provided in the same layer as the insulator 250b.

Note that the above description of the insulator 250 in <Structure example of semiconductor device> can be referred to for materials, structures, and the like of the insulator 250a and the insulator 250b.

In this embodiment, hafnium oxide is used as the insulator 250a and the insulator 250b. In this case, the insulator 250a and the insulator 250b contain at least oxygen and hafnium.

The conductor 260 is placed in a depression of the insulator 250a. In the transistor 200, the conductor 260 is formed in a self-aligned manner to fill the openings that the oxide 230 and the conductor 242a have.

Although the conductor 260 having a single-layer structure is described with reference to FIG. 13B, the present invention is not limited to this. For example, the conductor 260 may have a stacked-layer structure of two or more layers.

Note that the above description in <Structure example of semiconductor device> can be referred to for a material, a structure, and the like of the conductor 260.

The conductor 246b is placed over the conductor 242a included in the transistor 200b. Furthermore, the conductor 246b is placed in contact with at least part of the top surface of the conductor 242a included in the transistor 200b. The conductor 246b has a protruding portion in a region overlapping with the conductor 242a included in the transistor 200b. The conductor 246b functions as a wiring.

The conductor 246c is placed over the conductor 242a included in the transistor 200a. The conductor 246c is placed in contact with at least part of the top surface of the conductor 242a included in the transistor 200a. The conductor 246c has a protruding portion in a region overlapping with the conductor 242a included in the transistor 200a.

Note that the above description in <Structure example of semiconductor device> can be referred to for materials, structures, and the like of the conductor 246b and the conductor 246c.

The conductor 262a is placed over the conductor 260 included in the transistor 200a. The conductor 262a is placed in contact with the top surface of the conductor 260 included in the transistor 200a. The conductor 262a functions as a wiring.

The conductor 262a preferably has a two-layer structure of a conductor 262a_1 and a conductor 262a_2 over the conductor 262a_1. For example, the conductor 262a_1 is preferably placed to cover the bottom surface and the side surface of the conductor 262a_2. Note that although the conductor 262a in FIG. 13B has a two-layer structure of the conductor 262a_1 and the conductor 262a_2, the conductor 262a can have a single-layer structure or a stacked-layer structure of three or more layers.

The conductor 262c is placed over the conductor 260 included in the transistor 200b. The conductor 262c is placed in contact with the top surface of the conductor 260 included in the transistor 200b.

The conductor 262c preferably has a two-layer structure of a conductor 262c_1 and a conductor 262c_2 over the conductor 262c_1. For example, the conductor 262c_1 is preferably placed to cover the bottom surface and the side surface of the conductor 262c_2. Note that although the conductor 262c in FIG. 13B has a two-layer structure of the conductor 262c_1 and the conductor 262c_2, the conductor 262c can have a single-layer structure or a stacked-layer structure of three or more layers.

As illustrated in FIG. 13B, the top surface of the conductor 262a is level with each of the top surfaces of the conductor 262c and the insulator 285.

As the conductor 262a_1 and the conductor 262c_1, a conductive material having a function of inhibiting diffusion of impurities such as a hydrogen atom, a hydrogen molecule, a water molecule, a nitrogen atom, a nitrogen molecule, a nitrogen oxide molecule, and a copper atom is preferably used. Alternatively, it is preferable to use a conductive material having a function of inhibiting diffusion of oxygen (e.g., at least one of an oxygen atom, an oxygen molecule, and the like).

In addition, when the conductor 262a_1 and the conductor 262c_1 have a function of inhibiting diffusion of oxygen, the conductivity of the conductor 262a_2 and the conductor 262c_2 can be inhibited from being lowered because of oxidation due to oxygen contained in the insulator 285. As the conductive material having a function of inhibiting diffusion of oxygen, for example, titanium, titanium nitride, tantalum, tantalum nitride, ruthenium, or ruthenium oxide is preferably used.

The conductor 262a functions as a wiring and thus is preferably formed using a conductor having high conductivity. For example, a conductive material containing tungsten, copper, or aluminum as its main component can be used as the conductor 262a_2. The conductor 262a_2 may have a stacked-layer structure; for example, a stacked-layer structure of the conductive material and titanium or titanium nitride may be employed. The same applies to the conductor 262c_2.

Note that the above description in <Structure example of semiconductor device> can be referred to for materials, structures, and the like of the conductor 262a and the conductor 262c.

### [Component Material of Semiconductor Device]

Component materials that can be used in the semiconductor device are described below.

### <<Substrate>>

As the substrate where the transistor 200 is formed, an insulator substrate, a semiconductor substrate, or a conductor substrate is used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate having an insulator region in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate including a nitride of a metal and a substrate including an oxide of a metal. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitive element, a resistor, a switching element, a light-emitting element, and a storage element.

### <<Insulator>>

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as a leakage current may arise because of a thinner gate insulator. When a high-k material is used for the insulator functioning as a gate insulator, the voltage at the time of the operation of the transistor can be reduced while the physical thickness is maintained. In contrast, when a material with a low relative dielectric constant is used for the insulator functioning as an interlayer film, parasitic capacitance generated between wirings can be reduced. Thus, a material is preferably selected depending on the function of the insulator.

Examples of the insulator with a high relative dielectric constant include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator with a low relative dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

When a transistor including a metal oxide is surrounded by an insulator having a function of inhibiting passage of oxygen and impurities such as hydrogen, the transistor can have stable electrical characteristics. As the insulator having a function of inhibiting passage of oxygen and impurities such as hydrogen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum may be used. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

The insulator functioning as the gate insulator is preferably an insulator including a region containing oxygen to be released by heating. For example, when a structure is employed in which silicon oxide or silicon oxynitride including a region containing oxygen to be released by heating is in contact with the oxide 230, oxygen vacancies included in the oxide 230 can be compensated for.

### <<Conductor>>

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. In addition, tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that retain their conductivity even after absorbing oxygen. Alternatively, a semiconductor having high electrical conductivity, typified by polycrystalline silicon containing an impurity element such as phosphorus, or silicide such as nickel silicide may be used.

A stack of a plurality of conductive layers formed of the above-described materials may be used. For example, a stacked-layer structure combining a material containing the above-described metal element and a conductive material containing oxygen may be employed. In addition, a stacked-layer structure combining a material containing the above-described metal element and a conductive material containing nitrogen may be employed. Furthermore, a stacked-layer structure combining a material containing the above-described metal element, a conductive material containing oxygen, and a conductive material containing nitrogen may be employed.

In the case where an oxide is used for the channel formation region of the transistor, the conductor functioning as the gate electrode preferably employs a stacked-layer structure combining a material containing the above-described metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, as the conductor functioning as the gate electrode, a conductive material containing oxygen and a metal element contained in the metal oxide where the channel is formed. A conductive material containing the above-described metal element and nitrogen may be used. For example, a conductive material containing nitrogen, such as titanium nitride or tantalum nitride, may be used. Indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### [Modification Example of Memory Cell 100]

A structure example different from that of the memory cell 100 illustrated in FIG. 13 is described below with reference to FIG. 14B.

FIG. 14B illustrates a modification example of the memory cell 100 illustrated in FIG. 13. FIG. 14B is a cross-sectional view of a semiconductor device including the memory cell 100. The memory cell 100 illustrated in FIG. 14B is different from the transistor 200 illustrated in FIG. 13 in including an insulator 254a, an insulator 254b, an insulator 212, and an insulator 247.

The insulator 254a is positioned between the insulator 250a and the conductor 260. Specifically, the insulator 254a is provided in the depression of the insulator 250a. Furthermore, the insulator 254a is provided in contact with the side surface and the bottom surface of the conductor 260. In such a structure, the insulator 254a can also be regarded as having a depression. The uppermost portion of the insulator 254a is level with each of the uppermost portion of the insulator 275a and the uppermost portion of the insulator 250a.

The insulator 254a functions as part of a gate insulator. As the insulator 254a, a barrier insulating film against hydrogen is preferably used. In that case, diffusion of impurities included in the conductor 260, such as hydrogen, into the oxide 230_2 can be inhibited. Silicon nitride is preferably used as the insulator 254a, for example. For example, silicon nitride deposited by a PEALD method is preferably used as the insulator 254a. In this case, the insulator 254a contains at least nitrogen and silicon. Alternatively, as the insulator 254a, aluminum oxide, magnesium oxide, hafnium oxide, gallium oxide, indium gallium zinc oxide, silicon nitride oxide, or the like may be used, for example. Note that the insulator 254a is less permeable to hydrogen than the insulator 250a, for example. As the insulator 254a, a material that is less permeable to hydrogen than the insulator 250a is used, for example.

Furthermore, the insulator 254a may have a barrier property against oxygen. Thus, diffusion of oxygen contained in the insulator 250a into the conductor 260 can be inhibited.

Furthermore, the insulator 254a needs to be provided in the openings that the oxide 230 and the conductor 242a have, together with the insulator 275a, the insulator 250a, and the conductor 260. The thickness of the insulator 254a is preferably small for miniaturization of the transistor. The thickness of the insulator 254a is greater than or equal to 0.1 nm and less than or equal to 5.0 nm, preferably greater than or equal to 0.5 nm and less than or equal to 3.0 nm, further preferably greater than or equal to 1.0 nm and less than or equal to 3.0 nm. In this case, at least part of the insulator 254a includes a region having the above-described thickness. The thickness of the insulator 254a is preferably smaller than that of the insulator 250a. In this case, at least part of the insulator 254a includes a region having a thickness that is smaller than that of the insulator 250a.

The insulator 254b is placed outside the oxide 230 and the conductor 242a (on the insulator 275b side) in the top view. The insulator 254b is positioned between the insulator 250b and the insulator 274. Specifically, the insulator 254b is provided in contact with the top surface of the insulator 250b. Furthermore, the insulator 254b is provided in contact with the side surface and the bottom surface of the insulator 274.

The insulator 254a and the insulator 254b are formed through the same step. Thus, the insulator 254a and the insulator 254b contain the same insulating material. The thickness of the insulator 254a is equal to that of the insulator 254b.

The insulator 247 is positioned between the conductor 262a and the insulator 277c, the insulator 278, and the insulator 285. Furthermore, the insulator 247 is positioned between the conductor 262c and the insulator 277b, the insulator 278, and the insulator 285. The insulator 247 is provided in contact with the side surface of the conductor 262a or the conductor 262c.

The insulator 247 preferably functions as a barrier insulating film that inhibits impurities such as water and hydrogen from diffusing into the conductor 262a or the conductor 262c. This can inhibit diffusion of impurities such as hydrogen contained in the insulator 285 into the oxide 230_2 through the conductor 262a or the conductor 262c. As the insulator 247, an insulator that can be used as the insulator 254a can be used. For example, silicon nitride deposited by a PEALD method is used as the insulator 247. In this case, the insulator 247 contains at least nitrogen and silicon.

Note that an insulator formed using the same material as the insulator 247 is sometimes formed to cover the side surface of the conductor 260 in a region exposed from the insulator 276.

The insulator 212 is provided over a substrate (not illustrated) and is provided below the insulator 216 and the conductor 244.

The insulator 212 functions as an interlayer film. The insulator 212 preferably functions as a barrier insulating film that inhibits diffusion of impurities such as water and hydrogen into the transistor 200 from the substrate side. Providing the insulator 212 can inhibit diffusion of impurities such as water and hydrogen to the transistor 200 side from the substrate side.

As the insulator 212, an insulator that can be used as the insulator 254a described above may be used. For example, the insulator 212 is preferably formed using a nitride containing silicon such as silicon nitride or silicon nitride oxide. Specifically, silicon nitride deposited by a sputtering method is used as the insulator 212. When the insulator 212 is deposited by a sputtering method, high-density silicon nitride can be formed. As the insulator 212, a film of silicon nitride deposited by a PEALD method or a CVD method may be stacked over a film of silicon nitride deposited by a sputtering method.

### <Method for Manufacturing Semiconductor Device>

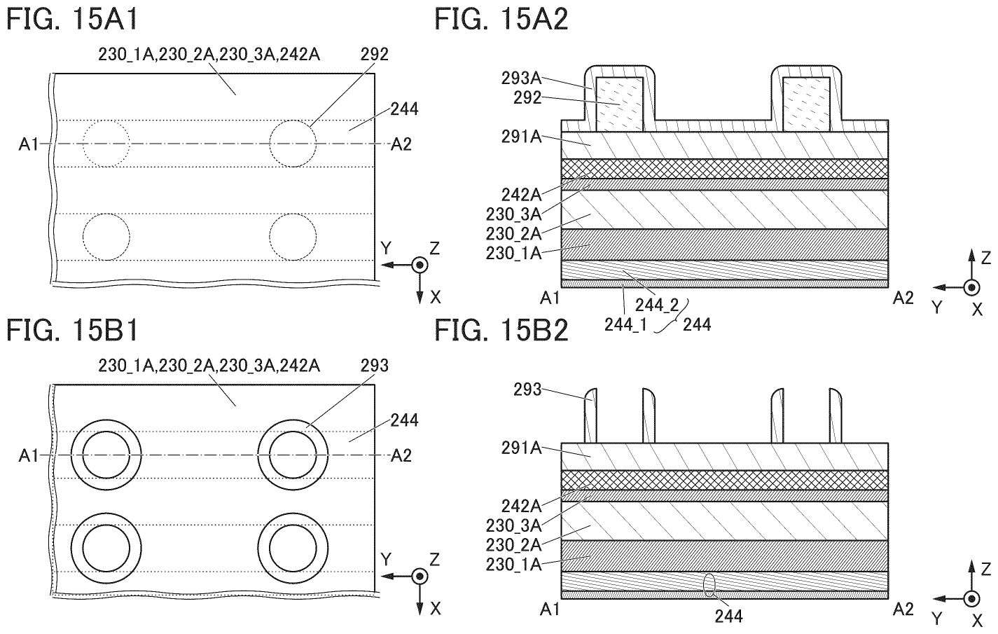

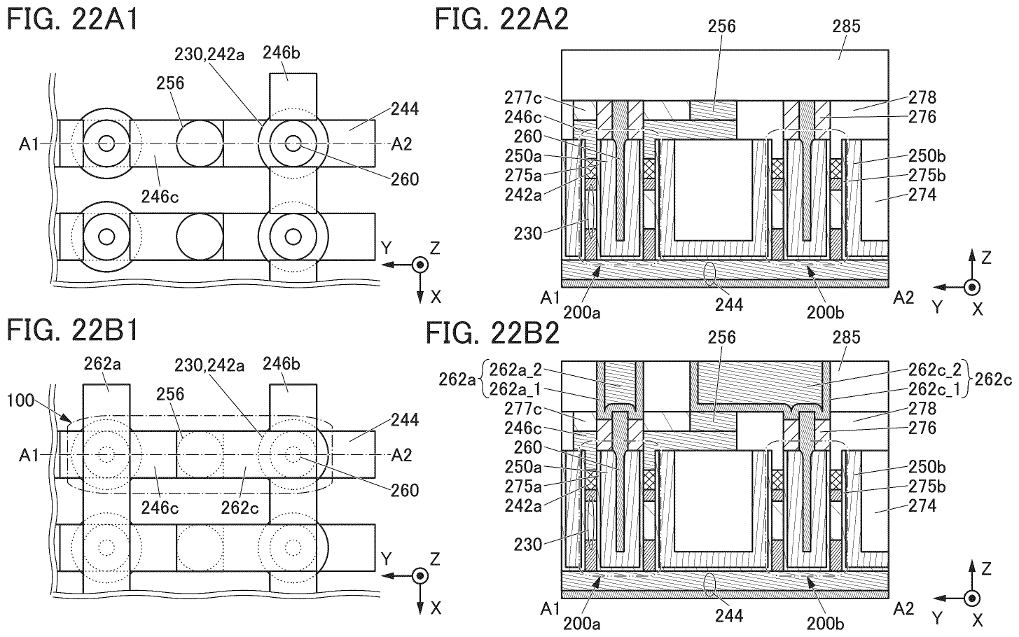

Next, a method for manufacturing the semiconductor device illustrated in FIG. 13A to FIG. 13D is described with reference to FIG. 15A1 to FIG. 22B2.

In FIG. 15A1 to FIG. 22B2, the drawings A1 and B1 are top views. Moreover, each of the drawings A2 and B2 is a cross-sectional view corresponding to a portion indicated by the dashed-dotted line A1-A2 in the corresponding drawing A1 or B1. For clarity of the drawings, some components are omitted in the top views of the drawings A1 and B1.

Hereinafter, an insulating material for forming an insulator, a conductive material for forming a conductor, or a semiconductor material for forming a semiconductor can be deposited by a plating method, a sputtering method, a CVD method, an MBE method, a PLD method, an ALD method, or the like as appropriate.

Examples of the sputtering method include an RF sputtering method in which a high-frequency power source is used as a sputtering power source, and a DC sputtering method in which a direct-current power source is used. The DC sputtering method includes a pulsed DC sputtering method in which a voltage is applied while being changed in a pulsed manner. The RF sputtering method is mainly used in the case where an insulating film is formed, and the DC sputtering method is mainly used in the case where a metal conductive film is formed. The pulsed DC sputtering method is mainly used in the case where a compound such as an oxide, a nitride, or a carbide is deposited by a reactive sputtering method.

Note that the CVD method can be classified into a plasma CVD (PECVD) method using plasma, a thermal CVD (TCVD) method using heat, a photo CVD method using light, and the like. Moreover, the CVD method can be classified into a metal CVD (MCVD) method and a metal organic CVD (MOCVD) method depending on a source gas to be used.

A high-quality film can be obtained at a relatively low temperature by the plasma CVD method. Furthermore, the thermal CVD method is a deposition method that does not use plasma and thus enables less plasma damage to an object to be processed. For example, a wiring, an electrode, an element (a transistor, a capacitor, or the like), or the like included in a semiconductor device might be charged up by receiving electric charge from plasma. In this case, accumulated electric charge might break the wiring, the electrode, the element, or the like included in the semiconductor device. By contrast, such plasma damage is not caused in the case of the thermal CVD method, which does not use plasma, and thus the yield of the semiconductor device can be increased. In addition, the thermal CVD method does not cause plasma damage during deposition, so that a film with few defects can be obtained.

As an ALD method, a thermal ALD method, in which a precursor and a reactant react with each other only by a thermal energy, a PEALD method, in which a reactant excited by plasma is used, or the like can be used.

The CVD method and the ALD method are different from the sputtering method in which particles ejected from a target or the like are deposited. Thus, the CVD method and the ALD method are deposition methods that enable good step coverage almost regardless of the shape of an object to be processed. In particular, an ALD method enables excellent step coverage and excellent thickness uniformity and thus is suitable for covering a surface of an opening portion with a high aspect ratio, for example. On the other hand, the ALD method has a relatively low deposition rate, and thus is preferably used in combination with another deposition method with a high deposition rate, such as the CVD method, in some cases.

By the CVD method, a film with a certain composition can be deposited depending on the flow rate ratio of the source gases. For example, by the CVD method, a film whose composition is continuously changed can be deposited by changing the flow rate ratio of the source gases during deposition. In the case where the film is deposited while the flow rate ratio of the source gases is changed, as compared with the case where the film is deposited using a plurality of deposition chambers, the time taken for the deposition can be shortened because the time taken for transfer or pressure adjustment is not required. Thus, the productivity of the semiconductor device can be increased in some cases.

By the ALD method, a film with a certain composition can be deposited by concurrently introducing different kinds of precursors. In the case where different kinds of precursors are introduced, a film with a certain composition can be deposited by controlling the number of cycles for each of the precursors.

First, a substrate (not illustrated) is prepared, and the insulator 216 (not illustrated) is deposited over the substrate. The insulator 216 is preferably deposited by a sputtering method.

By using a sputtering method that does not need to use a molecule containing hydrogen as a deposition gas, the hydrogen concentration in the insulator 216 can be reduced.

In this embodiment, as the insulator 216, silicon oxide is deposited by a pulsed DC sputtering method using a silicon target in an atmosphere containing an oxygen gas. The use of a pulsed DC sputtering method enables the film thickness distribution to be more uniform and the sputtering rate, deposition rate, and film quality to be improved.

When the insulator 212 illustrated in FIG. 14B is provided, the insulator 212 and the insulator 216 are preferably successively deposited without exposure to the air. For example, a multi-chamber film formation apparatus is used. As a result, the amounts of hydrogen in the insulator 212 and the insulator 216 can be reduced, and furthermore, entry of hydrogen into the films in intervals between deposition steps can be inhibited.

Then, an opening is formed in the insulator 216. Examples of the opening include a groove and a slit. A region where an opening is formed is referred to as an opening portion in some cases. Wet etching may be used for the formation of the opening; however, dry etching is preferably used for microfabrication.

As a dry etching apparatus, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a dry etching apparatus including a high-density plasma source can be used. As the dry etching apparatus including a high-density plasma source, an inductively coupled plasma (ICP) etching apparatus or the like can be used, for example.

Note that an insulator functioning as an etching stopper film in forming the opening by etching the insulator 216 is preferably provided in contact with the bottom surface of the insulator 216. For example, in the case where silicon oxide or silicon oxynitride is used for the insulator 216 in which the opening is to be formed, silicon nitride, aluminum oxide, or hafnium oxide is preferably used for the insulator. For example, the insulator 212 illustrated in FIG. 14B may be provided as the insulator. In other words, the insulator 212 preferably has the function.

After the formation of the opening, a conductive film to be the conductor 244_1 is deposited. The conductive film desirably includes a conductor having a function of inhibiting passage of oxygen. For example, tantalum nitride, tungsten nitride, or titanium nitride can be used. Alternatively, a stacked-layer film of the conductor having a function of inhibiting passage of oxygen and tantalum, tungsten, titanium, molybdenum, aluminum, copper, or a molybdenum-tungsten alloy can be used.

In this embodiment, a titanium nitride film is formed as the conductive film to be the conductor 244_1. When such a metal nitride is provided below the conductor 244_2, oxidation of the conductor 244_2 by the insulator 216 or the like can be inhibited. Furthermore, even when a metal that is likely to diffuse, such as copper, is used for the conductor 244_2, the metal can be prevented from diffusing to the outside through the conductor 244_1.

Next, a conductive film to be the conductor 244_2 is deposited. Tantalum, tungsten, titanium, molybdenum, aluminum, copper, a molybdenum-tungsten alloy, or the like can be used for the conductive film. In this embodiment, a tungsten film is deposited as the conductive film.

Next, by performing CMP treatment, the conductive film to be the conductor 244_1 and the conductive film to be the conductor 244_2 are partly removed to expose the insulator 216. As a result, the conductor 244_1 and the conductor 244_2 remain only in the opening portion formed in the insulator 216, so that the conductor 244 (the conductor 244_1 and the conductor 244_2) is formed. Note that the insulator 216 is partly removed by the CMP treatment in some cases.

Next, an oxide film 230_1A, an oxide film 230_2A, and an oxide film 230_3A are deposited in this order over the insulator 216 and the conductor 244 (see FIG. 15A1 and FIG. 15A2). The oxide film 230_1A, the oxide film 230_2A, and the oxide film 230_3A are preferably deposited successively without being exposed to the air environment. Depositing these films without being exposed to the air environment can prevent impurities or moisture from the air environment from attaching onto the oxide film 230_1A and the oxide film 230_2A; this can keep clean the interface between the oxide film 230_1A and the oxide film 230_2A, the vicinity of the interface, the interface between the oxide film 230_2A and the oxide film 230_3A, and the vicinity of the interface.

For example, in the case where the oxide film 230_1A, the oxide film 230_2A, and the oxide film 230_3A are deposited by a sputtering method, oxygen or a mixed gas of oxygen and a noble gas is used as a sputtering gas. Increasing the proportion of oxygen contained in the sputtering gas can increase the amount of excess oxygen in the deposited oxide films. In the case where the above oxide films are deposited by a sputtering method, a target of the above-described In-M-Zn oxide or the like can be used.

In the case where a metal oxide film to which nitrogen is added is deposited by a sputtering method as the oxide film 230_1A and the oxide film 230_3A, a metal oxide film to which nitrogen is added can be deposited even with a structure in which a target does not contain nitrogen by performing deposition using a sputtering gas containing a nitrogen gas. In the case where a metal oxide film is deposited by adding a nitrogen gas, the higher the nitrogen flow rate ratio is, the higher the carrier mobility of the metal oxide film can be.

The nitrogen flow rate ratio can be set as appropriate in a range of from 10% to 100% inclusive in accordance with characteristics required for the oxide 230_1 and the oxide 230_3. At this time, for example, the sputtering gas can be a mixed gas of a nitrogen gas and an argon gas.

The sputtering gas may be a mixed gas of a nitrogen gas and an oxygen gas or a mixed gas of a nitrogen gas, an oxygen gas, and an argon gas.

In the case of using a target containing nitrogen, a structure not using nitrogen as a sputtering gas can be employed for depositing a metal oxide film to which nitrogen is added.

In the case where the sputtering gas for the oxide film 230_1A contains an oxygen gas, part of oxygen contained in the sputtering gas is supplied to the insulator 216 in some cases. Thus, the proportion of oxygen contained in the sputtering gas is higher than or equal to 70%, preferably higher than or equal to 80%, further preferably 100%.

It is preferable to highly purify the above-described sputtering gas. For example, as an oxygen gas, a nitrogen gas, or an argon gas used as the sputtering gas, a gas highly purified to have a dew point of −40° C. or lower, preferably −80° C. or lower, further preferably −100° C. or lower, still further preferably −120° C. or lower is used, whereby entry of moisture or the like into the metal oxide film can be prevented as much as possible.

In the case where the oxide film 230_2A is deposited by a sputtering method and the proportion of oxygen contained in the sputtering gas is higher than 30% and lower than or equal to 100%, preferably higher than or equal to 70% and lower than or equal to 100%, an oxygen-excess oxide semiconductor is formed. In a transistor using an oxygen-excess oxide semiconductor for its channel formation region, relatively high reliability can be obtained. Note that one embodiment of the present invention is not limited thereto. In the case where the oxide film 230_2A is formed by a sputtering method and the proportion of oxygen contained in the sputtering gas for deposition is higher than or equal to 1% and lower than or equal to 30%, preferably higher than or equal to 5% and lower than or equal to 20%, an oxygen-deficient oxide semiconductor is formed. In a transistor using an oxygen-deficient oxide semiconductor in its channel formation region, relatively high field-effect mobility can be obtained. Furthermore, when the deposition is performed while the substrate is being heated, the crystallinity of the oxide film can be improved.

For the deposition method of the oxide film 230_3A, the deposition method of the oxide film 230_1A can be referred to.

Note that the insulating film 230_1A, the oxide film 230_2A, and the oxide film 230_3A are preferably deposited by a sputtering method without exposure to the air. For example, a multi-chamber film formation apparatus is used. As a result, entry of hydrogen into the oxide film 230_1A, the oxide film 230_2A, and the oxide film 230_3A in intervals between deposition steps can be inhibited.

In the case where a metal oxide film to which nitrogen is added is deposited by a sputtering method as each of the oxide film 230_1A and the oxide film 230_3A and a metal oxide film is deposited by a sputtering method as the oxide film 230_2A, switching the kind of gas introduced into the sputtering apparatus, i.e., stopping the introduction of nitrogen, after the deposition of the oxide film 230_1A enables the deposition of the oxide film 230_2A. Furthermore, after the deposition of the oxide film 230_2A, the kind of gas introduced into the sputtering apparatus is switched, that is, nitrogen is introduced, so that the oxide film 230_3A is deposited. Thus, the oxide film 230_1A, the oxide film 230_2A, and the oxide film 230_3A can be successively deposited, which is excellent in mass productivity.

In this embodiment, as each of the oxide film 230_1A and the oxide film 230_3A, a metal oxide film to which nitrogen is added is deposited by a sputtering method. In addition, the oxide film 230_2A is deposited by a sputtering method using an oxide target with In:Ga:Zn=4:2:4.1 [atomic ratio], an oxide target with In:Ga:Zn=1:1:1 [atomic ratio], an oxide target with In:Ga:Zn=1:1:1.2 [atomic ratio], or an oxide target with In:Ga:Zn=1:1:2 [atomic ratio]. Note that each of the oxide 230_1, the oxide 230_2 and the oxide 230_3 is preferably formed so as to have characteristics required for the respective oxide films by selecting the deposition conditions and the atomic ratios as appropriate.

Next, heat treatment is preferably performed. The heat treatment is performed in a temperature range where the oxide film 230_1A, the oxide film 230_2A, and the oxide film 230_3A do not become polycrystals, i.e., at a temperature higher than or equal to 250° C. and lower than or equal to 650° C., preferably higher than or equal to 400° C. and lower than or equal to 600° C. Note that the heat treatment is performed in a nitrogen gas or inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is approximately 20%. The heat treatment may be performed under reduced pressure. Alternatively, the heat treatment may be performed in an atmosphere containing an oxidizing gas at 10 ppm or more, 1% or more, or 10% or more in order to compensate for oxygen released, after heat treatment is performed in a nitrogen gas or inert gas atmosphere.

The gas used in the above heat treatment is preferably highly purified. For example, the amount of moisture contained in the gas used in the above heat treatment is less than or equal to 1 ppb, preferably less than or equal to 0.1 ppb, further preferably less than or equal to 0.05 ppb. The heat treatment using a highly purified gas can prevent entry of moisture or the like into the oxide film 230_1A, the oxide film 230_2A, the oxide film 230_3A, and the like as much as possible.

In this embodiment, the heat treatment is performed at 400° C. for one hour with a flow rate ratio of a nitrogen gas to an oxygen gas being 4:1. By the heat treatment using the oxygen gas, impurities such as carbon, water, and hydrogen in the oxide film 230_2A can be reduced, for example. Furthermore, the reduction of impurities in the film improves the crystallinity of the oxide film 230_2A, thereby offering a dense structure with higher density. Accordingly, the crystal region in the oxide film 230_2A can be expanded, and in-plane variation of the crystal region in the oxide film 230_2A can be reduced. Accordingly, an in-plane variation of electrical characteristics of the transistor 200 can be reduced.

By performing the heat treatment, the hydrogen concentrations in the insulator 216 and the oxide film 230_2A can be reduced. In particular, the oxide 230_2 formed from the oxide film 230_2A functions as the channel formation region of the transistor 200. Thus, the transistor 200 preferably includes the oxide film 230_2 with reduced hydrogen concentration in terms of favorable reliability.

Next, the conductive film 242A is deposited over the oxide film 230_3A (see FIG. 15A1 to FIG. 15A2). For example, as the conductive film 242A, a tantalum nitride film is formed by a sputtering method. Note that heat treatment may be performed before the deposition of the conductive film 242A. This heat treatment may be performed under reduced pressure, and the conductive film 242A may be successively deposited without exposure to the air. The treatment can remove moisture and hydrogen adsorbed onto the surface of the oxide film 230_3A, and further can reduce the moisture concentration and the hydrogen concentration in the oxide film 230_1A, the oxide film 230_2A, and the oxide film 230_3A. The heat treatment temperature is preferably higher than or equal to 100° C. and lower than or equal to 400° C. In this embodiment, the heat treatment temperature is 200° C.

Next, an insulating film 291A is deposited over the conductive film 242A (see FIG. 15A1 to FIG. 15A2). As the insulating film 291A, an insulating film having a function of inhibiting passage of oxygen is preferably used. For example, as the insulating film 291A, an aluminum oxide film or a silicon nitride film may be deposited by a sputtering method.

Note that the conductive film 242A and the insulating film 291A are preferably deposited by a sputtering method without exposure to the air. For example, a multi-chamber film formation apparatus is used. As a result, the amounts of hydrogen in the conductive film 242A and the insulating film 291A can be reduced, and furthermore, entry of hydrogen into the films in intervals between deposition steps can be inhibited. In the case where a hard mask is provided over the insulating film 291A, a film to be the hard mask is preferably successively deposited without exposure to the air.

Next, the oxide film 230_1A, the oxide film 230_2A, the oxide film 230_3A, a conductive film 242A, and the insulating film 291A are processed into hollow cylindrical shapes by a lithography method to form the oxide 230 (the oxide 230_1, the oxide 230_2, the oxide 230_3), the conductor 242a, and an insulator 291. Here, the oxide 230_1, the oxide 230_2, the oxide 230_3, the conductor 242a, and the insulator 291 are formed to at least partly overlap with the conductor 244. A dry etching method or a wet etching method can be employed for the processing.

In the lithography method, first, a resist is exposed to light through a mask. Next, a region exposed to light is removed or left using a developing solution, so that a resist mask is formed. Then, etching treatment through the resist mask is performed, whereby a conductor, a semiconductor, an insulator, or the like can be processed into a desired shape. The resist mask may be formed through, for example, exposure of the resist to KrF excimer laser light, ArF excimer laser light, EUV light, or the like. A liquid immersion technique may be employed in which a gap between a substrate and a projection lens is filled with a liquid (e.g., water) in light exposure. An electron beam or an ion beam may be used instead of the light. Note that a mask is unnecessary in the case of using an electron beam or an ion beam. Note that the resist mask can be removed by dry etching treatment such as ashing, wet etching treatment, wet etching treatment after dry etching treatment, or dry etching treatment after wet etching treatment.

In addition, a hard mask formed of an insulator or a conductor may be used under the resist mask. In the case of using a hard mask, a hard mask with a desired shape can be formed in the following manner: an insulating film or a conductive film that is the material of the hard mask is formed over the conductive film 242A, a resist mask is formed thereover, and then the hard mask material is etched. The etching of the conductive film 242A and the like may be performed after removing the resist mask or with the resist mask remaining. In the latter case, the resist mask sometimes disappears during the etching. The hard mask may be removed by etching after the etching of the conductive film 242A and the like. Meanwhile, the hard mask is not necessarily removed when the hard mask material does not affect later steps or can be utilized in later steps. In this embodiment, the insulator 291 is used as a hard mask.

Described below is an example of a method for forming the oxide 230 (the oxide 230_1, the oxide 230_2, and the oxide 230_3), the conductor 242a, and the insulator 291 each of which has a hollow cylindrical shape with a lithography method.

First, a resist mask 292 is formed over the insulating film 291A (see FIG. 15A1 and FIG. 15A2). At least part of the resist mask 292 is provided in a region overlapping with the conductor 244.

Although the top surface shape of the resist mask 292 is circular, the present invention is not limited thereto; for example, the top surface may have an elliptical shape or a polygonal shape such as a triangular shape or a quadrangular shape. When the top surface has a polygonal shape, the polygonal shape may have rounded corners.

The resist mask 292 can be formed in the following manner; for example, a resist is exposed to light through a mask and a region exposed to light is removed or left using a developing solution. The resist mask 292 may be shrunk by isotropic etching with oxygen plasma. The shrinkage of the resist mask is referred to resist slimming or resist trimming, in some cases. Shrinking the resist mask 292 enables the resist mask 292 to be miniaturized.

Alternatively, the resist mask 292 may be formed, for example, in the following manner: a resist is exposed to light through a mask capable of forming a line pattern, the resist is exposed to light again through the mask rotated by 90 degrees around the Z-axis, and the exposed region is removed or left using a developing solution. The top surface of the resist mask 292 processed in such a manner has a shape with rounded corners or a circular shape.

The above-described multi-patterning technique is preferably employed for forming the resist mask 292. For example, the resist mask 292 may be formed in the following manner: a resist mask with a line pattern extending in the X direction is formed using a multi-patterning technique, and the resist mask with the line pattern extending in the X direction is processed with a multi-patterning technique for forming a resist mask with a line pattern extending in the Y direction. The top surface shape of the resist mask 292 processed in such a manner has a shape with rounded corners or a circular shape.

Next, an insulating film 293A is deposited over the resist mask 292 (see FIG. 15A1 and FIG. 15A2). The thickness of the insulating film 293A corresponds to the width H1 illustrated in FIG. 13D. Thus, the thickness of the insulating film 293A is set as appropriate in accordance with the design of the transistor 200.

Next, the insulating film 293A is subjected to anisotropic etching, so that an insulator 293 is formed (see FIG. 15B1 and FIG. 15B2). For the anisotropic etching of the insulating film 293A, a dry etching method is employed, for example. When the insulating film 293A is subjected to anisotropic etching, the insulator 293 is formed on the side surface of the resist mask 292. That is, the insulator 293 can be rephrased as a sidewall.

Next, the resist mask 292 is removed (see FIG. 15B1 and FIG. 15B2). When the resist mask 292 is removed, the insulator 293 remains over the insulating film 291A. Note that the top surface shape of an opening that the insulator 293 has corresponds to the top surface shape of the resist mask 292. For example, in the case where the top surface of the resist mask 292 has a circular shape, the top surface of the insulator 293 has a hollow cylindrical shape as illustrated in FIG. 15B1. In the case where the top surface shape of the resist mask 292 has the above-described elliptical shape, the top surface of the insulator 293 has a hollow elliptical shape. In the case where the top surface shape of the resist mask 292 has a polygonal shape with rounded corners, the top surface of the insulator 293 has a hollow polygonal shape with rounded corners.

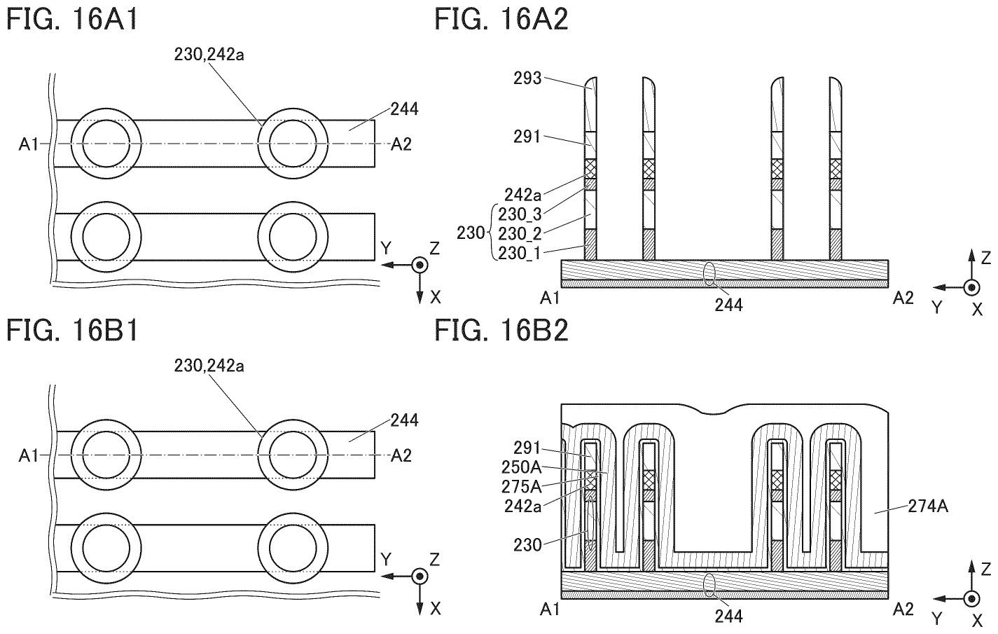

Next, the insulating film 291A, the conductive film 242A, the oxide film 230_3A, the oxide film 230_2A, and the oxide film 230_1A are partly processed with use of the insulator 293 as a hard mask until the top surfaces of the insulator 216 and the conductor 244 are exposed (see FIG. 16A1 and FIG. 16A2). A dry etching method or a wet etching method can be employed for the processing. Processing by a dry etching method is suitable for microfabrication. The insulating film 291A, the conductive film 242A, the oxide film 230_3A, the oxide film 230_2A, and the oxide film 230_1A may be processed under different conditions.

By the above processing, the insulator 291, the conductor 242a, and the oxide 230 (the oxide 230_3, the oxide 230_2, and the oxide 230_1) whose top surface shapes are the same or substantially the same as the top surface shape of the insulator 293 are formed (see FIG. 16A1 and FIG. 16A2). That is, in the top view, end portions of the insulator 291, the conductor 242a, and the oxide 230 are aligned with each other. Each of the oxide 230, the conductor 242a, and the insulator 291 has a hollow cylindrical shape. As described above, the top surface shapes of the oxide 230, the conductor 242a, and the insulator 291 correspond to the top surface shape of the resist mask 292. Thus, the hollow cylindrical shape can be rephrased as appropriate in accordance with the top surface shape of the resist mask 292.

The above is an example of a method for forming the oxide 230, the conductor 242a, and the insulator 291 each of which has a hollow cylindrical shape with a lithography method.

Note that the side surfaces of the oxide 230 and the conductor 242a are preferably perpendicular to the top surface of the insulator 216. With such a structure, a plurality of the transistors 200 can be provided with high density in a small area.

Note that the present invention is not limited to the above structure. As described with reference to FIG. 11A, the side surfaces of the oxide 230 and the conductor 242a may each have a tapered shape. With such tapered shapes of the side surfaces, the coverage with an insulating film to be the insulator 275a and the like can be improved in a later step, so that defects such as voids can be reduced.

Next, the insulator 293 is removed (see FIG. 16B1 and FIG. 16B2).

Up to this step, attachment of impurities to the side surfaces of the oxide 230, the conductor 242a, and the insulator 291 or diffusion of the impurities into them may be caused. A step of removing the impurities may be performed. Examples of the impurities include hafnium, aluminum, silicon, tantalum, fluorine, and chlorine.

In order to remove impurities attached to the side surface of the oxide 230 in the above etching step, cleaning treatment is performed. Examples of the cleaning method include wet cleaning using a cleaning solution (also can be referred to as wet etching process), plasma treatment using plasma, and cleaning by heat treatment, and any of these cleanings may be performed in combination as appropriate. Note that the cleaning treatment sometimes makes the groove portion deeper.

The wet cleaning may be performed using an aqueous solution in which ammonia water, oxalic acid, phosphoric acid, hydrofluoric acid, or the like is diluted with carbonated water or pure water; pure water; carbonated water; or the like. Alternatively, ultrasonic cleaning using such an aqueous solution, pure water, or carbonated water may be performed. Alternatively, such cleaning methods may be performed in combination as appropriate.

Note that in this specification and the like, in some cases, an aqueous solution in which hydrofluoric acid is diluted with pure water is referred to as diluted hydrofluoric acid, and an aqueous solution in which ammonia water is diluted with pure water is referred to as diluted ammonia water. The concentration, temperature, and the like of the aqueous solution are adjusted as appropriate in accordance with an impurity to be removed, the structure of a semiconductor device to be cleaned, or the like. The concentration of ammonia in the diluted ammonia water is higher than or equal to 0.01% and lower than or equal to 5%, preferably higher than or equal to 0.1% and lower than or equal to 0.5%. The concentration of hydrogen fluoride in the diluted hydrofluoric acid is higher than or equal to 0.01 ppm and lower than or equal to 100 ppm, preferably higher than or equal to 0.1 ppm and lower than or equal to 10 ppm.

A frequency greater than or equal to 200 kHz, preferably greater than or equal to 900 kHz is preferably used for the ultrasonic cleaning. Damage to the oxide 230 and the like can be reduced with this frequency.

The cleaning treatment may be performed a plurality of times, and the cleaning solution may be changed in every cleaning treatment. For example, first cleaning treatment may use diluted hydrofluoric acid or diluted ammonia water, and second cleaning treatment may use pure water or carbonated water.

After the etching or the cleaning, heat treatment may be performed. The heat treatment is performed at higher than or equal to 100° C. and lower than or equal to 450° C., preferably higher than or equal to 350° C. and lower than or equal to 400° C. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, the heat treatment is preferably performed in an oxygen atmosphere. Accordingly, oxygen can be supplied to the oxide 230_2 to reduce oxygen vacancies. In addition, the crystallinity of the oxide 230_2 can be improved by such heat treatment. The heat treatment may be performed under reduced pressure. Alternatively, heat treatment may be performed in an oxygen atmosphere, and then heat treatment may be successively performed in a nitrogen atmosphere without exposure to the air.

Note that the cleaning treatment and the heat treatment may be performed before the insulator 293 is removed.

Next, an insulating film 275A is deposited over the insulator 216, the conductor 244, and the insulator 291 (see FIG. 16B1 and FIG. 16B2). In other words, the insulating film 275A is deposited to cover the oxide 230, the conductor 242a, and the insulator 291.

The insulating film 275A is preferably deposited by an ALD method. As described above, it is preferable to deposit the insulating film 275A to have a small thickness, and a variation in the film thickness needs to be small. Since an ALD method is a deposition method in which a precursor and a reactant (e.g., oxidizer) are alternately introduced and the film thickness can be adjusted with the number of repetition times of the cycle, accurate control of the film thickness is possible. As illustrated in FIG. 16B1 and FIG. 16B2, the insulating film 275A needs to be deposited on the side surface of the opening formed in the oxide 230, the conductor 242a, and the insulator 291 and the top surfaces of the conductor 244 and the insulator 216 with good coverage. In particular, it is preferable that the insulating film 275A be deposited on the side surface of the oxide 230 and the side surface of the conductor 242a with good coverage. The ALD method enables an atomic layer to be deposited one by one on the bottom surface and the side surface of the opening portion, whereby the insulating film 275A can be formed in the opening with good coverage.

When the insulating film 275A is deposited by an ALD method, ozone (O₃), oxygen (O₂), water (H₂O), or the like can be used as the oxidizer. When an oxidizer that does not contain hydrogen, such as ozone (O₃) or oxygen (O₂), is used, the amount of hydrogen diffusing into the oxide 230 can be reduced.

As the insulating film 275A, an insulating film having a function of inhibiting passage of oxygen is preferably used. For example, an aluminum oxide film can be deposited as the insulating film 275A by an ALD method. In this manner, the oxide 230 and the conductor 242a can be covered with the insulating film 275A having a function of inhibiting diffusion of oxygen. This structure can inhibit direct diffusion of oxygen from the insulator 274 or the like into the oxide 230 and the conductor 242a in a later step.

Next, microwave treatment may be performed in an oxygen-containing atmosphere. Here, the microwave treatment refers to, for example, treatment using an apparatus including a power source that generates high-density plasma with the use of a microwave. In this specification and the like, a microwave refers to an electromagnetic wave having a frequency greater than or equal to 300 MHz and less than or equal to 300 GHz.

The microwave treatment is preferably performed with a microwave treatment apparatus including a power source for generating high-density plasma using microwaves, for example. Here, the frequency of the microwave treatment apparatus is set to higher than or equal to 300 MHz and lower than or equal to 300 GHz, preferably higher than or equal to 2.4 GHz and lower than or equal to 2.5 GHZ, for example, 2.45 GHz. Oxygen radicals at a high density can be generated with high-density plasma. The electric power of the power source that applies microwaves of the microwave treatment apparatus is set to higher than or equal to 1000 W and lower than or equal to 10000 W, preferably higher than or equal to 2000 W and lower than or equal to 5000 W. The microwave treatment apparatus may be provided with a power source that applies RF to the substrate side. Furthermore, application of RF to the substrate side allows oxygen ions generated by the high-density plasma to be efficiently introduced into the oxide 230_2.

The microwave treatment is preferably performed under reduced pressure, and the pressure is set to higher than or equal to 10 Pa and lower than or equal to 1000 Pa, preferably higher than or equal to 300 Pa and lower than or equal to 700 Pa. The treatment temperature may be lower than or equal to 750° C., preferably lower than or equal to 500° C., and is approximately 400° C., for example. The oxygen plasma treatment may be followed successively by heat treatment without exposure to the air. For example, the temperature is set to higher than or equal to 100° C. and lower than or equal to 750° C., preferably higher than or equal to 300° C. and lower than or equal to 500° C.

Furthermore, the microwave treatment is performed using an oxygen gas and an argon gas, for example. Here, the oxygen flow rate ratio (O₂/(O₂+Ar)) is higher than 0% and lower than or equal to 100%, preferably higher than 0% and lower than or equal to 50%, further preferably higher than or equal to 10% and lower than or equal to 40%, or still further preferably higher than or equal to 10% and lower than or equal to 30%. The carrier concentration in the oxide 230_2 can be reduced by thus performing the microwave treatment in an atmosphere containing oxygen. In addition, the carrier concentrations in the oxide 230_2 and the oxide 230_3 can be prevented from being excessively reduced by preventing an excess amount of oxygen from being introduced into the chamber in the microwave treatment.

The microwave treatment in an oxygen-containing atmosphere converts an oxygen gas into plasma using a high-frequency wave such as a microwave or RF and makes the oxygen plasma act on the oxide 230_2. At this time, the region 230_2 can also be irradiated with the high-frequency wave such as the microwave or RF. In other words, the microwave, the high-frequency wave such as RF, the oxygen plasma, or the like can be applied to the oxide 230_2. The effect of the plasma, the microwave, or the like enables V_{O}H in the oxide 230_2 to be cut, and hydrogen to be removed from the oxide 230_2. That is, V_{O}H contained in the oxide 230_2 can be reduced. As a result, oxygen vacancies and V_{O}H in the oxide 230_2 can be reduced to lower the carrier concentration. In addition, oxygen radicals generated by the oxygen plasma or oxygen contained in the insulator 275a can be supplied to oxygen vacancies formed in the oxide 230_2, thereby further reducing oxygen vacancies and lowering the carrier concentration in the oxide 230_2.

Furthermore, the insulating film 275A having a barrier property against oxygen is provided in contact with the side surfaces of the conductor 242a. Thus, formation of an oxide film on the side surface of the conductor 242a by the microwave treatment can be inhibited.

Furthermore, the film quality of the insulating film 275A can be improved, leading to higher reliability of the transistor 200.

Next, an insulating film 250A is formed over the insulating film 275A (see FIG. 16B1 and FIG. 16B2). The insulating film 250A is preferably formed using an insulator having a function of inhibiting diffusion of oxygen. Such a structure can inhibit oxidation of the conductor 260 due to oxygen contained in the oxide 230. As the insulating film 250A, for example, a hafnium oxide film may be deposited by a thermal ALD method.

In the case where the microwave treatment is not performed after the insulating film 275A is deposited, the insulating film 275A and the insulating film 250A are preferably deposited successively without being exposed to the air environment. By the deposition without exposure to the air, impurities or moisture from the air environment can be prevented from being attached onto the insulating film 275A, so that an interface between the insulating film 275A and the insulating film 250A and the vicinity of the interface can be kept clean.

Next, an insulating film 274A is deposited over the insulating film 250A (see FIG. 16B1 and FIG. 16B2). A silicon oxide film is deposited by a sputtering method as the insulating film 274A, for example. By using a sputtering method that does not need to use a molecule containing hydrogen as a deposition gas, the hydrogen concentration in the insulating film 274A can be reduced. Note that heat treatment may be performed before the insulating film 274A is deposited. In this embodiment, as the insulator film 274A, a silicon oxide film is deposited by a CVD method.

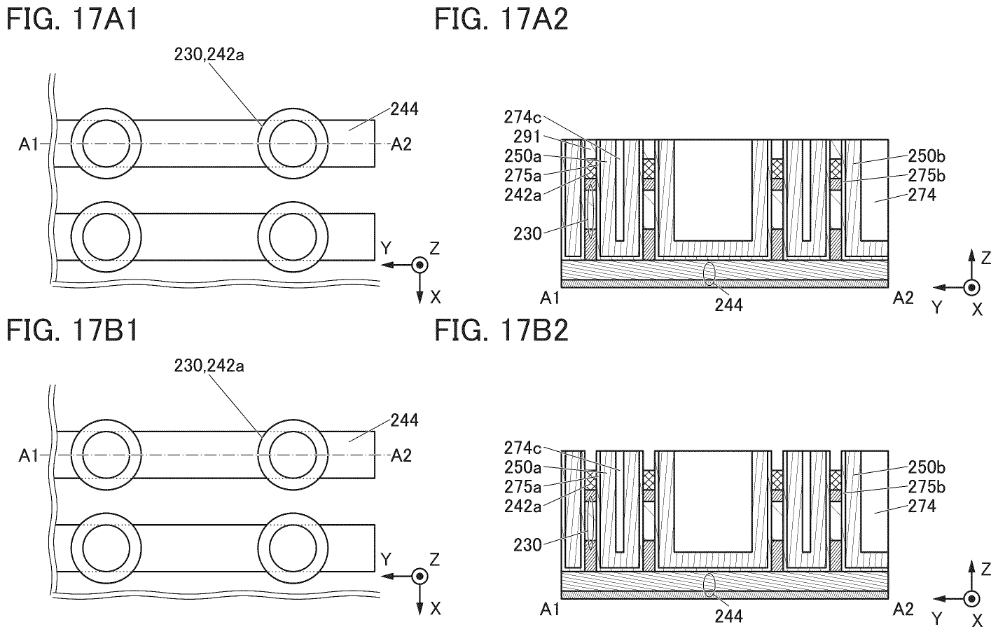

Next, the insulating film 274A, the insulating film 250A, and the insulating film 275A are processed by CMP treatment until the insulator 291 is exposed. By the CMP treatment, the insulator 274 and an insulator 274c are formed from the insulating film 274A, the insulator 250a and the insulator 250b are formed from the insulating film 250A, and the insulator 275a and the insulator 275b are formed from the insulating film 275A (see FIG. 17A1 and FIG. 17A2).

As described above, each of the oxide 230, the conductor 242a, and the insulator 291 has a hollow cylindrical shape. That is, the stack of the oxide 230, the conductor 242a, and the insulator 291 has a hollow cylindrical shape. The insulator 275a is provided to be in contact with the inner wall of the hollow portion of the stack, the top surface of the insulator 216, and the top surface of the conductor 244. The insulator 250a is provided to be in contact with the inner wall and the bottom surface of the depression formed in the insulator 275a. The insulator 274c is provided to fill the depression formed in the insulator 250a.

The insulator 275b is provided in contact with the outer side surface of the stack, the top surface of the insulator 216, and the top surface of the conductor 244. The insulator 250b is provided to be in contact with the top surface of the insulator 275b, and the insulator 274 is provided to be in contact with the top surface of the insulator 250b.

The top surface of the insulator 291 is partly removed by the CMP treatment in some cases.

The top surface of the insulator 274 is level with the top surfaces of the insulator 291 and the insulator 274c. The uppermost portions of the insulator 250a, the insulator 250b, the insulator 275a, and the insulator 275b are level with each other.

Next, the insulator 291 is removed to expose the top surface of the conductor 242a (see FIG. 17B1 and FIG. 17B2). A dry etching method or a wet etching method is preferably used for the removal of the insulator 291.

By removing the insulator 291, the top surface of the conductor 242a can be exposed in a self-aligned manner. Thus, the conductor 246b and the conductor 246c formed later can be placed to be surely in contact with the conductor 242a without positional alignment. Note that in the case where the insulator 291 is removed by etching, an etching condition with a high selectivity is preferably employed so that the insulator 274c is not removed by the etching. Thus, after the insulator 291 is removed, the insulator 274c can remain.

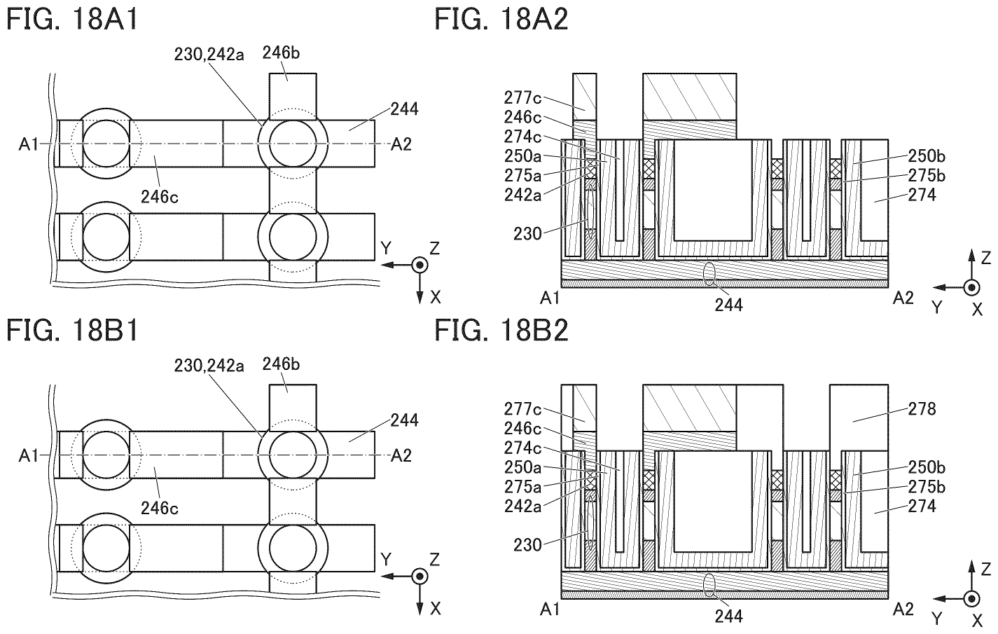

Next, a conductive film to be the conductor 246b and the conductor 246c and an insulating film to be the insulator 277b and the insulator 277c are deposited in this order. Next, part of the conductive film and part of the insulating film are processed by a lithography method (FIG. 18A1 and FIG. 18A2). Through the processing, the conductor 246b, the conductor 246c, the insulator 277b, and the insulator 277c can be formed. At this time, a protruding portion is formed in a region that is of the conductor 246b and overlaps with the conductor 242a and a region that is of the conductor 246c and overlaps with the conductor 242a. Wet etching can be used for the processing; however, dry etching is preferably used for microfabrication.

Next, an insulating film to be the insulator 278 is formed over the insulator 277b, the insulator 277c, the insulator 274, and the like. The insulating film may be deposited using the same material as the insulating film to be the insulator 277b and the insulator 277c or may be deposited using a different material.

Next, the insulating film to be the insulator 278 is processed by CMP treatment until the insulator 277b and the insulator 277c are exposed. By the CMP treatment, the insulator 278 having a flat top surface is formed. Note that the top surfaces of the insulator 277b and the insulator 277c are partly removed by the CMP treatment in some cases.

Next, an opening is formed in a region that is of the insulator 278 and overlaps with the insulator 274c, the insulator 250a, and the insulator 275a (see FIG. 18B1 to FIG. 18B2). Note that in the case where the resist mask 292 is formed using the above-described multi-patterning technique, the above-described multi-patterning technique is used also in the case where the opening is formed in the insulator 278.

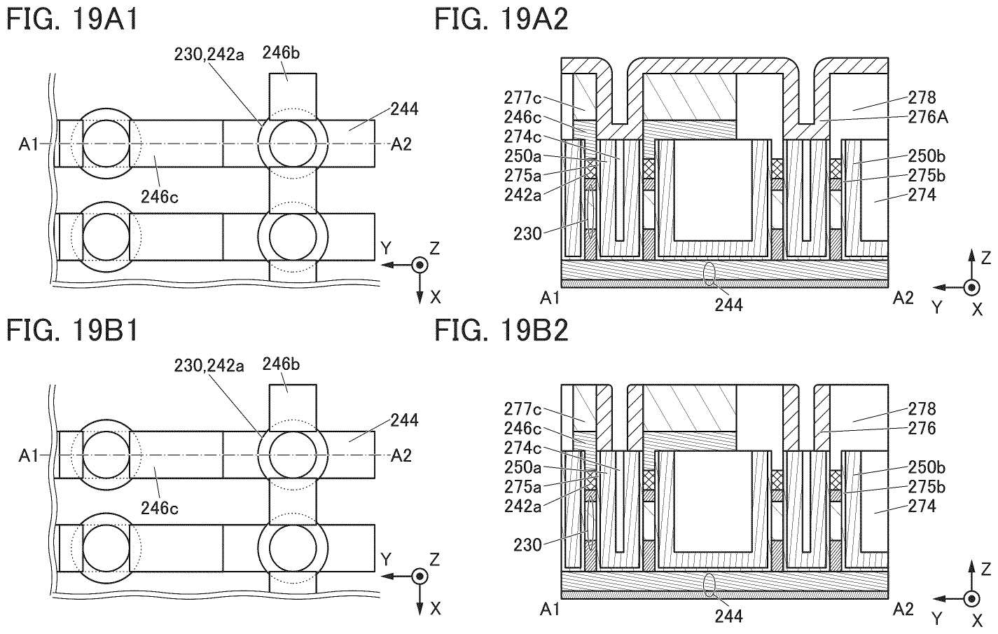

Next, an insulating film 276A is deposited over the insulator 274c, the insulator 250a, the insulator 275a, the insulator 277b, the insulator 277c, and the insulator 278 (see FIG. 19A1 and FIG. 19A2). The insulating film 276A is preferably deposited by an ALD method. The insulating film 276A needs to be deposited on the bottom surface and a side surface of the opening portion formed in the insulator 278 with good coverage. An ALD method enables an atomic layer to be deposited one by one on the bottom surface and the side surface of the opening portion, whereby the insulating film 276A can be deposited on the opening with favorable coverage. In this embodiment, a silicon nitride film is deposited by a PEALD method as the insulating film 276A.

Next, the insulating film 276A is subjected to anisotropic etching to form the insulator 276 (see FIG. 19B1 and FIG. 19B2). By forming the insulator 276, part of the top surface of the insulator 250a and the top surface of the insulator 274c are exposed.

For the anisotropic etching, a dry etching method is preferably employed, for example. When the insulator 276 is provided on the sidewall of the opening portion, the conductor 246b or the conductor 246c can physically keep a distance from the conductor 260 formed later. Thus, electrical continuity between the conductor 246b or the conductor 246c and the conductor 260 can be prevented. In other words, the conductor 246b or the conductor 246c and the conductor 260 can be prevented from being electrically connected to each other.

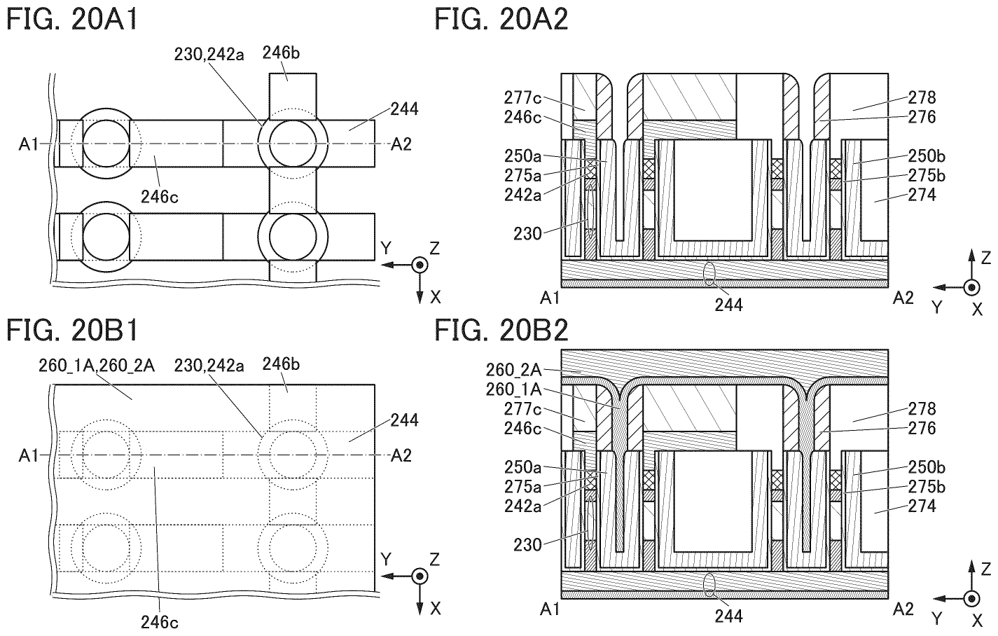

Next, the insulator 274c is removed (see FIG. 20A1 and FIG. 20A2). A dry etching method or a wet etching method is preferably used for the removal of the insulator 274c. Note that in the case where the insulator 274c is removed by etching, an etching condition with a high selectivity is preferably employed so that the insulator 250a and the insulator 276 are not removed by the etching. Thus, after the insulator 274c is removed, the insulator 250a and the insulator 276 can remain.

Next, a conductive film 260_1A and a conductive film 260_2A are deposited in this order (see FIG. 20B1 and FIG. 20B2). In this embodiment, a titanium nitride film is deposited by an ALD method as the conductive film 260_1A and a tungsten film is deposited by a CVD method as the conductive film 260_2A.

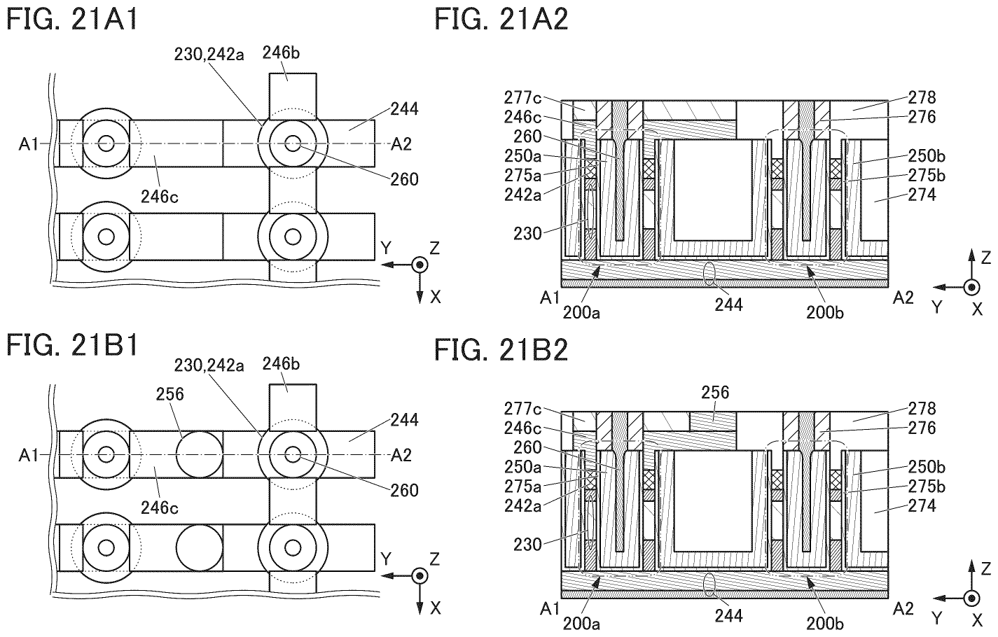

Next, the conductive film 260_1A and the conductive film 260_2A are processed by CMP treatment until the insulator 277b, the insulator 277c, and the insulator 278 are exposed, whereby the conductor 260 is formed (see FIG. 21A1 and FIG. 21A2). Accordingly, the conductor 260 is placed to fill the opening of the insulator 276 and the depression of the insulator 250a. That is, the conductor 260 is placed to fill the opening formed in the oxide 230 with the insulator 275a and the insulator 250a therebetween.

Note that although part of the conductive film 260_1A remains in the opening of the insulator 276 and the depression of the insulator 250a in order to form the conductor 260 in FIG. 21A2, the present invention is not limited thereto. Depending on the conditions of the CMP treatment, the size, depth, or the like of the opening of the insulator 276, part of the conductive film 260_1A and part of the conductive film 260_2A may remain in the opening of the insulator 276 and the depression of the insulator 250a. At this time, the conductor 260 has a stacked-layer structure of a first conductor formed from the conductive film 260_1A and a second conductor formed from the conductive film 260_2A. In the case where only the conductive film 260_1A remains in the opening of the insulator 276 and the depression of the insulator 250a as illustrated in FIG. 21A2, the conductive film 260_2A is not necessarily deposited.

By the above CMP treatment, part of the insulator 277b, part of the insulator 277c, and part of the insulator 278 are removed in some cases.

Next, an opening reaching the conductor 246c is formed in the insulator 277c. Next, a conductive film to be the conductor 256 is deposited. Next, part of the conductive film is removed by CMP treatment to expose the insulator 277b, the insulator 277c, and the insulator 278. Consequently, the conductor 256 is formed in the above-described opening portion (see FIG. 21B1 and FIG. 21B2). By the CMP treatment, part of the insulator 277b, part of the insulator 277c, and part of the insulator 278 are removed in some cases.

Next, the insulator 285 is formed over the insulator 276, the insulator 277b, the insulator 277c, the insulator 278, the conductor 260, and the conductor 256 (see FIG. 22A1 and FIG. 22A2). The insulator 285 is preferably deposited by a sputtering method. By using a sputtering method that does not need to use a molecule containing hydrogen as a deposition gas, the hydrogen concentration in the insulator 285 can be reduced. In this embodiment, as the insulator 285, silicon oxide is deposited by a sputtering method.

Next, an opening is formed in the insulator 285 (see FIG. 22B1 and FIG. 22B2). By forming the opening, at least the top surface of the insulator 276, the top surface of the conductor 256, and the top surface of the conductor 260 are exposed. Wet etching may be used for the formation of the opening; however, dry etching is preferably used for microfabrication. When the opening is formed in the insulator 285, part of the insulator 276 is removed in some cases.

Next, a conductive film to be the conductor 262a_1 and the conductor 262c_1 and a conductive film to be the conductor 262a_2 and the conductor 262c_2 are deposited in this order. In this embodiment, a titanium nitride film is deposited by an ALD method as the conductive film to be the conductor 262a_1 and the conductor 262c_1, and a tungsten film is deposited by a CVD method as the conductive film to be the conductor 262a_2 and the conductor 262c_2.

Next, the conductive film to be the conductor 262a_1 and the conductor 262c_1 and the conductive film to be the conductor 262a_2 and the conductor 262c_2 are processed by CMP treatment until the insulator 285 is exposed. Thus, the conductor 262a (the conductor 262a_1 and the conductor 262a_2) and the conductor 262c (the conductor 262c_1 and the conductor 262c_2) are formed (see FIG. 22B1 and FIG. 22B2). Note that in the case where the conductor 260 and the conductors 262a_1 and 262c_1 are formed using the same material, the boundaries between the conductor 260 and the conductors 262a_1 and 262c_1 are difficult to detect clearly in some cases.

In the above-described manner, the semiconductor device including the transistor 200 illustrated in FIG. 13A to FIG. 13D can be manufactured. As illustrated in FIG. 15A1 to FIG. 22B2, the transistor 200 can be manufactured in accordance with the method for manufacturing the semiconductor device described in this embodiment.

With one embodiment of the present invention, a semiconductor device that can be miniaturized or highly integrated can be provided. With one embodiment of the present invention, a semiconductor device with a small variation in electrical characteristics of transistors can be provided. With one embodiment of the present invention, a semiconductor device with high reliability can be provided. With one embodiment of the present invention, a semiconductor device with favorable electrical characteristics can be provided. With one embodiment of the present invention, a semiconductor device with a high on-state current can be provided.

This embodiment can be combined with the other embodiments as appropriate. In this specification, in the case where a plurality of structure examples are shown in one embodiment, the structure examples can be combined as appropriate.

### Embodiment 2

In this embodiment, a storage device of one embodiment of the present invention will be described with reference to drawings. The storage device of one embodiment of the present invention is a storage device in which a transistor using an oxide as a semiconductor (hereinafter, referred to as an OS transistor in some cases) is used (hereinafter, such a storage device is referred to as an OS memory device in some cases).

### <Structure Example of Storage Device>

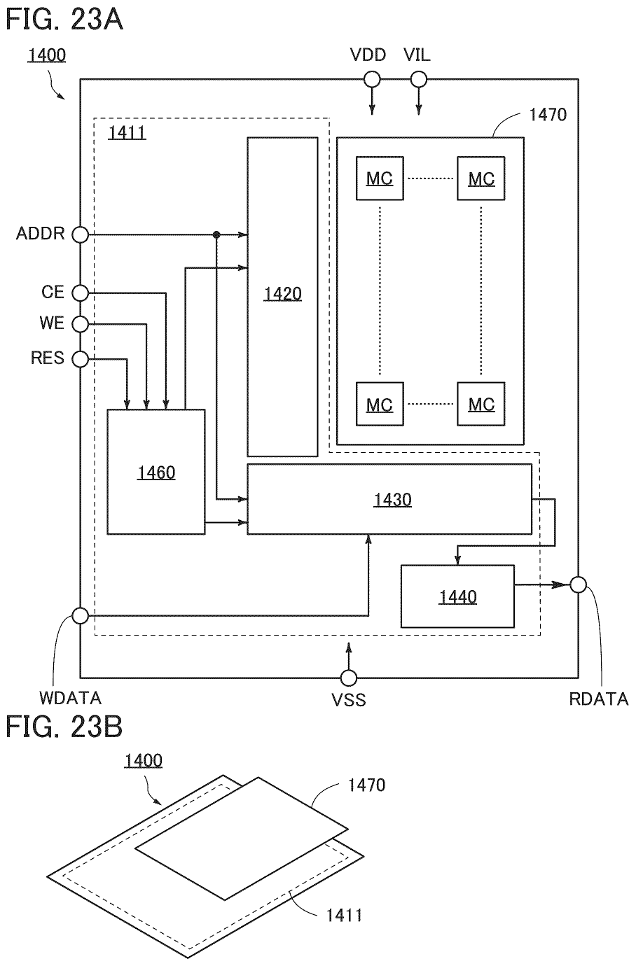

FIG. 23A illustrates a structure example of the OS memory device. A storage device 1400 includes a peripheral circuit 1411 and a memory cell array 1470. The peripheral circuit 1411 is a circuit having a function of writing data to memory cells included in the memory cell array 1470 and reading data from the memory cells included in the memory cell array 1470. The peripheral circuit 1411 includes a row circuit 1420, a column circuit 1430, an output circuit 1440, and a control logic circuit 1460.

The column circuit 1430 includes, for example, a column decoder, a precharge circuit, a sense amplifier, a write circuit, and the like. The precharge circuit has a function of precharging wirings. The sense amplifier has a function of amplifying a data signal read from a memory cell. Note that the wirings are connected to the memory cell included in the memory cell array 1470, and are described later in detail. The amplified data signal is output as a data signal RDATA to the outside of the storage device 1400 through the output circuit 1440. The row circuit 1420 includes, for example, a row decoder, a word line driver circuit, and the like, and can select a row to be accessed.

As power supply voltages from the outside, a low power supply voltage (VSS), a high power supply voltage (VDD) for the peripheral circuit 1411, and a high power supply voltage (VIL) for the memory cell array 1470 are supplied to the storage device 1400. Control signals (CE, WE, and RES), an address signal ADDR, and a data signal WDATA are also input to the storage device 1400 from the outside. The address signal ADDR is input to the row decoder and the column decoder, and the data signal WDATA is input to the write circuit.

The control logic circuit 1460 processes the control signals (CE, WE, and RES) input from the outside, and generates control signals for the row decoder and the column decoder. The control signal CE is a chip enable signal, the control signal WE is a write enable signal, and the control signal RES is a read enable signal. Signals processed by the control logic circuit 1460 are not limited thereto, and other control signals are input as necessary.

The memory cell array 1470 includes a plurality of memory cells MC arranged in a matrix and a plurality of wirings. Note that the number of wirings that connect the memory cell array 1470 to the row circuit 1420 depends on the structure of the memory cell MC, the number of memory cells MC in a column, and the like. The number of wirings that connect the memory cell array 1470 to the column circuit 1430 depends on the structure of the memory cell MC, the number of memory cells MC in a row, and the like.

Note that FIG. 23A illustrates an example in which the peripheral circuit 1411 and the memory cell array 1470 are formed on the same plane; however, this embodiment is not limited thereto. For example, as illustrated in FIG. 23B, the memory cell array 1470 may be provided to overlap with part of the peripheral circuit 1411. For example, the sense amplifier may be provided below the memory cell array 1470 so that they overlap with each other.

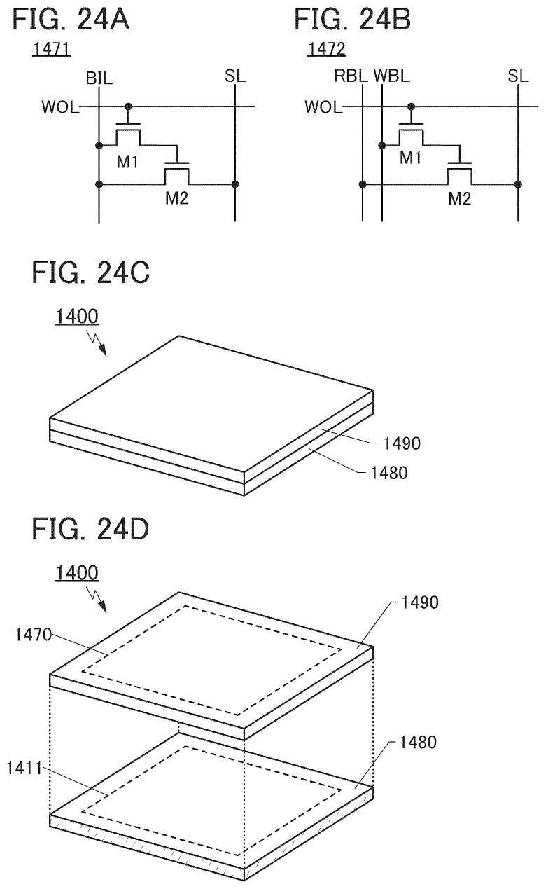

With FIG. 24A and FIG. 24B, a structure example of a memory cell applicable to the above-described memory cell MC is described.

FIG. 24A illustrates a configuration example of a gain-cell memory cell with two transistors. A memory cell 1471 illustrated in FIG. 24A includes a transistor M1 and a transistor M2. The transistor M1 and the transistor M2 are single-gate transistors.

A first terminal of the transistor M1 is connected to a gate of the transistor M2, a second terminal of the transistor M1 is connected to a wiring BIL, and a gate of the transistor M1 is connected to a wiring WOL. A first terminal of the transistor M2 is connected to a wiring SL, and a second terminal of the transistor M2 is connected to the wiring BIL.

The wiring BIL functions as a bit line, and the wiring WOL functions as a word line.

In the memory cell 1471, the gate capacitance of the transistor M2 is used as storage capacitance. That is, the memory cell 1471 can be regarded as a capacitor-less memory cell. Therefore, the memory cell 1471 can be regarded as a gain-cell memory cell with two transistors and no capacitor.

When the OS transistor is used as the transistor M1 and the transistor M1 is brought into the off state, charge at a node where one of the source and the drain of the transistor M1 is electrically connected to the gate of the transistor M2 can be retained for an extremely long time. Accordingly, a nonvolatile memory cell can be obtained.

As the memory cell 1471 illustrated in FIG. 24A, the memory cell 100 illustrated in FIG. 2 or the memory cell 100 illustrated in FIG. 13 can be used. In this case, the transistor M1 and the transistor M2 respectively correspond to the transistor 200a and the transistor 200b. The wiring BIL, the wiring WOL, and the wiring SL respectively correspond to the conductor 244, the conductor 262a, and the conductor 246b.

FIG. 24B illustrates another circuit configuration example of the gain-cell memory cell with two transistors. A memory cell 1472 illustrated in FIG. 24B includes a transistor M1 and a transistor M2. Note that the transistor M1 and the transistor M2 are single-gate transistors.

A first terminal of the transistor M1 is connected to a gate of the transistor M2, a second terminal of the transistor M1 is connected to a wiring WBL, and a gate of the transistor M1 is connected to a wiring WOL. A first terminal of the transistor M2 is connected to a wiring SL, and a second terminal of the transistor M2 is connected to a wiring RBL.

The wiring WBL functions as a write bit line, the wiring RBL functions as a read bit line, and the wiring WOL functions as a word line.

In the memory cell 1472, the gate capacitance of the transistor M2 is used as storage capacitance as in the memory cell 1471. When an OS transistor is used as the transistor M1 and the transistor M1 is brought into the off state, charge at a node where one of the source and the drain of the transistor M1 is electrically connected to the gate of the transistor M2 can be retained for an extremely long time. Accordingly, a nonvolatile memory cell can be obtained.

As the memory cell 1472 illustrated in FIG. 24B, the memory cell 100A illustrated in FIG. 6 can be used. In this case, the transistor M1 and the transistor M2 respectively correspond to the transistor 200a and the transistor 200b. The wiring WBL, the wiring RBL, the wiring WOL, and the wiring SL respectively correspond to the conductor 244a, the conductor 244b, the conductor 262a, and the conductor 246b.

Alternatively, the memory cell 100B illustrated in FIG. 8 or the memory cell 100C illustrated in FIG. 10 can be used as the memory cell 1472 illustrated in FIG. 24B. In this case, the transistor M1 and the transistor M2 respectively correspond to the transistor 200a and the transistor 200b. The wiring WBL, the wiring RBL, the wiring WOL, and the wiring SL respectively correspond to the conductor 246a, the conductor 246b, the conductor 262a, and the conductor 244b.

The circuit structure of the memory cell MC is not limited to that of the memory cell 1471 and the memory cell 1472 and can be changed.

When an OS transistor is used as the transistor M1, the transistor M1 can be formed in a BEOL process for forming a wiring of the storage device. In the case where a Si transistor is used in the peripheral circuit 1411 that is below and overlaps with the memory cell array 1470, the BEOL-Tr technology can be employed. With this technology, a 3D functional circuit can be constructed without a change of design rule, and high functionality can be achieved with low power consumption and low cost.

FIG. 24C is a perspective view of the storage device 1400. The storage device 1400 includes a layer 1480 and a layer 1490. FIG. 24D is a perspective view for explaining the structure of the storage device 1400, illustrating the layer 1480 and the layer 1490 separately.

The layer 1480 includes a transistor, for example. A semiconductor layer including a channel formation region of the transistor may be formed using a semiconductor material such as a single crystal semiconductor, a polycrystalline semiconductor, a microcrystalline semiconductor, or an amorphous semiconductor alone or in combination. As the semiconductor material, silicon, germanium, or the like can be used, for example. Alternatively, a compound semiconductor such as silicon germanium, silicon carbide, gallium arsenide, an oxide semiconductor, or a nitride semiconductor may be used. Alternatively, gallium arsenide, aluminum gallium arsenide, indium gallium arsenide, gallium nitride, indium phosphide, silicon germanium, or the like that can be used for a HEMT (High Electron Mobility Transistor) may be used.

The layer 1490 includes a transistor, for example. A semiconductor layer including a channel formation region of the transistor may be formed using a semiconductor material enabling formation of a thin film, such as an oxide semiconductor or silicon. With use of the BEOL-Tr technology, the layer 1490 can be provided over the layer 1480. Thus, miniaturization of the storage device 1400 can be achieved.

For example, the transistor included in the layer 1480 is a Si transistor. In this case, the peripheral circuit 1411 can be provided in the layer 1480. The transistor included in the layer 1490 is an OS transistor. In this case, the memory cell array 1470 can be provided in the layer 1480.

Accordingly, the storage device 1400 can be manufactured with use of the BEOL-Tr technology. Thus, the area occupied by the storage device 1400 can be reduced.

Note that the structures of the peripheral circuit 1411, the memory cell array 1470, and the like described in this embodiment are not limited to the above. The arrangement and functions of these circuits and the wirings, circuit components, and the like connected to the circuits can be changed, removed, or added as needed.

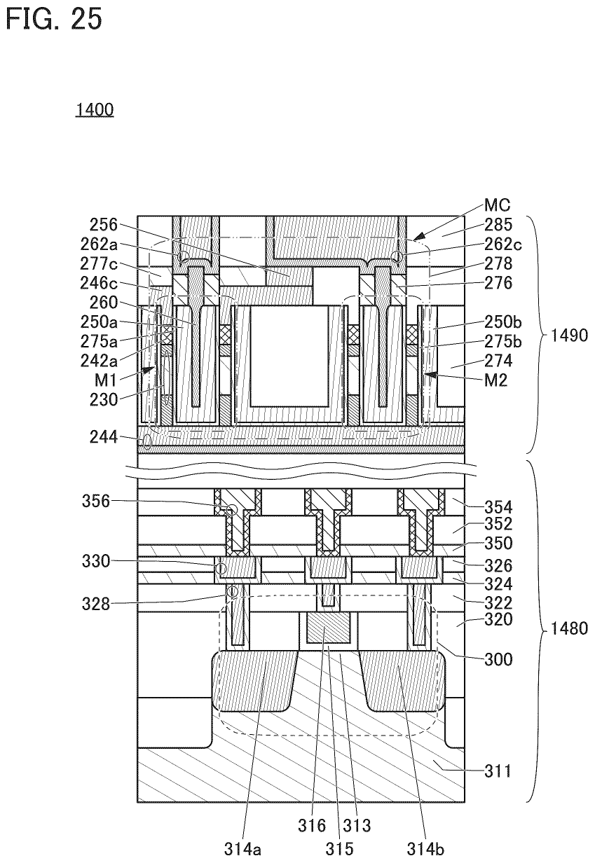

FIG. 25 illustrates a cross-sectional structure example of the storage device 1400 illustrated in FIG. 23A. In FIG. 25, part of the storage device 1400 illustrated in FIG. 23A is illustrated.

As illustrated in FIG. 25, the storage device 1400 includes the layer 1480 and the layer 1490 over the layer 1480. The peripheral circuit 1411 is provided in the layer 1480. That is, the layer 1480 can be regarded as a layer including the peripheral circuit 1411. In addition, the memory cell array 1470 is provided in the layer 1490. The semiconductor device described in the above embodiment can be used for the memory cell included in the memory cell array 1470. That is, the layer 1480 is positioned below the semiconductor device described in the above embodiment.

FIG. 25 illustrates a transistor 300 included in the layer 1480. The transistor 300 functions as part of the above-described sense amplifier. In this case, the layer 1480 can be regarded as a substrate where a semiconductor circuit including a transistor is formed.

FIG. 25 illustrates part of the memory cell array 1470 provided in the layer 1490. Specifically, FIG. 25 illustrates one memory cell MC provided in the layer 1490.

The conductor 262a corresponds to the wiring WOL. The conductor 244 corresponds to the wiring BIL. The conductor 246b (not illustrated) corresponds to the wiring SL.

Although FIG. 25 illustrates a structure in which one layer 1490 including the memory cell array 1470 is provided, the present invention is not limited thereto. For example, a plurality of layers each including the memory cell array 1470 may be provided to be stacked.

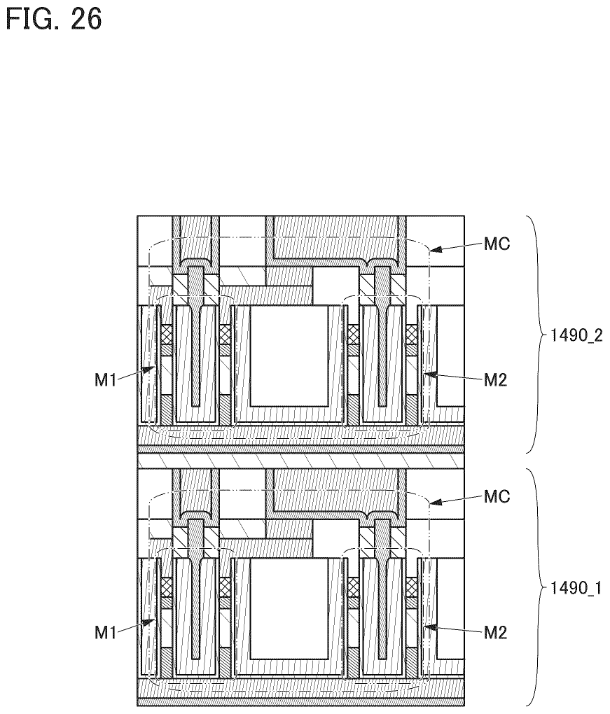

FIG. 26 illustrates a structure in which a layer 1490_1 including a memory cell array and a layer 1490_2 including a memory cell array are stacked. Note that the number of stacked layers may be three or more. Thus, when an OS transistor is used as a transistor included in the memory cell 100, the plurality of memory cell arrays 1470 can be provided to be stacked. That is, the amount of data that can be stored per unit area can be increased.

### <Transistor 300>

The transistor 300 is provided on a substrate 311 and includes a conductor 316 functioning as a gate, an insulator 315 functioning as a gate insulator, a semiconductor region 313 formed of part of the substrate 311, and a low-resistance region 314a and a low-resistance region 314b functioning as a source region and a drain region. The transistor 300 can be either a p-channel transistor or an n-channel transistor.

Here, in the transistor 300 illustrated in FIG. 25, the semiconductor region 313 (part of the substrate 311) where a channel is formed has a protruding shape. In addition, the conductor 316 is provided to cover a side surface and the top surface of the semiconductor region 313 with the insulator 315 therebetween. Note that a material adjusting the work function may be used for the conductor 316. Such a transistor 300 is also referred to as a FIN-type transistor because it utilizes the protruding portion of the semiconductor substrate. Note that an insulator functioning as a mask for forming the protruding portion may be included in contact with an upper portion of the protruding portion. Furthermore, although the case where the protruding portion is formed by processing part of the semiconductor substrate is described here, a semiconductor film having a protruding shape may be formed by processing an SOI substrate.

Note that the transistor 300 illustrated in FIG. 25 is an example and the structure is not limited thereto; an appropriate transistor is used in accordance with a circuit structure or a driving method.

### <Wiring Layer>

Wiring layers provided with an interlayer film, a wiring, a plug, and the like may be provided between the components. A plurality of wiring layers can be provided in accordance with design. Here, a plurality of conductors functioning as plugs or wirings are collectively denoted by the same reference numeral in some cases. Furthermore, in this specification and the like, a wiring and a plug electrically connected to the wiring may be a single component. That is, part of a conductor functions as a wiring in some cases and part of a conductor functions as a plug in other cases.

For example, an insulator 320, an insulator 322, an insulator 324, and an insulator 326 are stacked in this order over the transistor 300 as an interlayer film. Furthermore, a conductor 328, a conductor 330, and the like that are electrically connected to the transistor 200 are embedded in the insulator 320, the insulator 322, the insulator 324, and the insulator 326. Note that the conductor 328 and the conductor 330 function as a plug or a wiring.

The insulators functioning as the interlayer film may also function as a planarization film that covers an uneven shape thereunder. For example, a top surface of the insulator 322 may be planarized by planarization treatment using a chemical mechanical polishing (CMP) method or the like to increase planarity.

A wiring layer may be provided over the insulator 326 and the conductor 330. For example, in FIG. 25, an insulator 350, an insulator 352, and an insulator 354 are provided to be stacked sequentially. Furthermore, a conductor 356 is formed in the insulator 350, the insulator 352, and the insulator 354. The conductor 356 functions as a plug or a wiring.

Examples of an insulator that can be used as an interlayer film include an insulating oxide, an insulating nitride, an insulating oxynitride, an insulating nitride oxide, an insulating metal oxide, an insulating metal oxynitride, and an insulating metal nitride oxide.

For example, when a material having a low relative dielectric constant is used as the insulator functioning as an interlayer film, parasitic capacitance generated between wirings can be reduced. Thus, a material is preferably selected depending on the function of the insulators.

For example, as the insulator 322, the insulator 352, the insulator 354, and the like, an insulator having a low relative dielectric constant is preferably used. For example, the insulator preferably includes silicon oxide to which fluorine is added, silicon oxide to which carbon is added, silicon oxide to which carbon and nitrogen are added, porous silicon oxide, a resin, or the like. Alternatively, the insulator preferably has a stacked-layer structure of a resin and silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide. When silicon oxide or silicon oxynitride, which is thermally stable, is combined with a resin, the stacked-layer structure can have thermal stability and a low dielectric constant. Examples of the resin include polyester, polyolefin, polyamide (e.g., nylon and aramid), polyimide, polycarbonate, and acrylic.

When a transistor including an oxide semiconductor is surrounded by an insulator having a function of inhibiting passage of oxygen and impurities such as hydrogen, the electrical characteristics of the transistor can be stable. Thus, the insulator having a function of inhibiting the passage of oxygen and impurities such as hydrogen is used for the insulator 350 and the like.

As the insulator having a function of inhibiting passage of oxygen and impurities such as hydrogen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum are used. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; silicon nitride oxide; silicon nitride; or the like can be used.

As the conductor that can be used for a wiring or a plug, a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. Alternatively, a semiconductor having high electrical conductivity, typified by polycrystalline silicon containing an impurity element such as phosphorus, or silicide such as nickel silicide may be used.

For example, for the conductor 328, the conductor 330, the conductor 356, and the like, a single layer or stacked layers of a conductive material such as a metal material, an alloy material, a metal nitride material, or a metal oxide material that is formed using any of the above materials can be used. It is preferable to use a high-melting-point material that has both heat resistance and conductivity, such as tungsten or molybdenum, and it is preferable to use tungsten. Alternatively, it is preferable to form the conductors with a low-resistance conductive material such as aluminum or copper. The use of a low-resistance conductive material can reduce wiring resistance.

This embodiment can be combined with the other embodiments as appropriate. In this specification, in the case where a plurality of structure examples are shown in one embodiment, the structure examples can be combined as appropriate.

### Embodiment 3

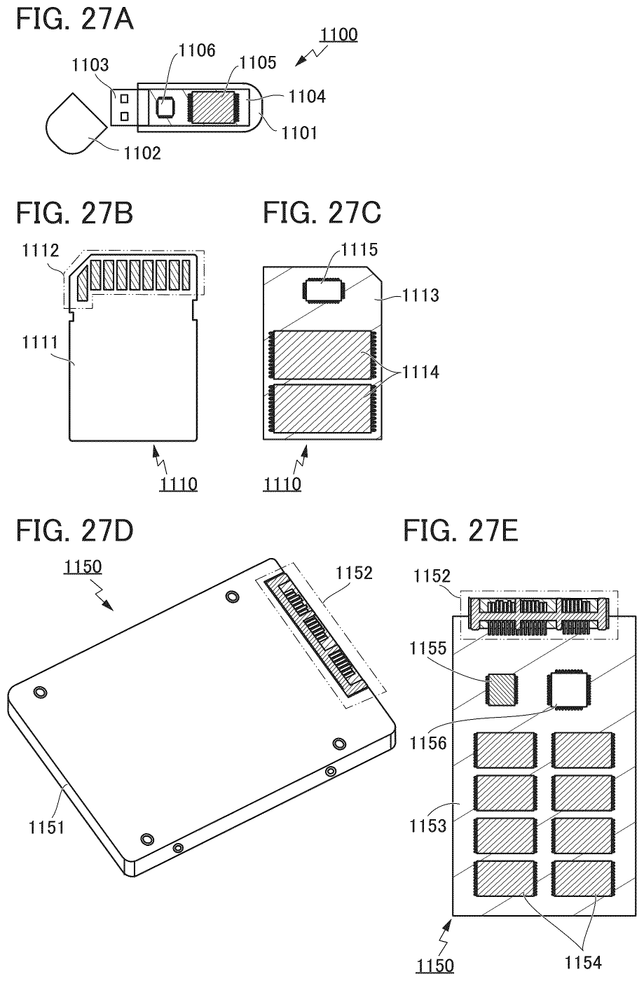

In this embodiment, application examples of the semiconductor device using the storage device described in the above embodiment will be described. The storage device described in the above embodiment can be used for a variety of removable storage devices such as memory cards (e.g., SD cards), USB memories, and SSDs (solid state drives). FIG. 27A to FIG. 27E schematically illustrate some structure examples of removable storage devices. The semiconductor device described in the above embodiment is processed into a packaged memory chip and used in a variety of storage devices and removable memories, for example.

FIG. 27A is a schematic view of a USB memory. A USB memory 1100 includes a housing 1101, a cap 1102, a USB connector 1103, and a substrate 1104. The substrate 1104 is held in the housing 1101. The substrate 1104 is provided with a memory chip 1105 and a controller chip 1106, for example. The storage device or the semiconductor device described in the above embodiment can be incorporated in the memory chip 1105 or the like.

FIG. 27B is a schematic external view of an SD card, and FIG. 27C is a schematic view of the internal structure of the SD card. An SD card 1110 includes a housing 1111, a connector 1112, and a substrate 1113. The substrate 1113 is held in the housing 1111. The substrate 1113 is provided with a memory chip 1114 and a controller chip 1115, for example. When the memory chip 1114 is also provided on the back side of the substrate 1113, the capacity of the SD card 1110 can be increased. In addition, a wireless chip with a radio communication function may be provided on the substrate 1113. With this, data can be read from and written in the memory chip 1114 by radio communication between a host device and the SD card 1110. The storage device or the semiconductor device described in the above embodiment can be incorporated in the memory chip 1114 or the like.

FIG. 27D is a schematic external view of an SSD, and FIG. 27E is a schematic view of the internal structure of the SSD. An SSD 1150 includes a housing 1151, a connector 1152, and a substrate 1153. The substrate 1153 is held in the housing 1151. The substrate 1153 is provided with a memory chip 1154, a memory chip 1155, and a controller chip 1156, for example. The memory chip 1155 is a work memory of the controller chip 1156, and a DOSRAM chip can be used, for example. When the memory chip 1154 is also provided on the back side of the substrate 1153, the capacity of the SSD 1150 can be increased. The storage device or the semiconductor device described in the above embodiment can be incorporated in the memory chip 1154 or the like.

This embodiment can be implemented in an appropriate combination with the structures described in the other embodiments and the like.

### Embodiment 4

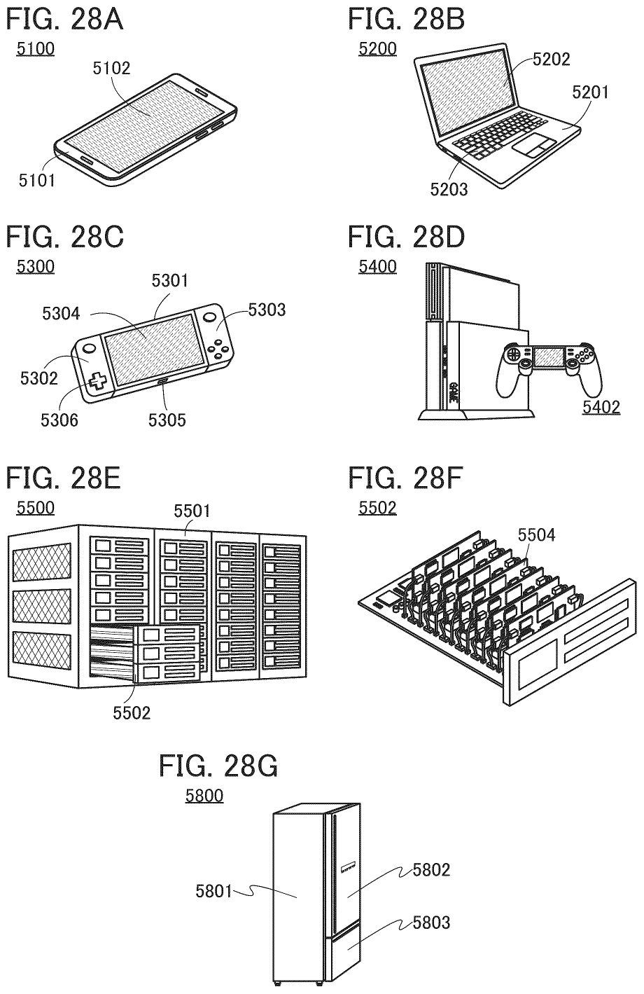

FIG. 28A to FIG. 28G illustrate specific examples of electronic devices each provided with the storage device or semiconductor device of one embodiment of the present invention.

### <Electronic Device⋅System>

The storage device or the semiconductor device of one embodiment of the present invention can be mounted on a variety of electronic devices. Examples of electronic devices include an information terminal, a computer, a smartphone, an e-book reader, a television device, digital signage, a large game machine such as a pachinko machine, a digital camera, a digital video camera, a digital photo frame, a mobile phone, a portable game machine, a video recording/reproducing device, a navigation system, and an audio reproducing device. Here, the computer refers not only to a tablet computer, a notebook computer, and a desktop computer, but also to a large computer such as a server system.

The electronic device of one embodiment of the present invention may include an antenna. When a signal is received by the antenna, a video, data, or the like can be displayed on a display portion. When the electronic device includes the antenna and a secondary battery, the antenna may be used for contactless power transmission.

The electronic device of one embodiment of the present invention may include a sensor (a sensor having a function of measuring force, displacement, position, speed, acceleration, angular velocity, rotational frequency, distance, light, liquid, magnetism, temperature, a chemical substance, sound, time, hardness, an electric field, current, voltage, power, radioactive rays, flow rate, humidity, a gradient, oscillation, odor, or infrared rays).

The electronic device of one embodiment of the present invention can have a variety of functions. For example, the electronic device can have a function of displaying a variety of data (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

### [Information Terminal]

With the storage device or semiconductor device of one embodiment of the present invention, a storage device for storing a microcontroller program can be configured. Thus, according to one embodiment of the present invention, the size of a microcontroller chip can be reduced.

FIG. 28A illustrates a mobile phone (smartphone), which is a type of information terminal. An information terminal 5100 includes a housing 5101 and a display portion 5102. As input interfaces, a touch panel is provided in the display portion 5102, and a button is provided in the housing 5101. The use of a downsized microcontroller of one embodiment of the present invention allows effective use of a limited space in the mobile phone. The storage device of one embodiment of the present invention may be used for storage of the mobile phone. This results in an increase in the storage capacity per unit area of the storage.

FIG. 28B illustrates a notebook information terminal 5200. The notebook information terminal 5200 includes a main body 5201 of the information terminal, a display portion 5202, and a keyboard 5203. The use of a downsized microcontroller of one embodiment of the present invention allows effective use of a limited space in the notebook information terminal. The storage device of one embodiment of the present invention may be used for storage of the notebook information terminal. This results in an increase in the storage capacity per unit area of the storage.

Note that although FIG. 28A and FIG. 28B illustrate a smartphone and a notebook information terminal, respectively, as examples of the electronic device in the above description, an information terminal other than a smartphone and a notebook information terminal can be used. Examples of information terminals other than a smartphone and a notebook information terminal include a PDA (Personal Digital Assistant), a desktop information terminal, and a workstation.

### [Game Machine]

FIG. 28C illustrates a portable game machine 5300 as an example of a game machine. The portable game machine 5300 includes a housing 5301, a housing 5302, a housing 5303, a display portion 5304, a connection portion 5305, an operation key 5306, and the like. The housing 5302 and the housing 5303 can be detached from the housing 5301. When the connection portion 5305 provided in the housing 5301 is attached to another housing (not illustrated), a video to be output to the display portion 5304 can be output to another video device (not illustrated). In that case, the housing 5302 and the housing 5303 can each function as an operating unit. Thus, a plurality of players can play a game at the same time. The storage device, the semiconductor device, or the like of one embodiment of the present invention can be incorporated into a chip provided on a substrate in the housing 5301, the housing 5302 and the housing 5303, for example.

FIG. 28D illustrates a stationary game machine 5400 as an example of a game machine. A controller 5402 is wired or connected wirelessly to the stationary game machine 5400.

The use of a downsized microcontroller of one embodiment of the present invention for the game machine such as the portable game machine 5300 or the stationary game machine 5400 allows effective use of a limited space in the game machine. The storage device, the semiconductor device, or the like of one embodiment of the present invention may be used for storage of the portable game machine. This results in an increase in the storage capacity per unit area of the storage.

Although the portable game machine and the stationary game machine are illustrated as examples of game machines in FIG. 28C and FIG. 28D, the game machine using the microcontroller of one embodiment of the present invention is not limited thereto. Examples of game machines using the microcontroller of one embodiment of the present invention include an arcade game machine installed in entertainment facilities (a game center, an amusement park, or the like) and a throwing machine for batting practice installed in sports facilities.

### [Large Computer]

The storage device, the semiconductor device, or the like of one embodiment of the present invention can be used in a large computer.

FIG. 28E illustrates a supercomputer 5500 as an example of a large computer. FIG. 28F illustrates a rack-mount computer 5502 included in the supercomputer 5500.

The supercomputer 5500 includes a rack 5501 and a plurality of rack-mount computers 5502. The plurality of computers 5502 are stored in the rack 5501. The computers 5502 are provided with a plurality of substrates 5504, and a microcontroller of one embodiment of the present invention can be mounted on the substrates. The use of a downsized microcontroller of one embodiment of the present invention allows effective use of a limited space in the large computer. The storage device, the semiconductor device, or the like of one embodiment of the present invention may be used for storage of the large computer. This results in an increase in the storage capacity per unit area of the storage.

Although a supercomputer is illustrated as an example of a large computer in FIG. 28E and FIG. 28F, a large computer using the microcontroller of one embodiment of the present invention is not limited thereto. Examples of a large computer using the microcontroller of one embodiment of the present invention include a computer that provides service (a server) and a large general-purpose computer (a mainframe).

### [Household Appliance]

FIG. 28G illustrates an electric refrigerator-freezer 5800 as an example of a household appliance. The electric refrigerator-freezer 5800 includes a housing 5801, a refrigerator door 5802, a freezer door 5803, and the like.

The storage device, the semiconductor device, or the like of one embodiment of the present invention can also be used for the electric refrigerator-freezer 5800. For example, the use of a downsized microcontroller of one embodiment of the present invention for the electric refrigerator-freezer 5800 allows effective use of a limited space in the electric refrigerator-freezer.

Although the electric refrigerator-freezer is described as an example of a household appliance, other examples of a household appliance include a vacuum cleaner, a microwave oven, an electric oven, a rice cooker, a water heater, an IH cooker, a water server, a heating-cooling combination appliance such as an air conditioner, a washing machine, a drying machine, and an audio visual appliance.

The electronic devices, the functions of the electronic devices, its effects, and the like described in this embodiment can be combined as appropriate with the description of another electronic device.

This embodiment can be implemented in an appropriate combination with the structures described in the other embodiments and the like.

### REFERENCE NUMERALS

10 semiconductor device
100A: memory cell, 100B: memory cell, 100C: memory cell, 100: memory cell, 200a: transistor, 200b: transistor, 200: transistor, 212: insulator, 216: insulator, 230_1: oxide, 230_1A: oxide film, 230_2: oxide, 230_21: region, 230_22: region, 230_2A: oxide film, 230_3: oxide, 230_3A: oxide film, 230: oxide, 242a: conductor, 242A: conductive film, 242b: conductor, 244_1: conductor, 244_2: conductor, 244a: conductor, 244b: conductor, 244c: conductor, 244: conductor, 246a: conductor, 246b: conductor, 246b1: protruding portion, 246c: conductor, 246cl: protruding portion, 246: conductor, 247: insulator, 250a: insulator, 250A: insulating film, 250b: insulator, 250: insulator, 254a: insulator, 254b: insulator, 256: conductor, 260_1A: conductive film, 260_2A: conductive film, 260: conductor, 262a: conductor, 262a_1: conductor, 262a_2: conductor, 262c: conductor, 262c_1: conductor, 262c_2: conductor, 264b: region, 264c: region, 274A: insulating film, 274c: insulator, 274: insulator, 275a: insulator, 275A: insulating film, 275b: insulator, 276A: insulating film, 276: insulator, 277b: insulator, 277c: insulator, 278: insulator, 285: insulator, 291A: insulating film, 291: insulator, 292: resist mask, 293A: insulating film, 293: insulator, 300: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 350: insulator, 352: insulator, 354: insulator, 356: conductor, 1100: USB memory, 1101: housing, 1102: cap, 1103: USB connector, 1104: substrate, 1105: memory chip, 1106: controller chip, 1110: SD card, 1111: housing, 1112: connector, 1113: substrate, 1114: memory chip, 1115: controller chip, 1150: SSD, 1151: housing, 1152: connector, 1153: substrate, 1154: memory chip, 1155: memory chip, 1156: controller chip, 1400: storage device, 1411: peripheral circuit, 1420: row circuit, 1430: column circuit, 1440: output circuit, 1460: control logic circuit, 1470: memory cell array, 1471: memory cell, 1472: memory cell, 1480: layer, 1490_1: layer, 1490_2: layer, 1490: layer, 5100: information terminal, 5101: housing, 5102: display portion, 5200: notebook information terminal, 5201: main body, 5202: display portion, 5203: keyboard, 5300: portable game machine, 5301: housing, 5302: housing, 5303: housing, 5304: display portion, 5305: connection portion, 5306: operation key, 5400: stationary game machine, 5402: controller, 5500: supercomputer, 5501: rack, 5502: computer, 5504: substrate, 5800: electric refrigerator-freezer, 5801: housing, 5802: refrigerator door, 5803: freezer door

1. A semiconductor device comprising:
a first conductor;
a first oxide and a second oxide each having an opening and being electrically connected to the first conductor;
a second conductor electrically connected to the first oxide;
a first insulator placed inside the opening of the first oxide;
a third conductor over the first insulator;
a fourth conductor electrically connected to the third conductor;
a fifth conductor electrically connected to the second oxide;
a second insulator placed inside the opening of the second oxide;
a sixth conductor over the second insulator;
a seventh conductor electrically connected to the sixth conductor; and
an eighth conductor electrically connected to the second conductor and the seventh conductor,
wherein the fourth conductor is in the same layer as the seventh conductor, and
wherein a direction in which the fourth conductor extends is the same as a direction in which the fifth conductor extends.

2. The semiconductor device according to claim 1,
wherein the first conductor extends in a direction orthogonal to the direction in which the fourth conductor extends.

3. The semiconductor device according to claim 1, further comprising:
a ninth conductor and a tenth conductor,
wherein the ninth conductor is between the first oxide and the second conductor,
wherein a side surface of the ninth conductor is aligned with a side surface of the first oxide,
wherein the tenth conductor is between the second oxide and the fifth conductor, and
wherein a side surface of the tenth conductor is aligned with a side surface of the second oxide.

4. The semiconductor device according to claim 3,
wherein the second conductor has a protruding portion, and
wherein the protruding portion is in contact with the ninth conductor.

5. The semiconductor device according to claim 1,
wherein a side surface of the first oxide has a tapered shape in a cross-sectional view.

6. A semiconductor device comprising:
a first conductor and a second conductor;
a first oxide having an opening and being electrically connected to the first conductor;
a third conductor electrically connected to the first oxide;
a first insulator placed inside the opening of the first oxide;
a fourth conductor over the first insulator;
a fifth conductor electrically connected to the fourth conductor;
a second oxide having an opening and electrically connected to the second conductor;
a sixth conductor electrically connected to the second oxide;
a second insulator placed inside the opening of the second oxide;
a seventh conductor over the second insulator;
an eighth conductor electrically connected to the seventh conductor; and
a ninth conductor electrically connected to the third conductor and the eighth conductor,
wherein the fifth conductor is in the same layer as the eighth conductor, and
wherein a direction in which the fifth conductor extends is the same as a direction in which the sixth conductor extends.

7. The semiconductor device according to claim 6,
wherein the first conductor extends in a direction orthogonal to the direction in which the fifth conductor extends, and
wherein the second conductor extends in a direction orthogonal to the direction in which the sixth conductor extends.

8. The semiconductor device according to claim 6, further comprising:
a tenth conductor and an eleventh conductor,
wherein the tenth conductor is between the first oxide and the third conductor,
wherein a side surface of the tenth conductor is aligned with a side surface of the first oxide,
wherein the eleventh conductor is between the second oxide and the sixth conductor, and
wherein a side surface of the eleventh conductor is aligned with a side surface of the second oxide.

9. The semiconductor device according to claim 6,
wherein a side surface of the first oxide has a tapered shape in a cross-sectional view.

10. A storage device comprising:
the semiconductor device according to claim 1, and a layer comprising a peripheral circuit,
wherein the layer is positioned below the semiconductor device, and
wherein the peripheral circuit is configured to write data to the semiconductor device and read data from the semiconductor device.

11. A storage device comprising:
the semiconductor device according to claim 6, and a layer comprising a peripheral circuit,
wherein the layer is positioned below the semiconductor device, and
wherein the peripheral circuit is configured to write data to the semiconductor device and read data from the semiconductor device.
